(19) United States
(12) Patent Application Publication
(10) Pub. No.: US 2013/0122424 A1
(43) Pub. Date: May 16, 2013

(54) PHOTORESIST COMPOSITION

(71) Applicant: SUMITOMO CHEMICAL COMPANY, LIMITED, Tokyo (JP)

(72) Inventors: Yuko YAMASHITA, Osaka-shi (JP); Nobuo ANDO, Osaka-shi (JP)

(73) Assignee: SUMITOMO CHEMICAL COMPANY, LIMITED, Tokyo (JP)

(21) Appl. No.: 13/676,959

(22) Filed: Nov. 14, 2012

(30) Foreign Application Priority Data
Nov. 16, 2011 (JP) 2011-250407

(51) Int. Cl. G03F 7/027; G03F 7/20

(52) U.S. Cl. 430/283.1; 430/285.1; 430/325

(57) ABSTRACT

The present invention provides a photoresist composition comprising a compound represented by formula (I):

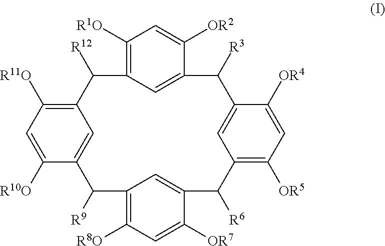

wherein R¹, R², R⁴, R⁵, R⁷, R⁸, R¹⁰ and R¹¹ independently represent a hydrogen atom, a C1-C20 aliphatic hydrocarbon group, or the like, R³; R⁶, R⁹ and R¹² independently represent a group of formula (II):

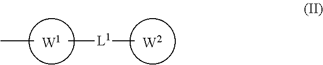

, and a salt represented by the formula (B1).

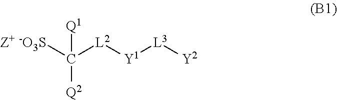

This nonprovisional application claims priority under 35 U.S.C. §119(a) on Patent Applications No. 2011-250407 filed in JAPAN on Nov. 16, 2010, the entire contents of which are hereby incorporated by reference.

### FIELD OF THE INVENTION

The present invention relates to a photoresist composition.

### BACKGROUND OF THE INVENTION

A photoresist composition is used for semiconductor micro fabrication.

JP 2010-285376A1 discloses a photoresist composition which comprises triphenylsulfonium=nonafluorobutanesulfonate as an acid generator.

### SUMMARY OF THE INVENTION

An object of the present invention is to provide a novel photoresist composition.

The present invention relates to the followings:

<1> A photoresist composition comprising
a compound represented by formula (I):

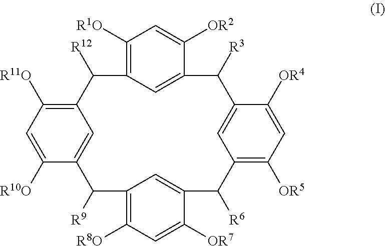

wherein R¹, R², R⁴, R⁵, R⁷, R⁸, R¹⁰ and R¹¹ independently represent a hydrogen atom, a C1-C20 aliphatic hydrocarbon group, a C6-C10 aromatic hydrocarbon group, or a C2-C10 alkoxyalkyl group, R³, R⁶, R⁹ and R¹² independently represent a group of formula (II):

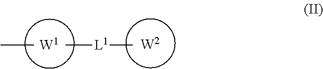

where the ring W¹ represents a C3-C36 aliphatic hydrocarbon ring, or a C6-C36 aromatic hydrocarbon ring, the ring W² represents a C3-C36 aliphatic hydrocarbon ring which optionally has a subsituent and in which a methylene group is optionally replaced by an oxygen atom, a sulfonyl group or a carbonyl group, or a C6-C36 aromatic hydrocarbon ring which optionally has a subsituent, and
L¹ represents a single bond or C1-C10 divalent aliphatic hydrocarbon group in which a methylene group is optionally replaced by an oxygen atom or a carbonyl group, and
a salt represented by the formula (B1):

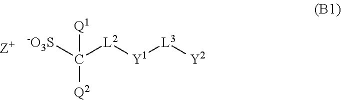

wherein Q¹ and Q² independently represent a fluorine atom or a C1-C6 perfluoroalkyl group,
L² represents a single bond or a C1-C17 divalent saturated hydrocarbon group in which a methylene group is optionally replaced by an oxygen atom, a carbonyl group, or —NR′— and in which a hydrogen atom is optionally replaced by a fluorine atom, and R′ represents a hydrogen atom or a C1-C4 alkyl group,
Y¹ represents a single bond or a C3-C18 divalent alicyclic hydrocarbon group in which a methylene group is optionally replaced by an oxygen atom, a carbonyl group or a sulfonyl group and in which a hydrogen atom is optionally replaced by a substituent,
L³ represents a single bond or a C1-C17 divalent hydrocarbon group in which a methylene group is optionally replaced by an oxygen atom or a carbonyl group,
Y² represents a C3-C18 alicyclic hydrocarbon group in which a methylene group is optionally replaced by an oxygen atom, a sulfonyl group or a carbonyl group and in which a hydrogen atom is optionally replaced by a substituent, and
Z⁺ represents an organic cation.
<2> The photoresist composition according to <1>, wherein Q¹ and Q² represent a fluorine atom.
<3> The photoresist composition according to <1> or <2>, wherein Y¹ represents a single bond or a C3-C18 divalent alicyclic hydrocarbon group.
<4> The photoresist composition according to any one of <1> to <3>, wherein L² represents a single bond or a C1-C17 divalent saturated hydrocarbon group in which a methylene group is optionally replaced by an oxygen atom or a carbonyl group and in which a hydrogen atom is optionally replaced by a fluorine atom.
<5> The photoresist composition according to any one of <1> to <4>, wherein L² represents *—CO—O-L^{s2}- where L^{S2} represents a single bond or a C1-C15 divalent hydrocarbon group and * represents a binding position to —C(Q¹)(Q²)-.
<6> The photoresist composition according to any one of <1> to <5>, wherein e represents an arylsulfonium cation.
<7> The photoresist composition according to any one of <1> to <6>, wherein the ring W¹ represents a benzene ring.
<8> The photoresist composition according to any one of <1> to <7>, wherein the ring W² represents a group of formula (I-a);

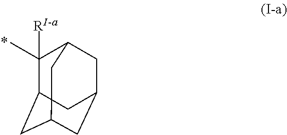

in which R^{I-a} represents a hydrogen atom or a C1-C6 alkyl group, and * represents a binding position to L¹, or a group of formula (I-d);

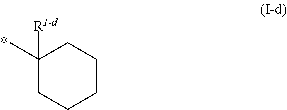

in which R^{I-d} represents a hydrogen atom or a C1-C6 alkyl group, and * represents a binding position to L¹.
<9> The photoresist composition according to any one of <1> to <8>, wherein L¹ represents *—CO—O—CH₂—O— or *—CO—O—CH₂—CO—O— where * represents a binding position to W¹.
<10> The photoresist composition according to any one of <1> to <9>, which further comprises a quencher.
<11> A process for producing a photoresist pattern comprising the following steps (1) to (5):

(1) a step of applying the photoresist composition according to any one of <1> to <10> onto a substrate,

(2) a step of forming a photoresist film by conducting drying,

(3) a step of exposing the photoresist film to radiation,

(4) a step of baking the exposed photoresist film, and

(5) a step of developing the baked photoresist film thereby forming a photoresist pattern.

### DESCRIPTION OF PREFERRED EMBODIMENTS

The photoresist composition of the present invention comprises

a compound represented by formula (I):

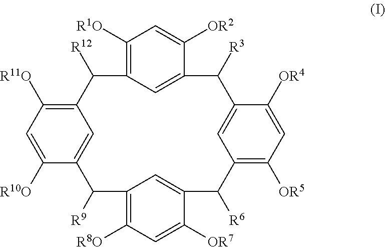

(hereinafter, simply referred to as COMPOUND (I)), and a salt represented by the formula (B1):

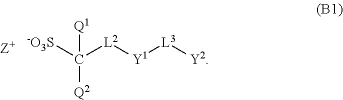

In formula (I), R¹, R², R⁴, R⁵, R⁷, R⁸, R¹⁰ and R¹¹ independently represent a hydrogen atom, a C1-C20 aliphatic hydrocarbon group, a C6-C10 aromatic hydrocarbon group, or a C2-C10 alkoxyalkyl group.

Examples of the aliphatic hydrocarbon group include a C1-C20 linear aliphatic hydrocarbon group, a C3-C20 branched aliphatic hydrocarbon group and a C3-C20 cyclic aliphatic hydrocarbon group.

Examples of the linear aliphatic hydrocarbon group include a C1-C20 linear alkyl group such as a methyl group, an ethyl group, a propyl group, a butyl group, a pentyl group, a hexyl group, a heptyl group, and an octyl group.

Examples of the branched aliphatic hydrocarbon group include a C3-C20 branched alkyl group such as an isopropyl group, an isobutyl group, a sec-butyl group, a tert-butyl group and 1-ethylhexyl group. The cyclic aliphatic hydrocarbon group may be monocyclic or polycyclic, examples of which include a cyclohexyl group, a norbornyl group, an adamantyl group, biadamantyl group, and a diadamantyl group.

Examples of the aromatic hydrocarbon group include a phenyl group and a naphthyl group.

Examples of the alkoxyalkyl group include a methoxymethyl group, an ethoxymethyl group and an adamantyloxymethyl group.

It is preferred that R¹, R⁴, R⁷ and R¹⁰ independently represent a hydrogen atom or a C1-C20 aliphatic hydrocarbon group. It is more preferred that R¹, R⁴, R⁷ and R¹⁰ independently represent a hydrogen atom, a methyl group, an ethyl group, a propyl group. It is still more preferred that R¹, R⁴, R⁷ and R¹⁰ independently represent a hydrogen atom.

It is preferred that R², R⁵, R⁸ and R¹¹ independently represent a C1-C20 aliphatic hydrocarbon group or a C6-C10 aromatic hydrocarbon group. It is more preferred that R², R⁵, R⁸ and R¹¹ independently represent a C1-C20 liner aliphatic hydrocarbon group. It is still more preferred that R², R⁵, R⁸ and R¹¹ independently represent a C1-C3 liner aliphatic hydrocarbon group such as a methyl group, an ethyl group and a propyl group. When R², R⁵, R⁸ and R¹¹ is a preferred group as mentioned above, COMPOUND (I) can be easily dissolved in an organic solvent.

In formula (I), R³, R⁶, R⁹ and R¹² independently represent a group of formula (II).

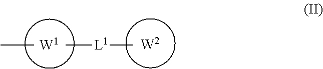

In formula (II), the ring W¹ represents a C3-C36 aliphatic hydrocarbon ring, or a C6-C36 aromatic hydrocarbon ring, and the ring W² represents a C3-C36 aliphatic hydrocarbon ring which optionally has a subsituent and in which a methylene group is optionally replaced by an oxygen atom, a sulfonyl group or a carbonyl group, or a C6-C36 aromatic hydrocarbon ring which optionally has a subsituent.

The aliphatic hydrocarbon ring represented by the ring W¹ includes a C3-C36 cycloalkane ring such as cyclopentane ring, cyclohexane ring, cycloheptane ring and adamantane ring.

The aromatic hydrocarbon ring represented by the ring W¹ or the ring W² includes a benzene ring and a naphthalene ring.

The aliphatic hydrocarbon ring represented by the ring W¹ or the ring W² optionally has a subsituent. The methylene group of the aliphatic hydrocarbon ring represented by the ring W² is optionally replaced by an oxygen atom, a sulfonyl group or a carbonyl group, preferably by an oxygen atom or a carbonyl group.

Examples of the subsituent for the aliphatic hydrocarbon ring include a C1-C5 alkyl group, a C1-C5 alkoxy group and a hydroxyl group.

The aliphatic hydrocarbon ring in which a methylene group has been replaced by an oxygen atom or a carbonyl group includes a C3-C20 lactone ring and C3-C20 cyclic ester.

The ring W¹ is preferably a C6-C36 aromatic hydrocarbon ring, more preferably a C6-C10 aromatic hydrocarbon ring, still more preferably a benzene ring.

Examples of the aliphatic hydrocarbon ring represented by the ring W² include the groups as represented by formulae (Y1) to (Y26).

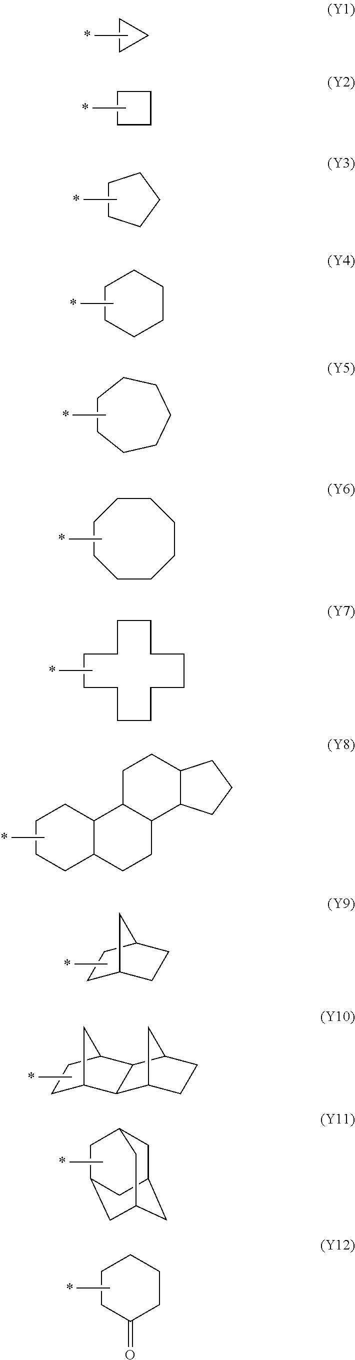

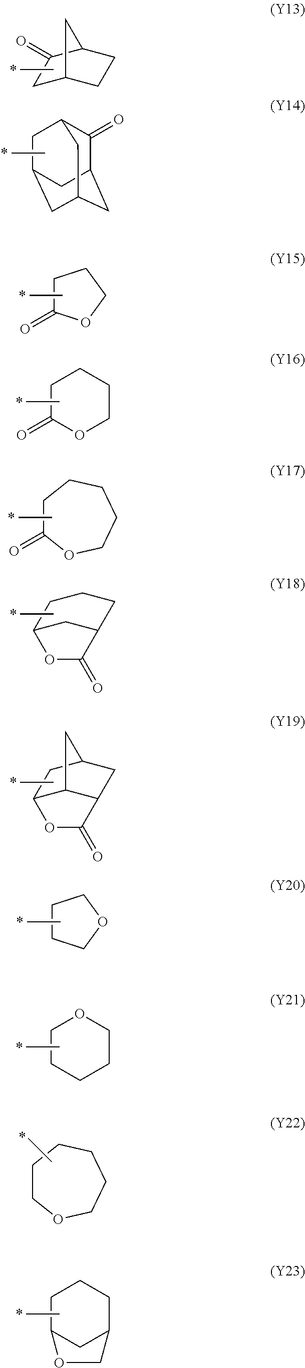

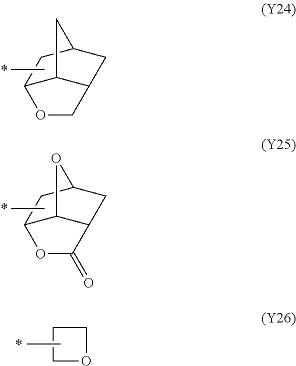

The aliphatic hydrocarbon ring represented by the ring W² includes preferably the rings of formulae (I-a) to (I-k), more preferably the rings of formulae (I-a), (I-b) and (I-d), still more preferably the rings of formulae (I-a) and (I-d).

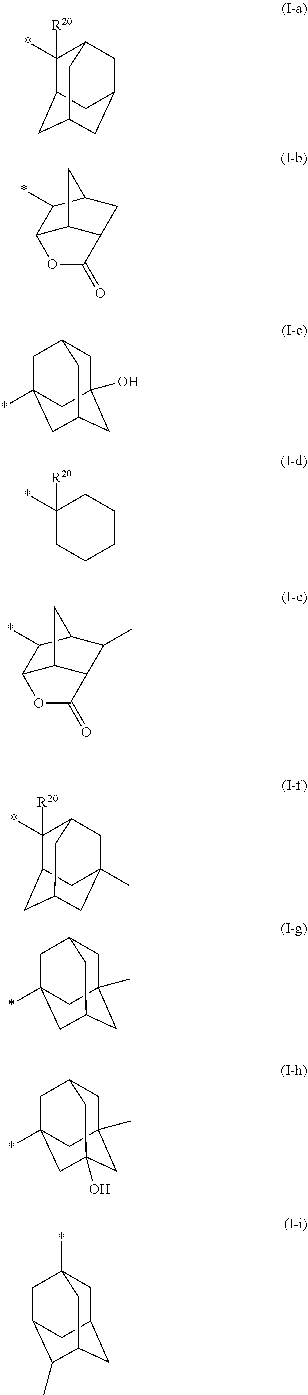

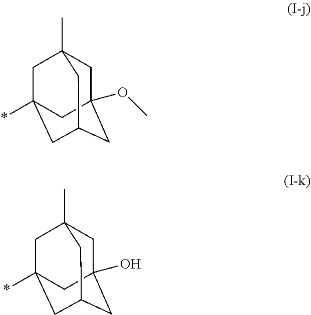

where R²⁰ represents a hydrogen atom or C1-C5 alkyl group, and * represents a binding position to L¹.
L¹ represents a single bond or C1-C10 divalent aliphatic hydrocarbon group in which a methylene group is optionally replaced by an oxygen atom or a carbonyl group.

Examples of the divalent aliphatic hydrocarbon group include C1-C10 alkanediyl group such as methyl group, ethylene group, propane-1,3-diyl group, propane-1,2-diyl group, butane-1,4-diyl group, pentane-1,5-diyl group, hexane-1,6-diyl group, heptane-1,7-diyl group, octane-1,8-diyl group, nonane-1,9-diyl group, decane-1,10-diyl group, undecane-1,11-diyl group, dodecane-1,12-diyl group, tridecane-1,13-diyl group, tetradecane-1,14-diyl group, pentadecane-1,15-diyl group, hexadecane-1,16-diyl group, heptadecane-1,17-diyl group, ethane-1,1-diyl group, propane-1,1-diyl group, propane-2,2-diyl group, butane-1,3-diyl group, 2-methyl-propane-1,3-diyl group, 1,1-dimethyl ethylene group, pentane-1,4-diyl group and 2-methyl-butane-1,4-diyl group.

In the aliphatic hydrocarbon group represented by L¹, a methylene group may be replaced by an oxygen atom or a carbonyl group. Considering easiness of its production, COMPOUND (I) preferably has, as the group of L¹, a divalent aliphatic hydrocarbon group in which a methylene group has been replaced by an oxygen atom or a carbonyl group.

Specific examples of the divalent aliphatic hydrocarbon group in which a methylene group has been replaced by an oxygen atom or a carbonyl group include the groups represented by any one of formulae (I1-1), (I1-2), (I1-3), (I1-4), (I1-5), (I1-6), (I1-7) and (I1-8);

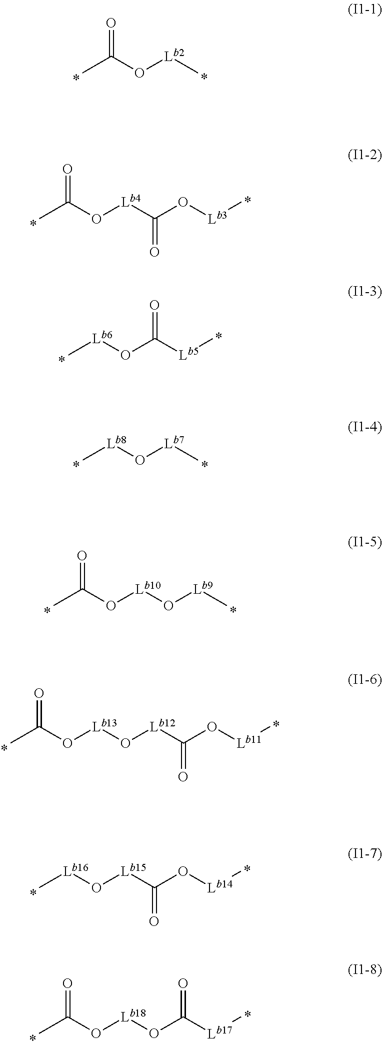

where * at the left side represents a binding site to the ring W¹ and * at the right side represents a binding site to the ring W²,
L^{b2} represents C1-C8 divalent aliphatic hydrocarbon group,
L^{b3} represents a single bond or a C1-C5 divalent aliphatic hydrocarbon group, L^{b4} represents a C1-C6 divalent aliphatic hydrocarbon group provided that the carbon atoms of L^{b3} and L^{b4} amount to 6 or less in total,
L^{b5} and L^{b6} respectively represent a single bond or a C1-C8 divalent aliphatic hydrocarbon group provided that the carbon atoms of L^{b5} and L^{b6} amount to 8 or less in total,
L^{b7} and L^{b8} respectively represent a single bond or a C1-C9 divalent aliphatic hydrocarbon group provided that the carbon atoms of L^{b7} and L^{b8} amount to 9 or less in total,
L^{b9} represents a single bond or a C1-C6 divalent aliphatic hydrocarbon group, L^{b10} represents a C1-C7 divalent aliphatic hydrocarbon group provided that the carbon atoms of L^{b9} and L^{b10} amount to 7 or less in total,
L^{b11} and L^{b13} respectively represent a C1-C4 divalent aliphatic hydrocarbon group, L^{b12} represents a single bond or a C1-C3 divalent aliphatic hydrocarbon group provided that the carbon atoms of L^{b11}, the carbon atoms of L^{b12} and L^{b13} amount to 5 or less in total,
L^{b14} and L^{b16} respectively represent a C1-C6 divalent aliphatic hydrocarbon group, L^{b15} represents a single bond or a C1-C5 divalent aliphatic hydrocarbon group provided that the carbon atoms of L^{b14}, L^{b15} and L^{b16} amount to 7 or less in total,
L^{b17} and L^{b18} respectively represent a C1-C5 divalent aliphatic hydrocarbon group, provided that the carbon atoms of L^{b17} and L^{b18} amount to 6 or less in total,
L^{b2}, L^{b3}, L^{b4}, L^{b5}, L^{b6}, L^{b7}, L^{b8}, L^{b9}, L^{b10}, L^{b11}, L^{b12}, L^{b13}, L^{b14}, L^{b15}, L^{b16}, L^{b17}, L^{b18} and L^{b19} are preferably divalent aliphatic saturated hydrocarbon group such as alkanediyl groups.

Examples of the group represented by formula (I1-1) include the following ones;

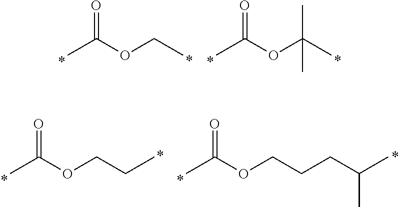

where * at the left side represents a binding site to the ring W¹ and * at the right side represents a binding site to the ring W².

Examples of the group represented by formula (I1-2) include the following ones;

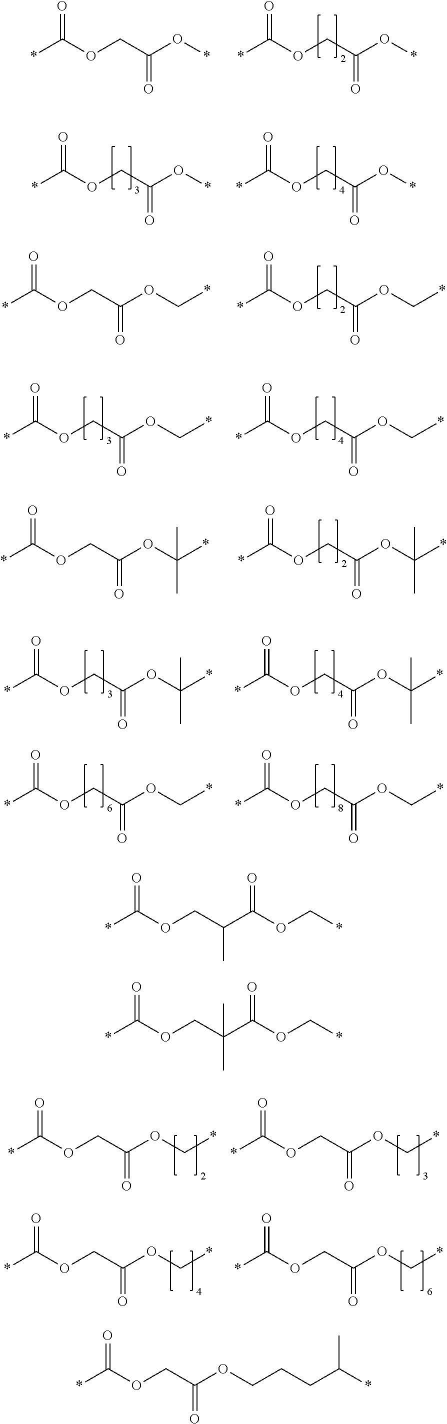

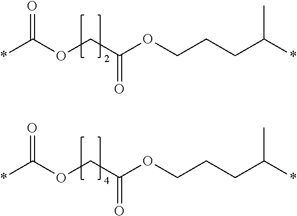

where * at the left side represents a binding site to the ring W¹ and * at the right side represents a binding site to the ring W².

Examples of the group represented by formula (I1-3) include the following ones;

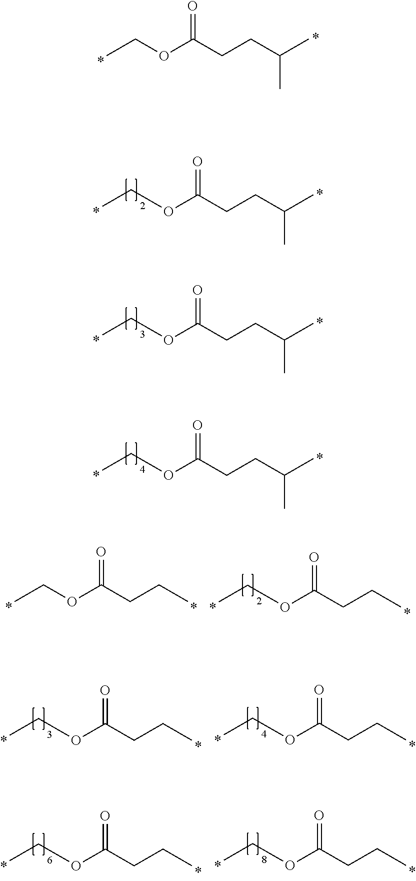

where * at the left side represents a binding site to the ring W¹ and * at the right side represents a binding site to the ring W².

Examples of the group represented by formula (I1-4) include the following ones;

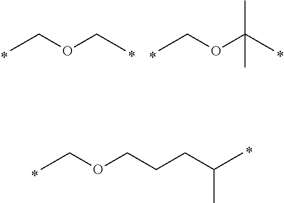

where * at the left side represents a binding site to the ring W¹ and * at the right side represents a binding site to the ring W².

Examples of the group represented by formula (I1-5) include the following ones;

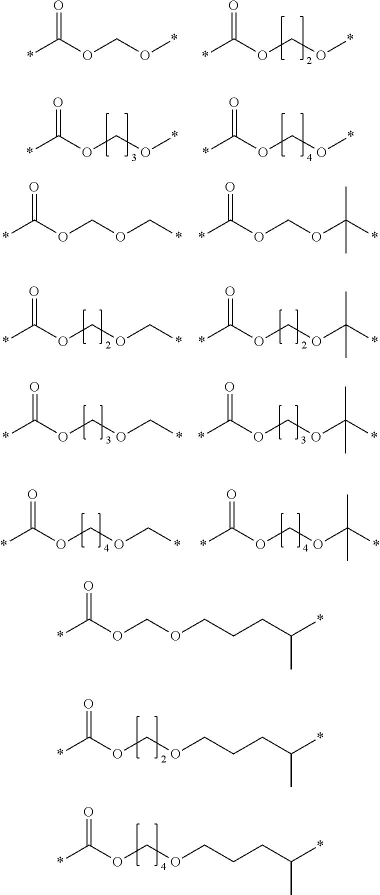

where * at the left side represents a binding site to the ring W¹ and * at the right side represents a binding site to the ring W².

Examples of the group represented by formula (I1-6) include the following ones;

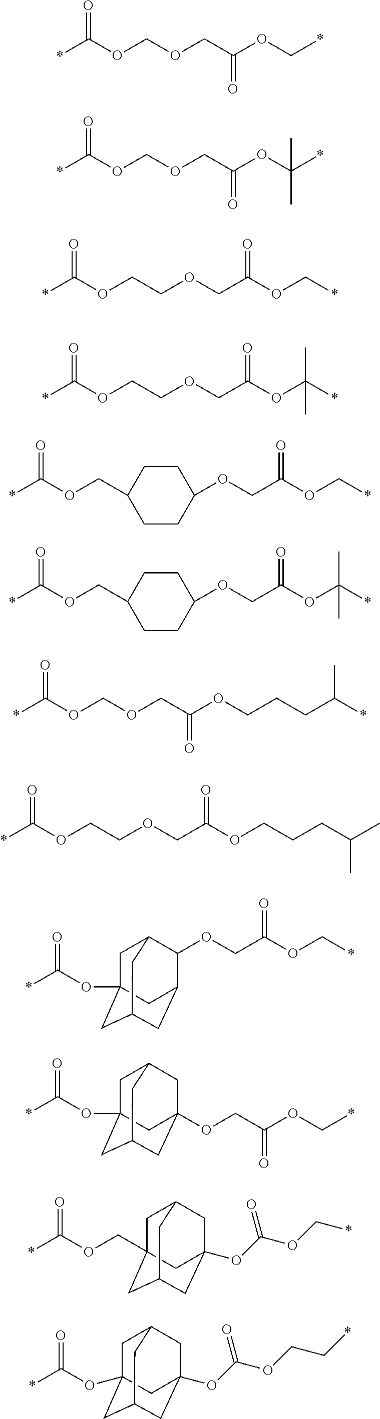

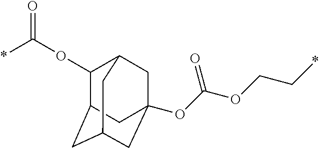 [SMILES: *CCOC(=O)OC12CC3CC(C1)C(OC(*)=O)C(C3)C2]

where * at the left side represents a binding site to the ring W¹ and * at the right side represents a binding site to the ring W².

Examples of the group represented by formula (I1-7) include the following ones;

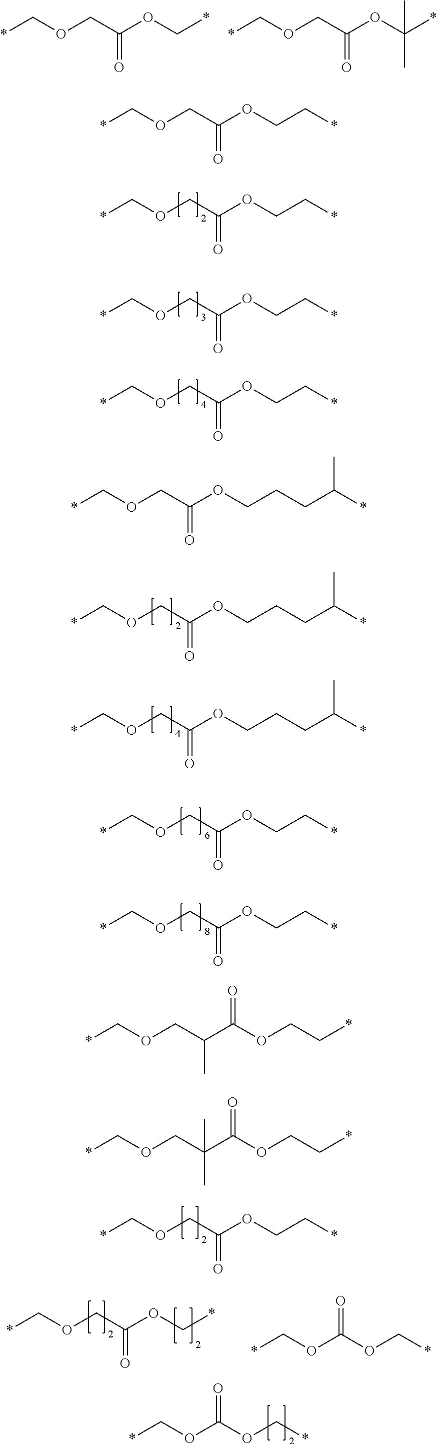

where * at the left side represents a binding site to the ring W¹ and * at the right side represents a binding site to the ring W².

Examples of the group represented by formula (I1-8) include the following ones;

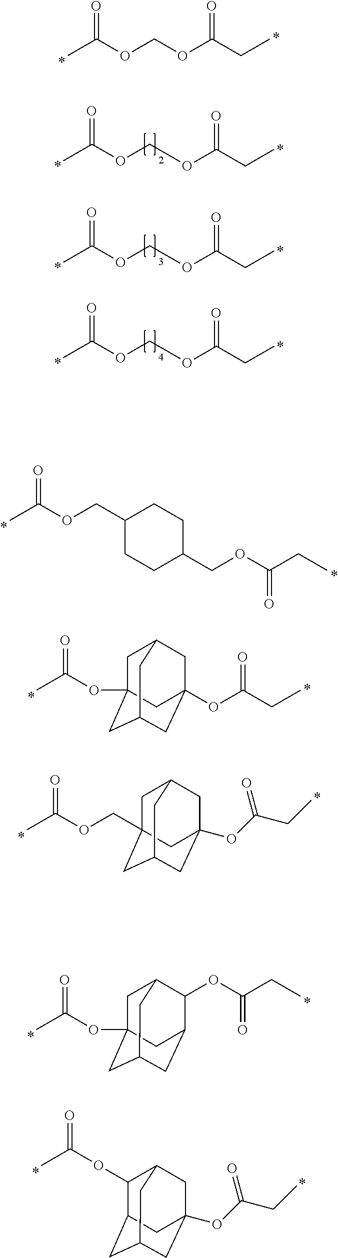

where * at the left side represents a binding site to the ring W¹ and * at the right side represents a binding site to the ring W².

L¹ preferably represents a group represented by any one of formulae (I1-2) and (I1-5), more preferably any one of specific examples of formulae (I1-2) and (I1-5) as mentioned above, still more preferably *—CO—O—CH₂—O— or *—CO—O—CH₂—CO—O— where * represents a binding position to W¹.

Specific examples of COMPOUND (I) include the following ones:

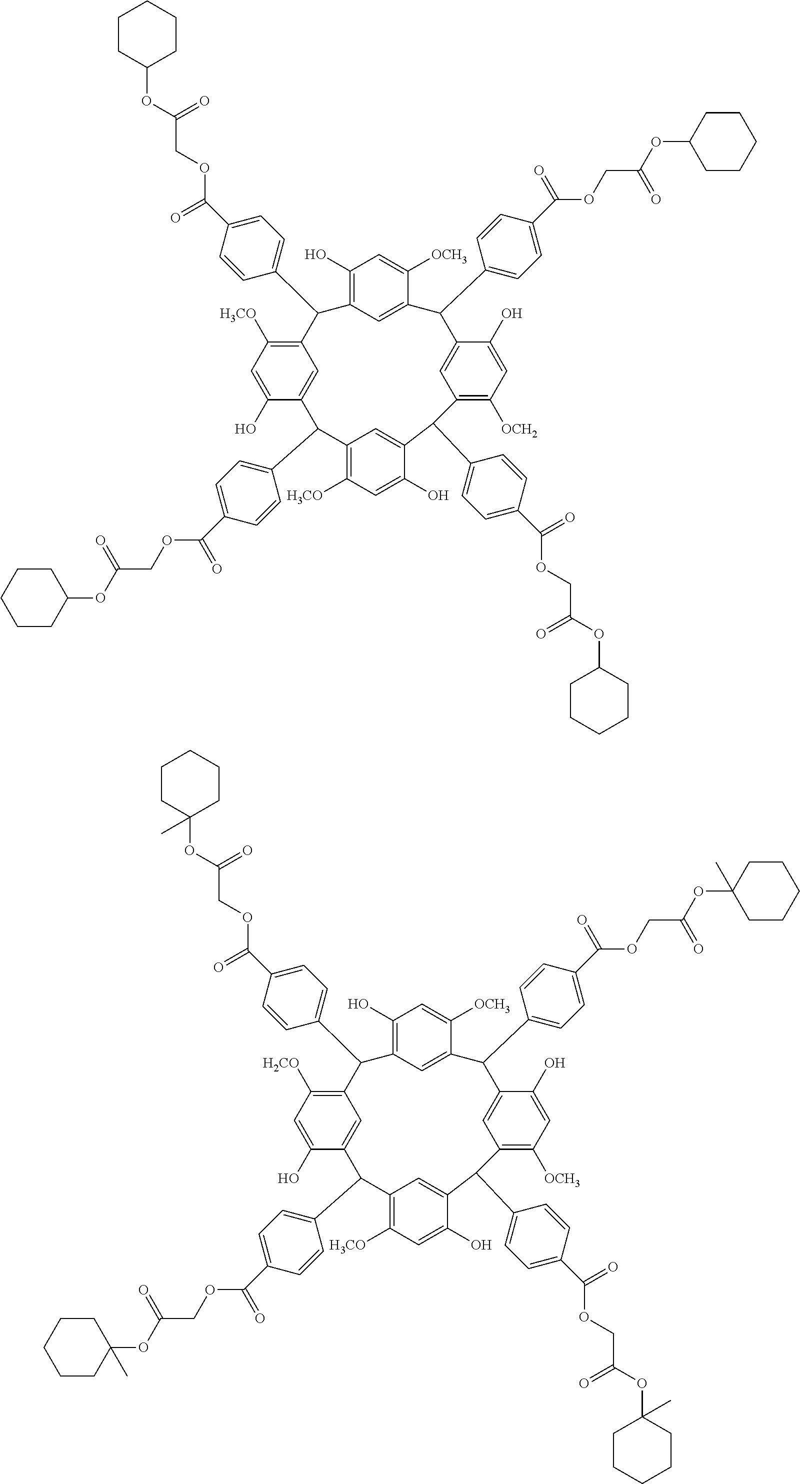

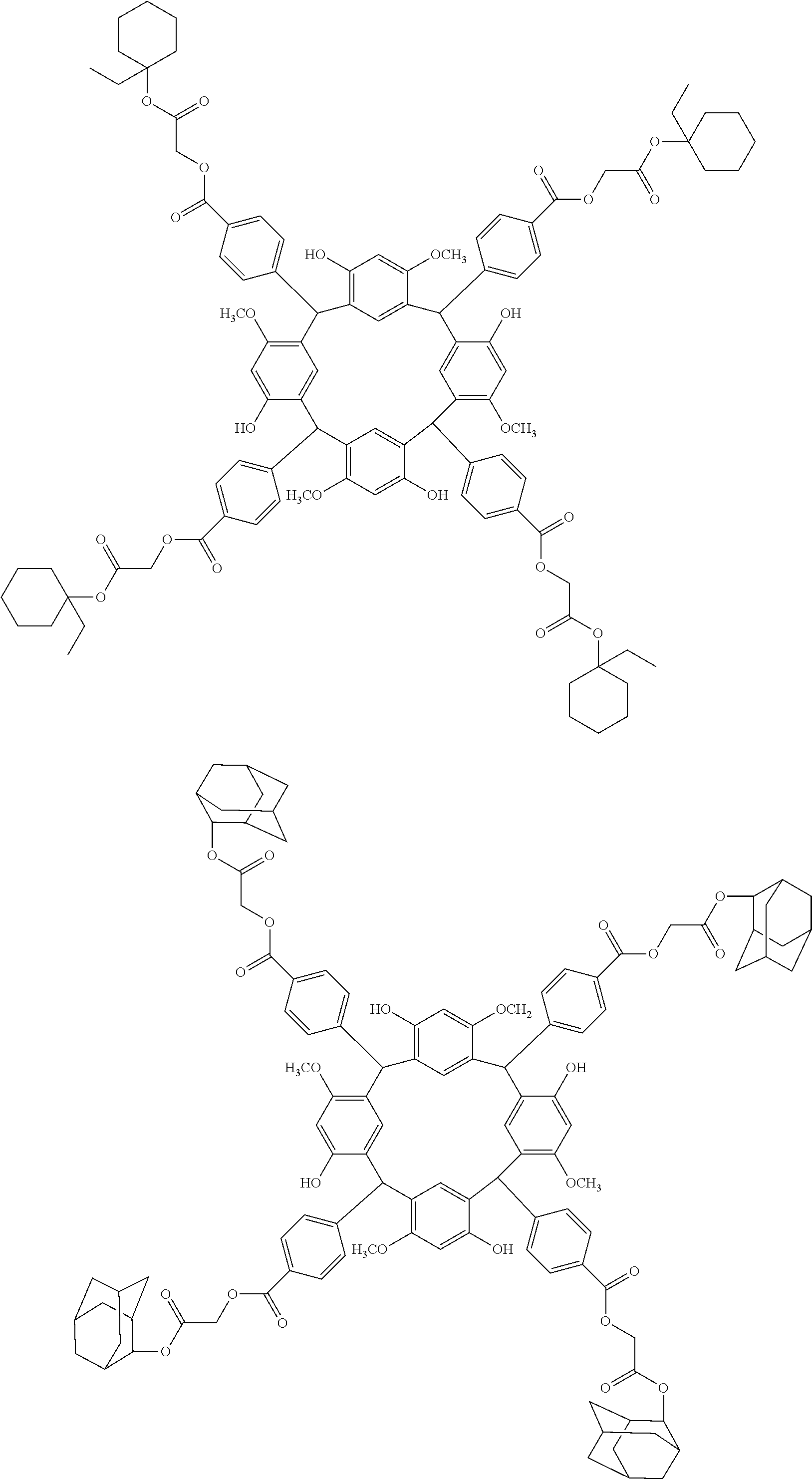

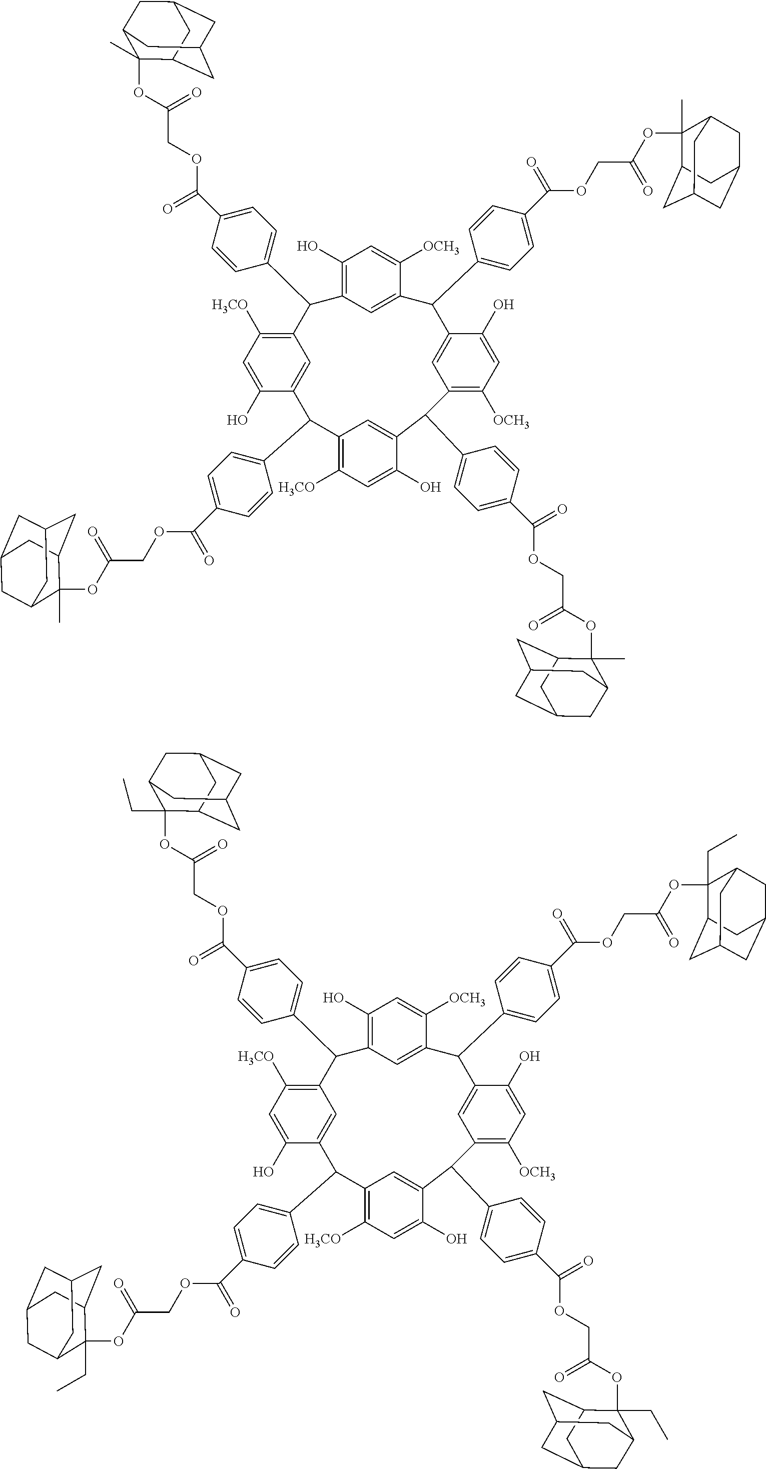 [SMILES: COc1cc(O)c2cc1C(c1ccc(C(=O)OCC(=O)OC3(C)C4CC5CC(C4)CC3C5)cc1)c1cc(c(OC)cc1O)C(c1ccc(C(=O)OCC(=O)OC3(C)C4CC5CC(C4)CC3C5)cc1)c1cc(c(OC)cc1O)C(c1ccc(C(=O)OCC(=O)OC3(C)C4CC5CC(C4)CC3C5)cc1)c1cc(c(OC)cc1O)C2c1ccc(C(=O)OCC(=O)OC2(C)C3CC4CC(C3)CC2C4)cc1 ; CCC1(OC(=O)COC(=O)c2ccc(C3c4cc(c(OC)cc4O)C(c4ccc(C(=O)OCC(=O)OC5(CC)C6CC7CC(C6)CC5C7)cc4)c4cc(c(OC)cc4O)C(c4ccc(C(=O)OCC(=O)OC5(CC)C6CC7CC(C6)CC5C7)cc4)c4cc(c(OC)cc4O)C(c4ccc(C(=O)OCC(=O)OC5(CC)C6CC7CC(C6)CC5C7)cc4)c4cc3c(OC)cc4O)cc2)C2CC3CC(C2)CC1C3]

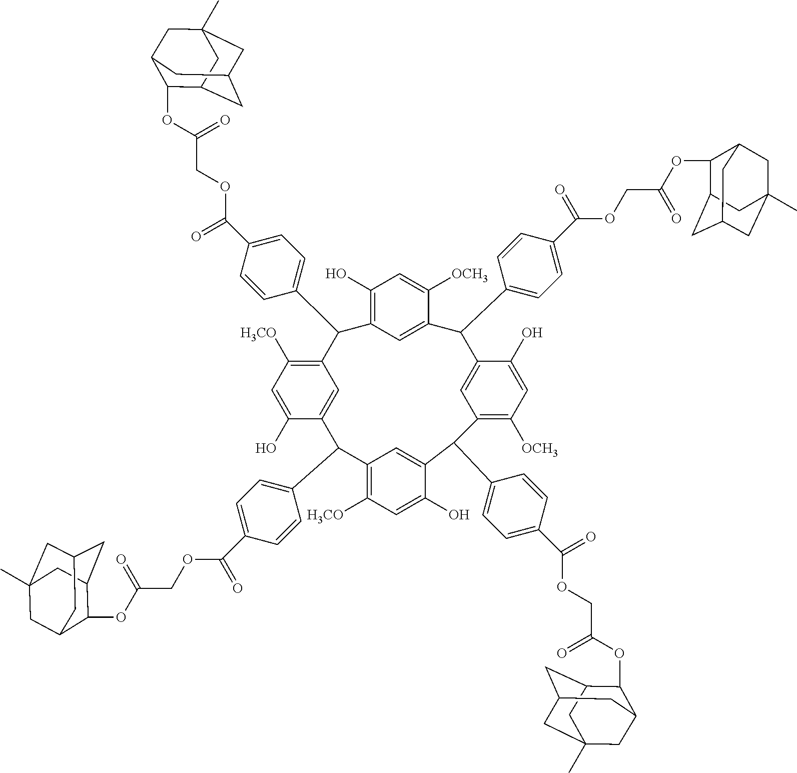

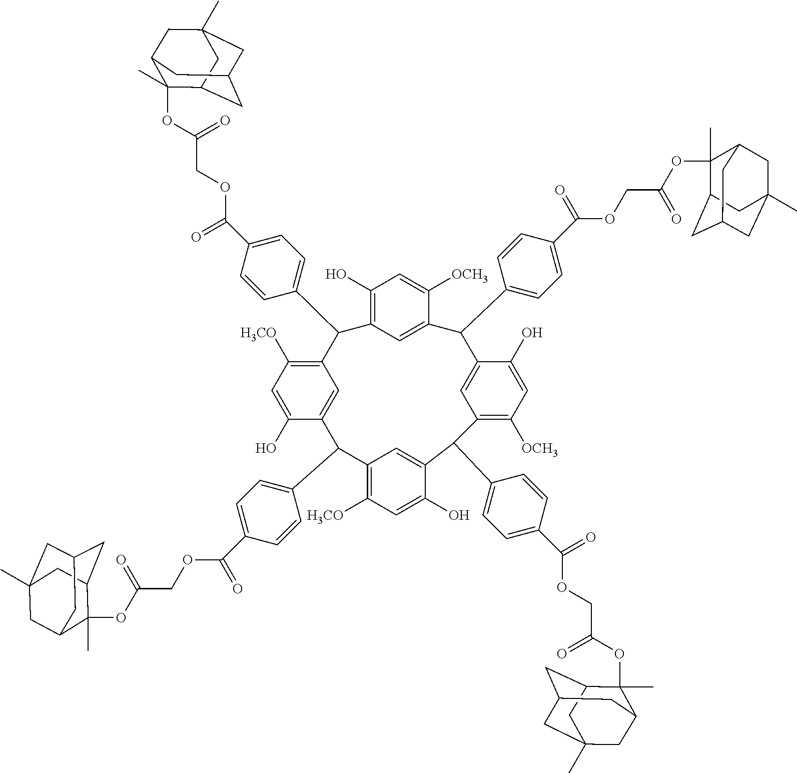

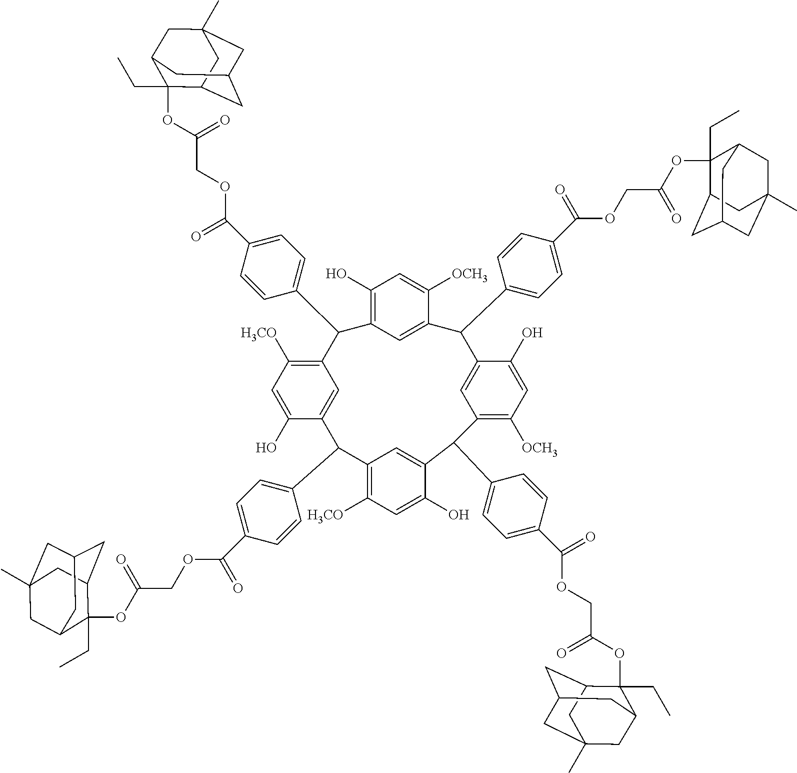

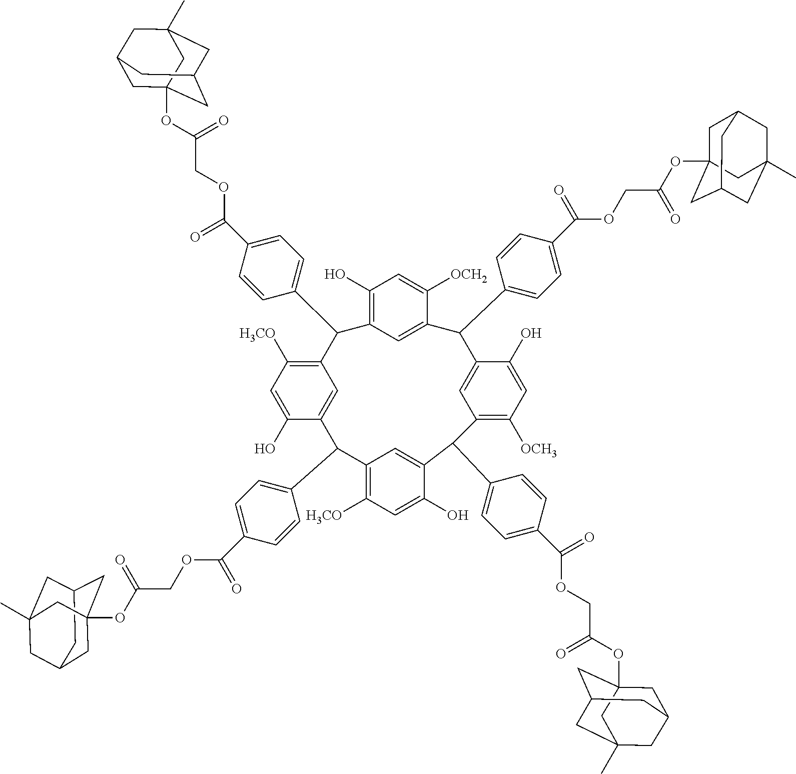

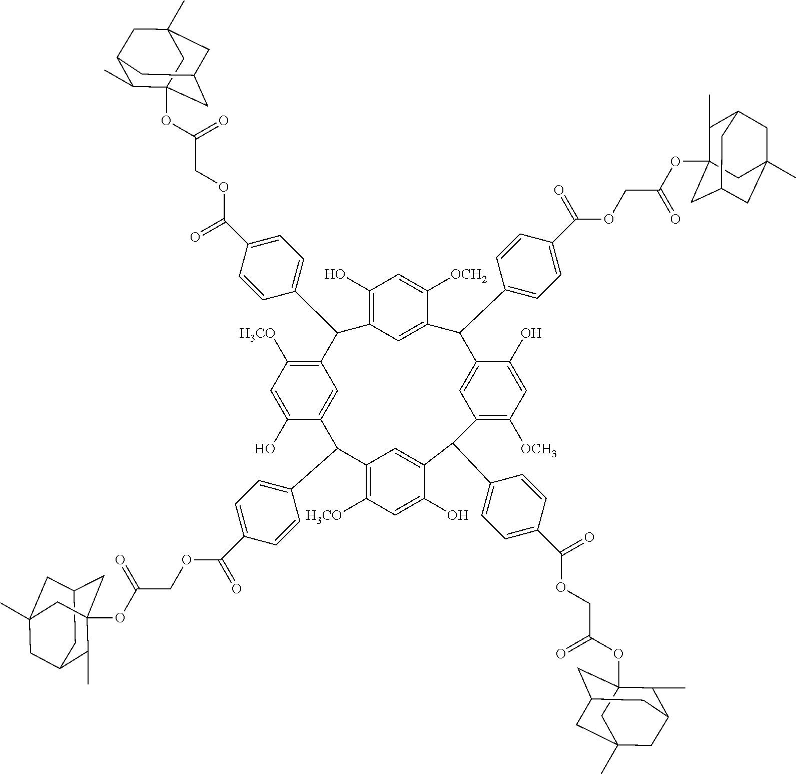

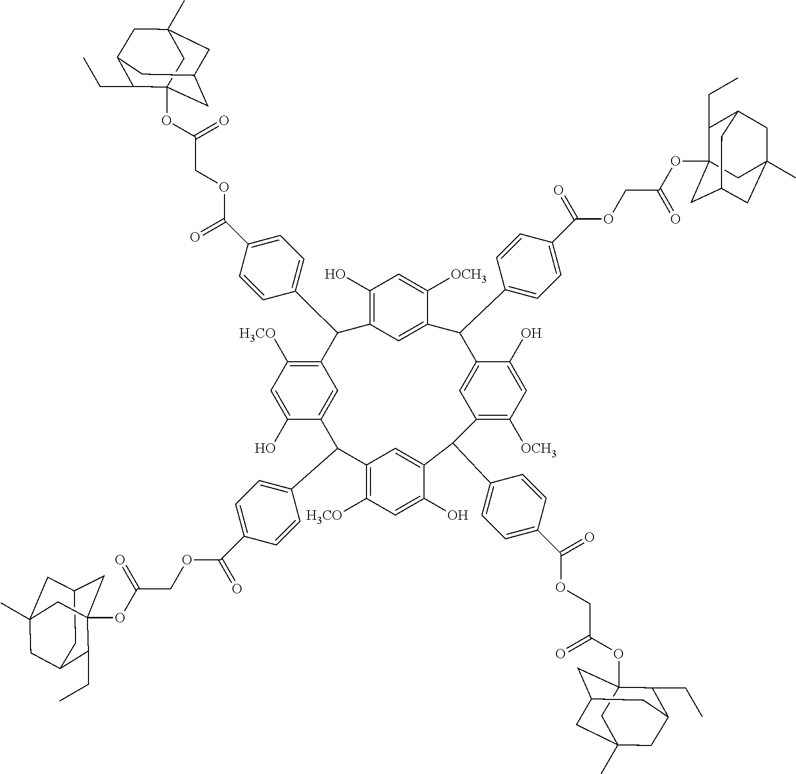

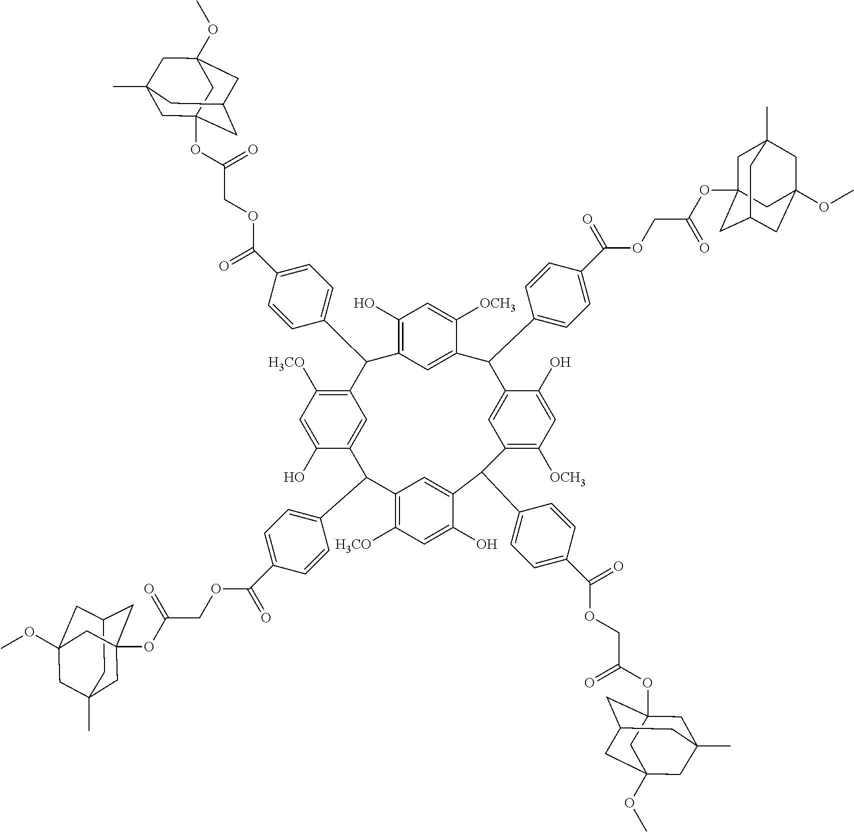

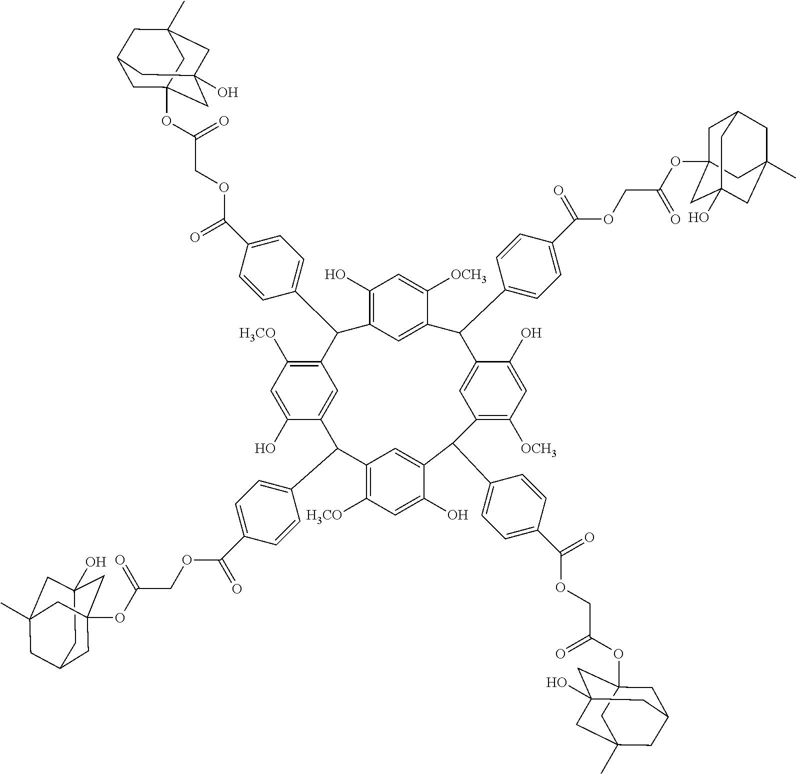

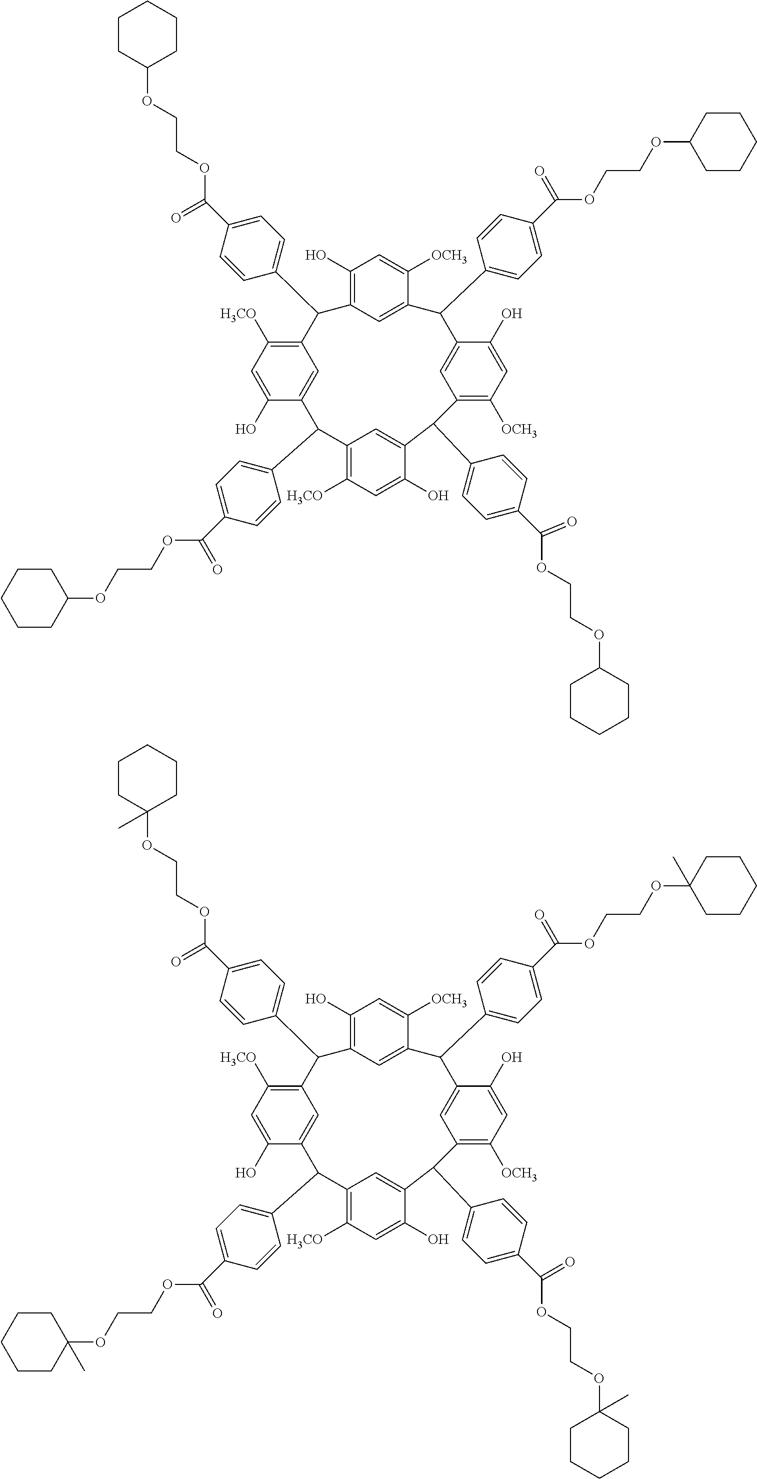 [SMILES: COc1cc(O)c2cc1C(c1ccc(C(=O)OCCOC3CCCCC3)cc1)c1cc(c(OC)cc1O)C(c1ccc(C(=O)OCCOC3CCCCC3)cc1)c1cc(c(OC)cc1O)C(c1ccc(C(=O)OCCOC3CCCCC3)cc1)c1cc(c(OC)cc1O)C2c1ccc(C(=O)OCCOC2CCCCC2)cc1 ; COc1cc(O)c2cc1C(c1ccc(C(=O)OCCOC3(C)CCCCC3)cc1)c1cc(c(OC)cc1O)C(c1ccc(C(=O)OCCOC3(C)CCCCC3)cc1)c1cc(c(OC)cc1O)C(c1ccc(C(=O)OCCOC3(C)CCCCC3)cc1)c1cc(c(OC)cc1O)C2c1ccc(C(=O)OCCOC2(C)CCCCC2)cc1]

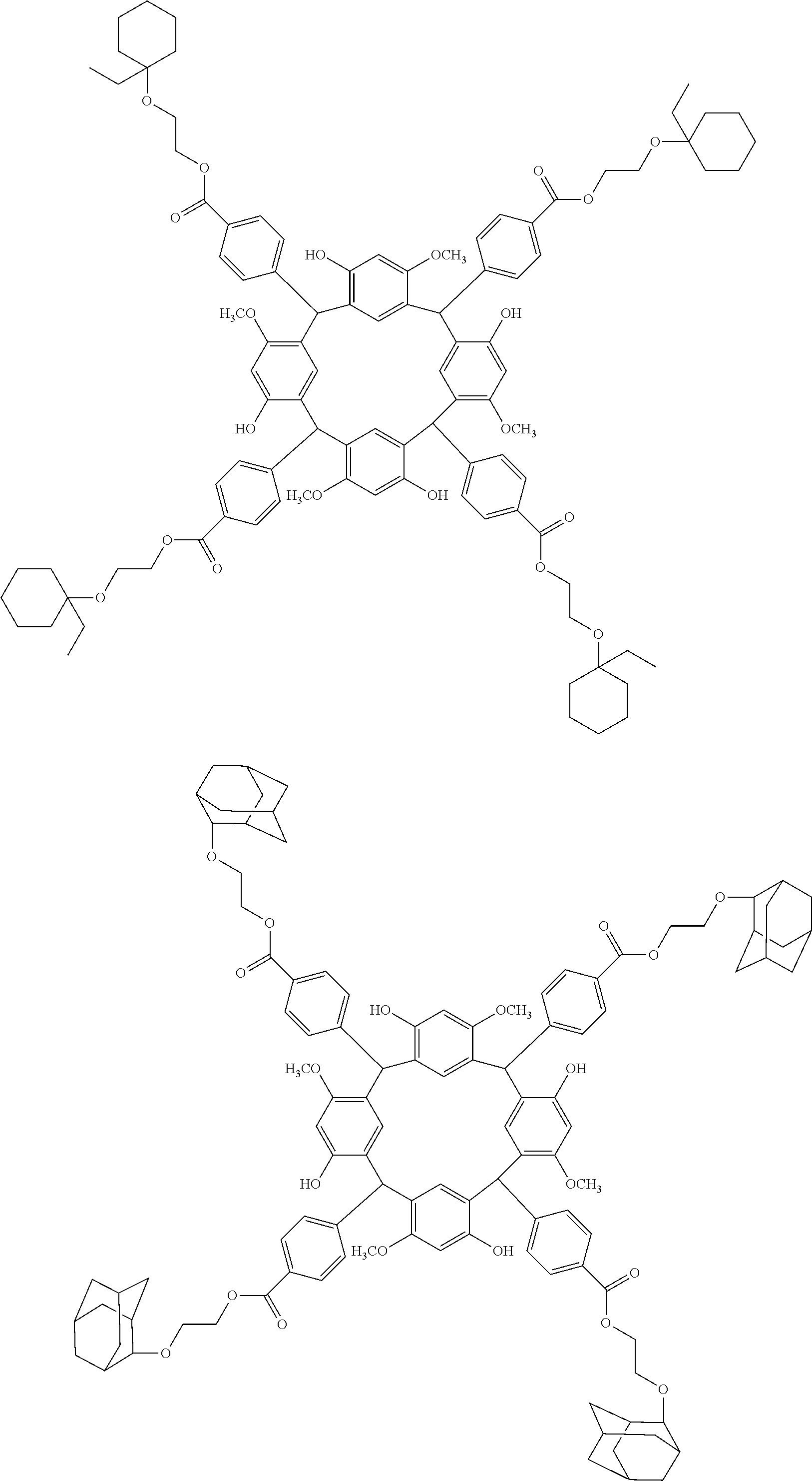 [SMILES: CCC1(OCCOC(=O)c2ccc(C3c4cc(c(OC)cc4O)C(c4ccc(C(=O)OCCOC5(CC)CCCCC5)cc4)c4cc(c(OC)cc4O)C(c4ccc(C(=O)OCCOC5(CC)CCCCC5)cc4)c4cc(c(OC)cc4O)C(c4ccc(C(=O)OCCOC5(CC)CCCCC5)cc4)c4cc3c(OC)cc4O)cc2)CCCCC1 ; COc1cc(O)c2cc1C(c1ccc(C(=O)OCCOC3C4CC5CC(C4)CC3C5)cc1)c1cc(c(OC)cc1O)C(c1ccc(C(=O)OCCOC3C4CC5CC(C4)CC3C5)cc1)c1cc(c(OC)cc1O)C(c1ccc(C(=O)OCCOC3C4CC5CC(C4)CC3C5)cc1)c1cc(c(OC)cc1O)C2c1ccc(C(=O)OCCOC2C3CC4CC(C3)CC2C4)cc1]

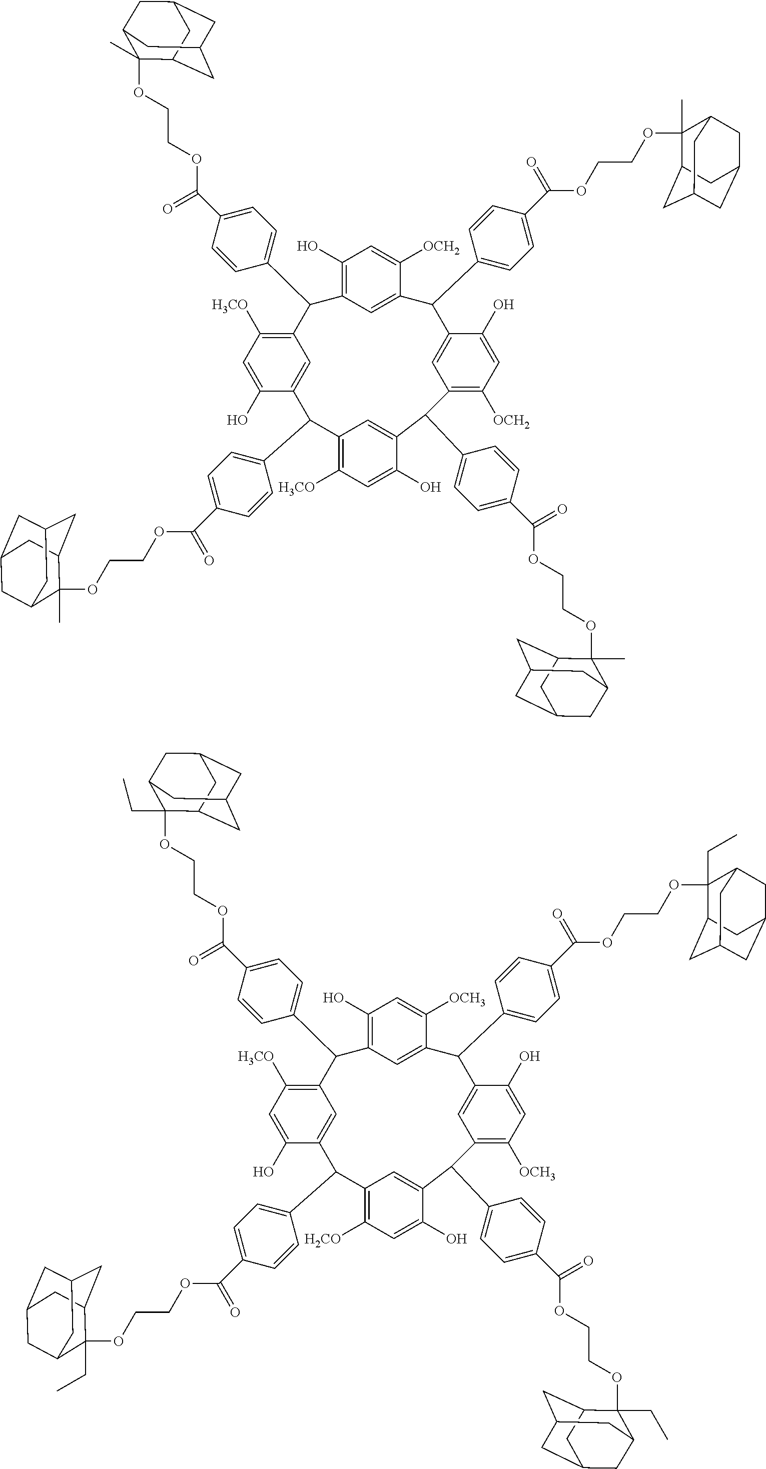

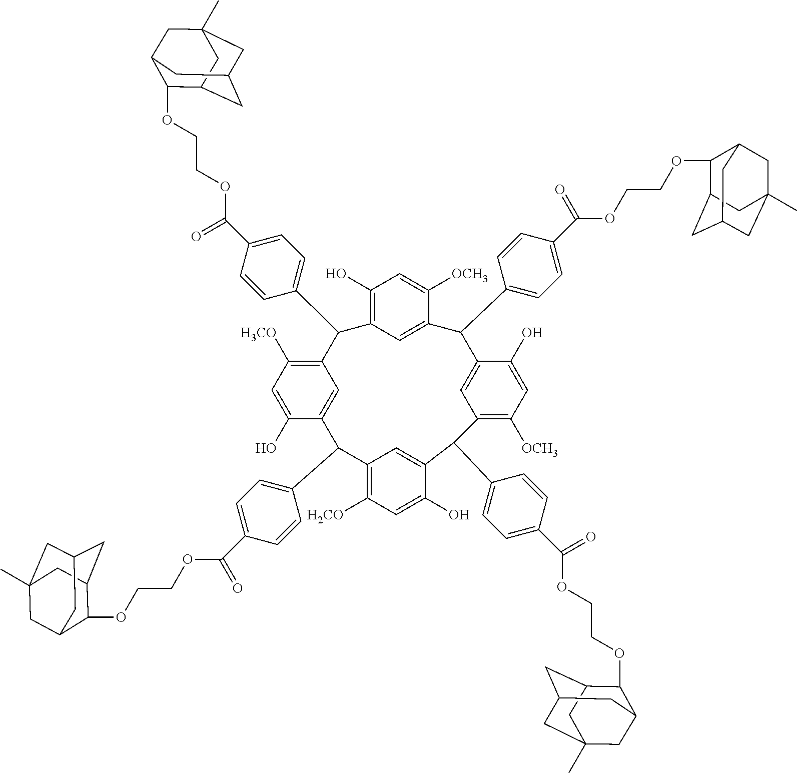

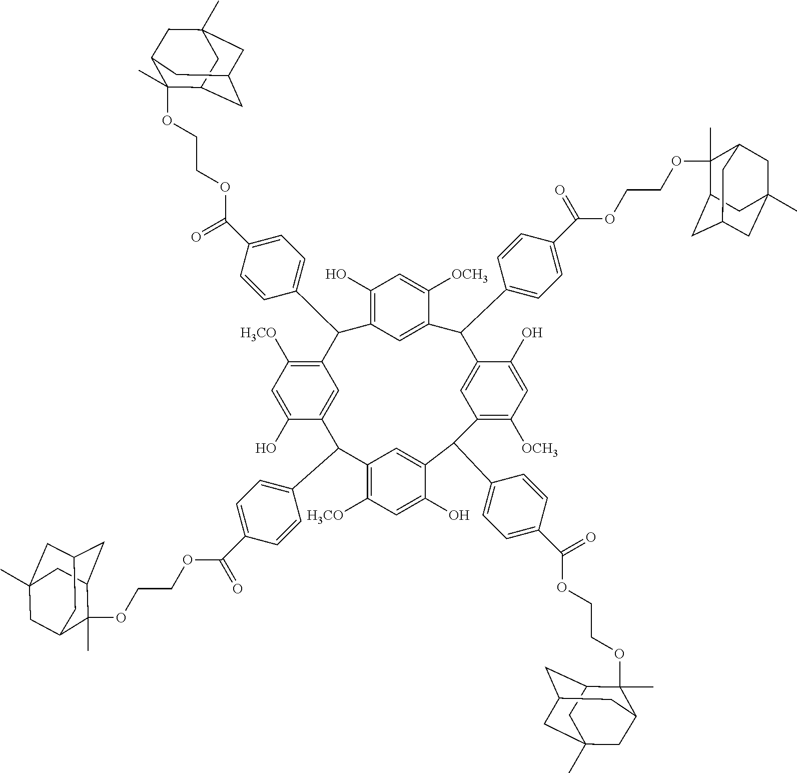

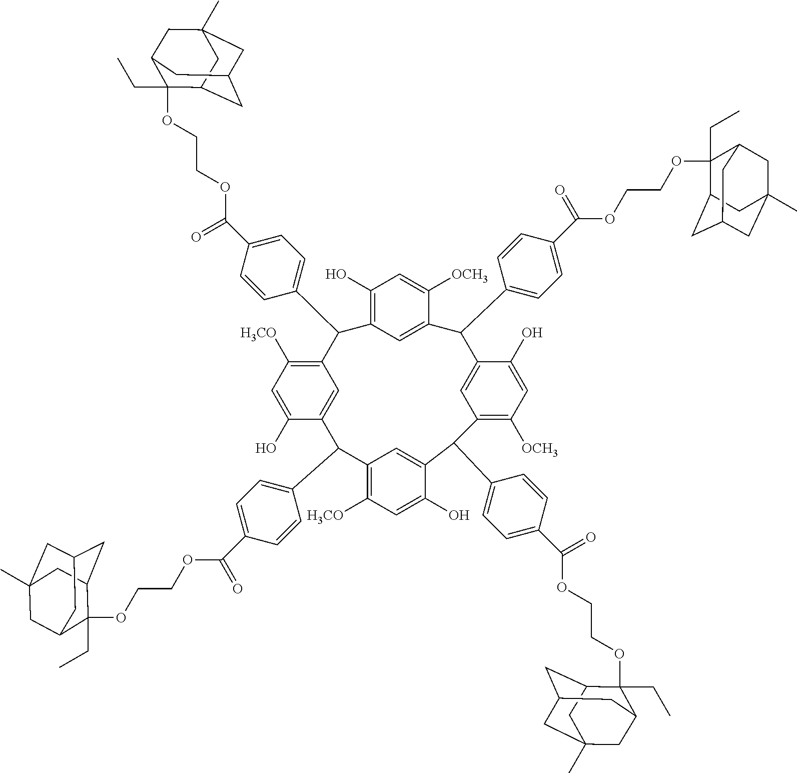

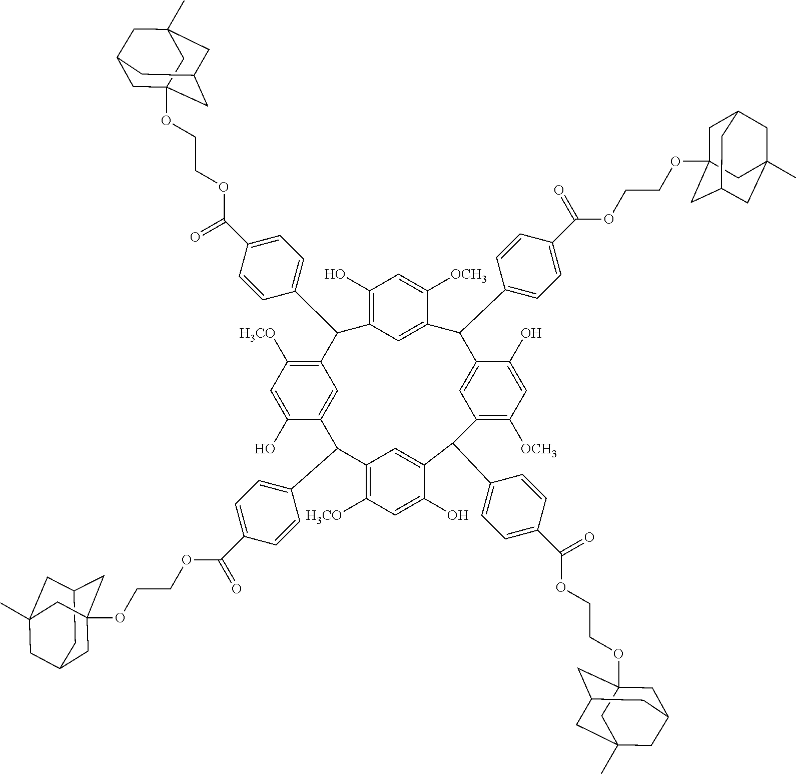

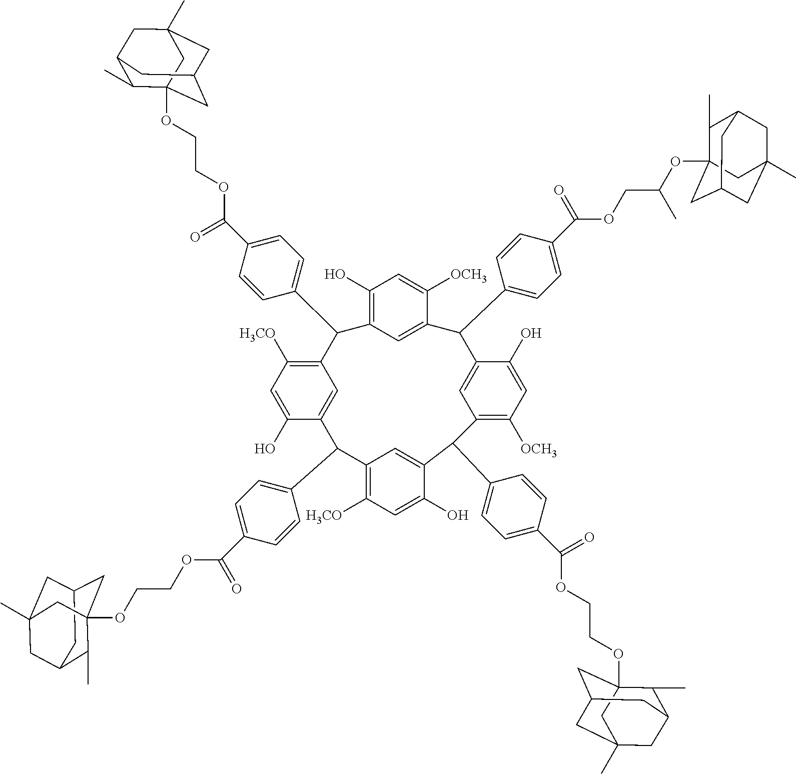

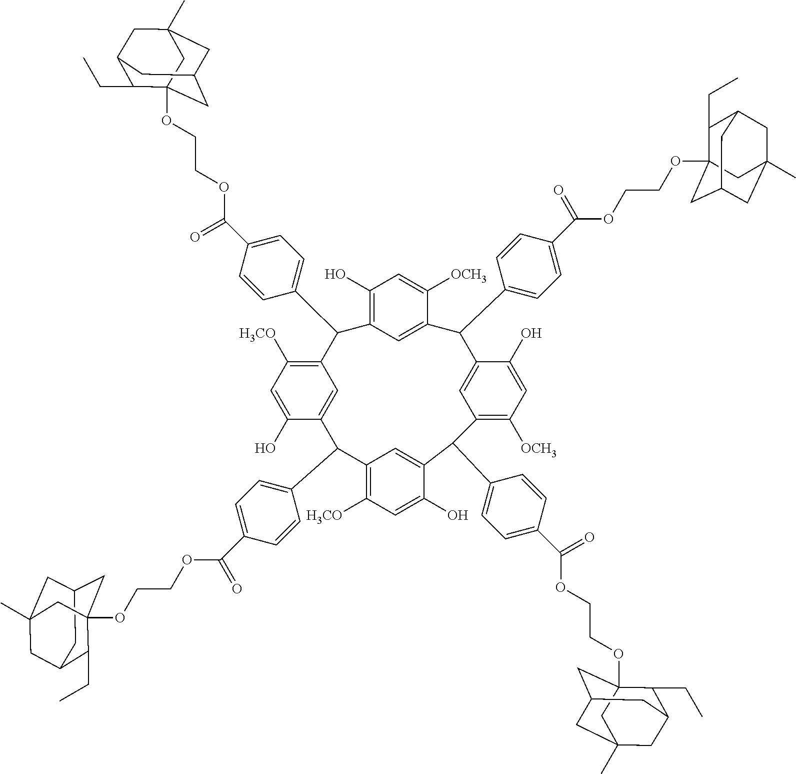

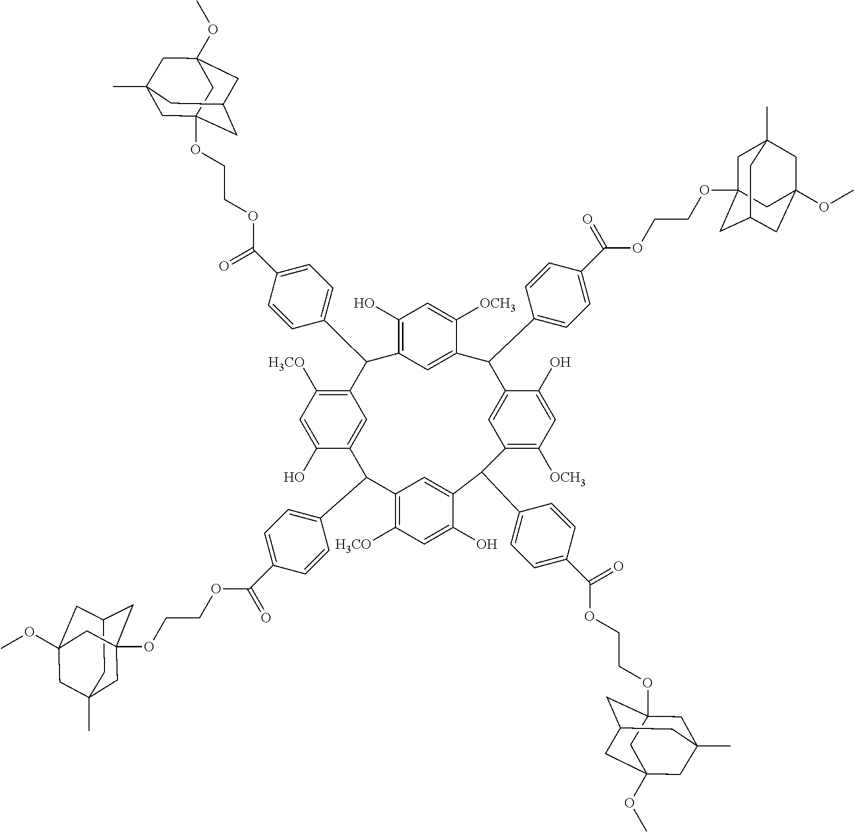

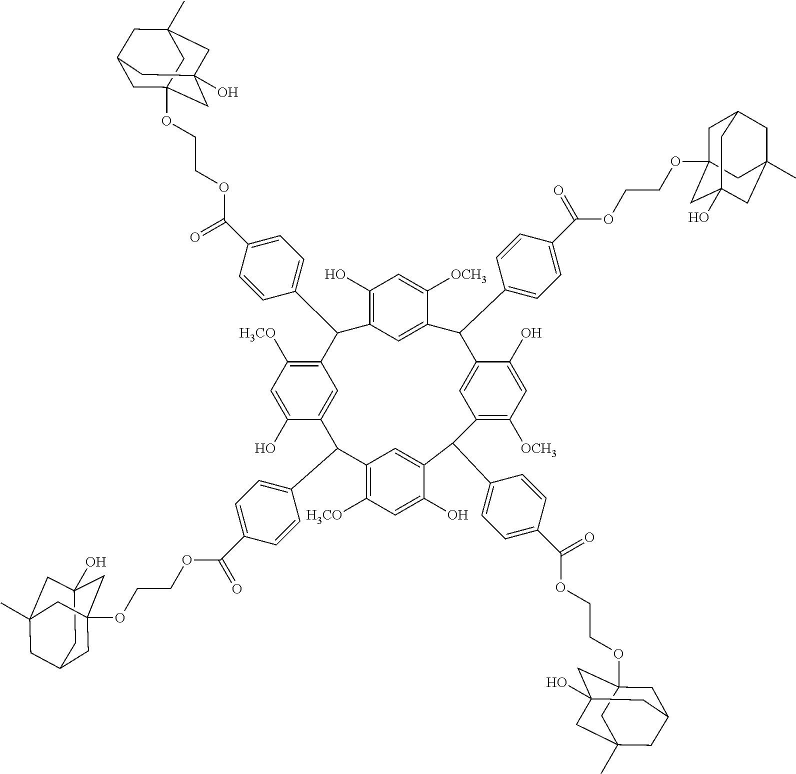

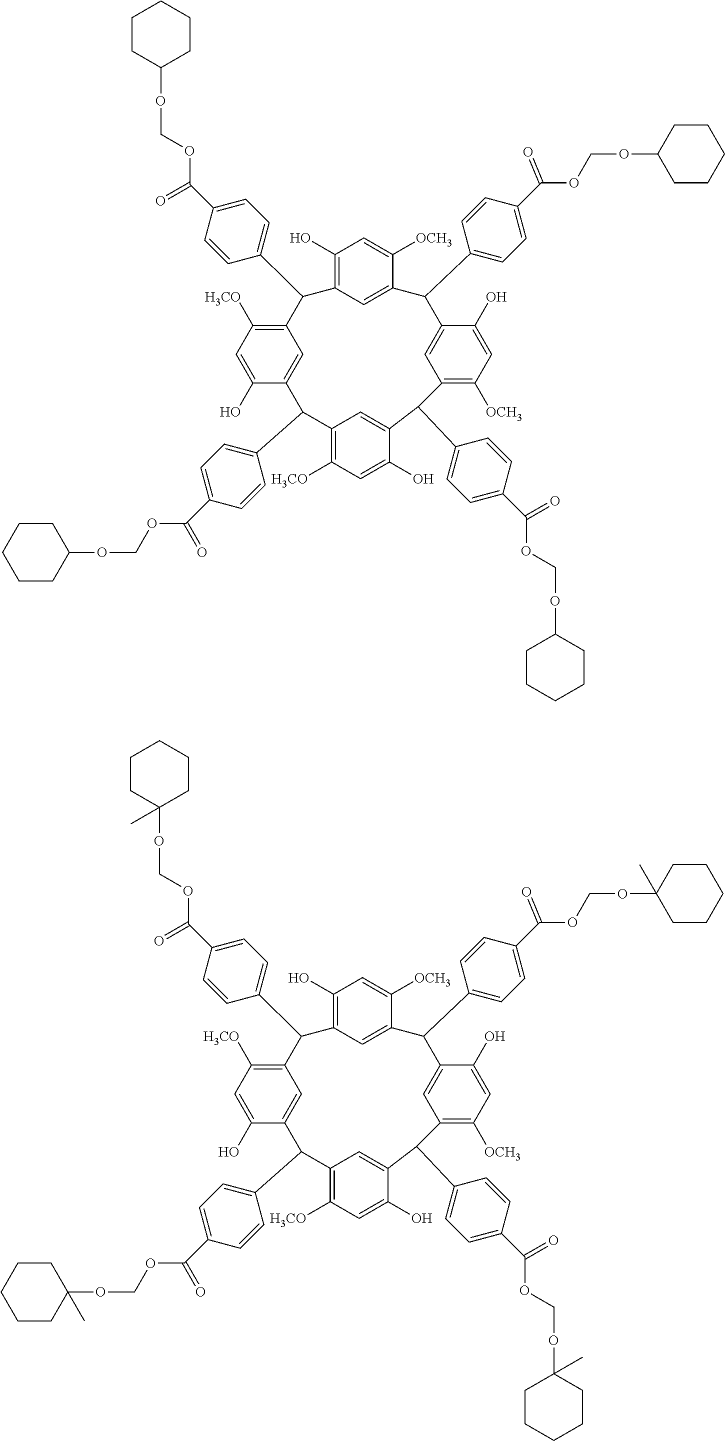 [SMILES: COc1cc(O)c2cc1C(c1ccc(C(=O)OCOC3CCCCC3)cc1)c1cc(c(OC)cc1O)C(c1ccc(C(=O)OCOC3CCCCC3)cc1)c1cc(c(OC)cc1O)C(c1ccc(C(=O)OCOC3CCCCC3)cc1)c1cc(c(OC)cc1O)C2c1ccc(C(=O)OCOC2CCCCC2)cc1 ; COc1cc(O)c2cc1C(c1ccc(C(=O)OCOC3(C)CCCCC3)cc1)c1cc(c(OC)cc1O)C(c1ccc(C(=O)OCOC3(C)CCCCC3)cc1)c1cc(c(OC)cc1O)C(c1ccc(C(=O)OCOC3(C)CCCCC3)cc1)c1cc(c(OC)cc1O)C2c1ccc(C(=O)OCOC2(C)CCCCC2)cc1]

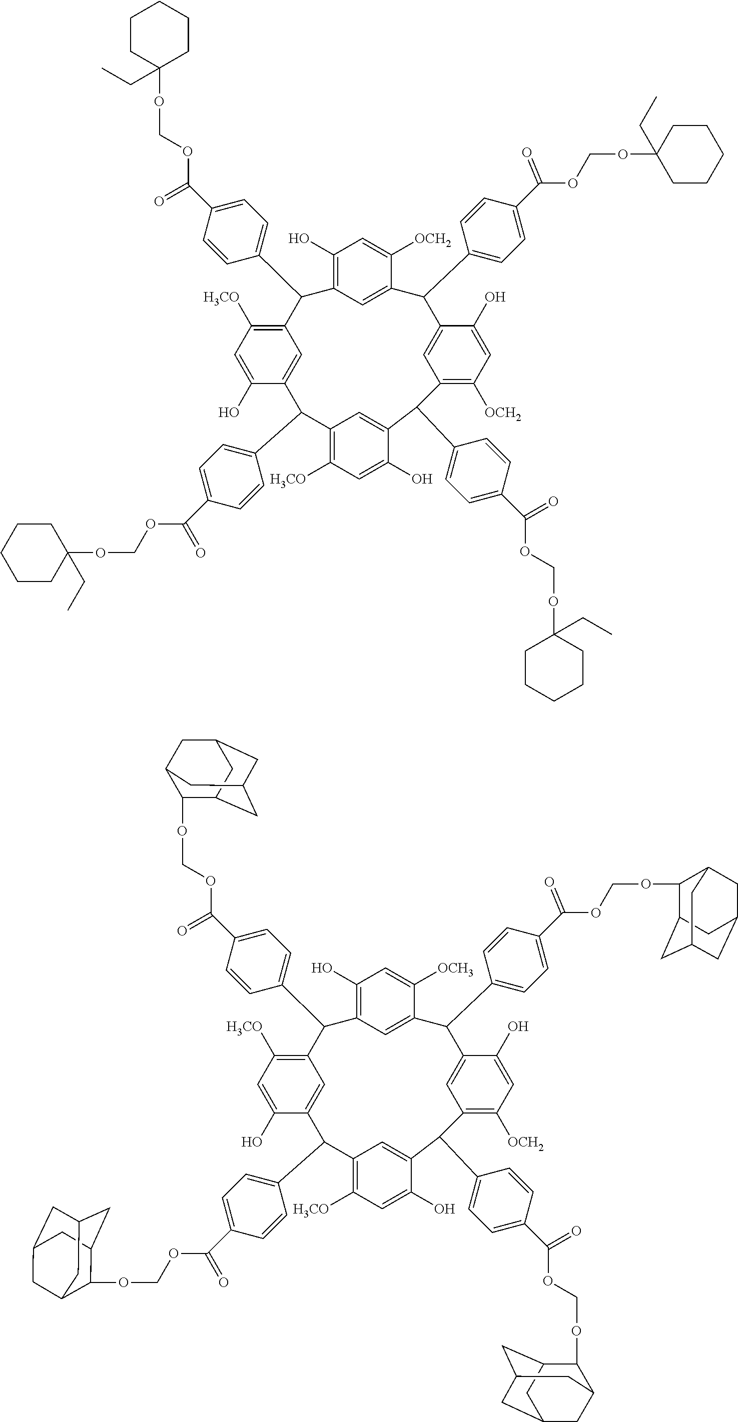

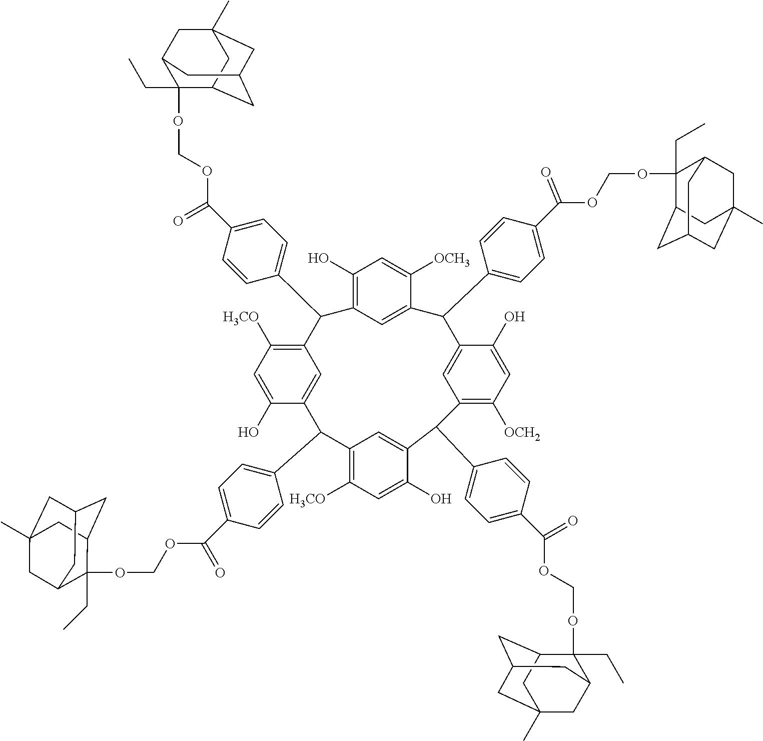

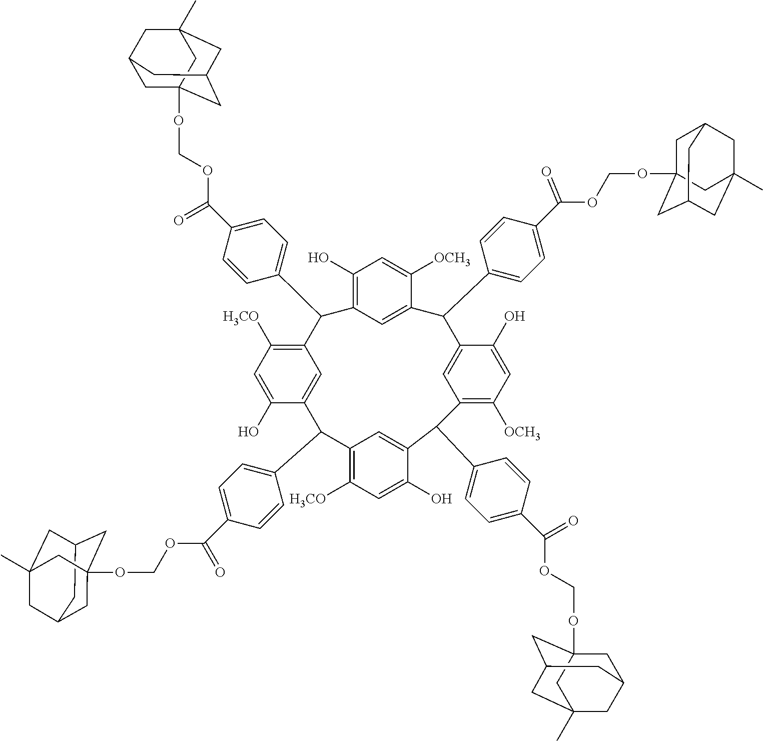

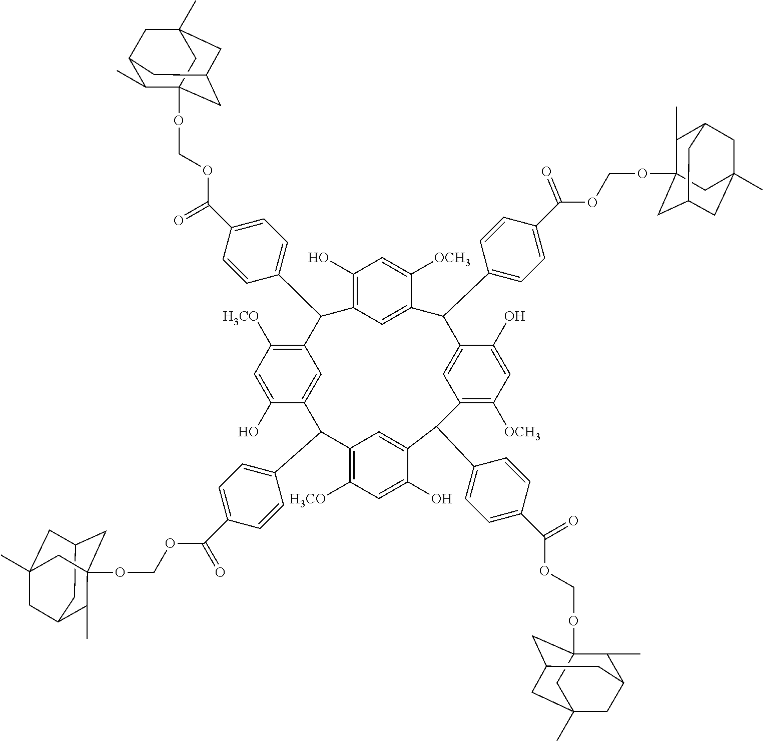

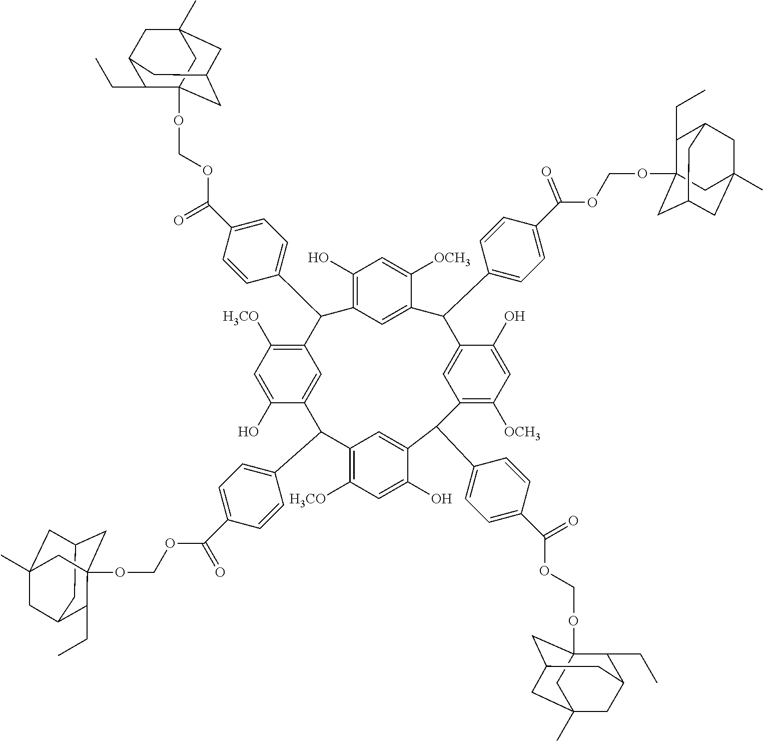

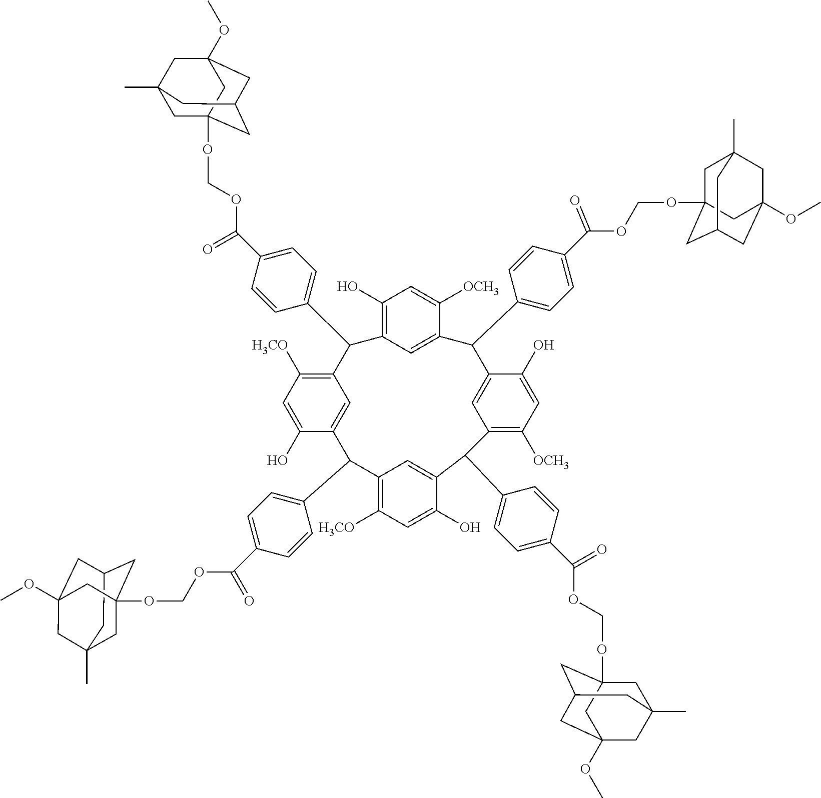

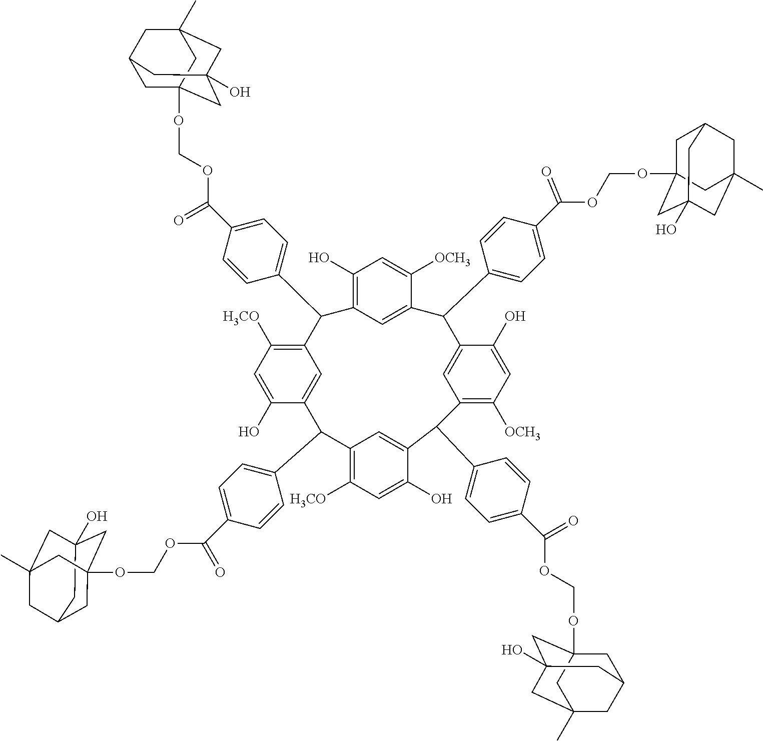

COMPOUND (I) is preferably a compound represented by formula (I) wherein R¹, R², R⁴, R⁵, R⁷, R⁸, R¹⁰ and R¹¹ are independently a hydrogen atom or a C1-C4 alkyl group, and R³, R⁶, R⁹ and R¹² independently represent a group represented by the formula (II) where W¹ is a C6-C10 aromatic hydrocarbon ring, W² is an adamantyl group or a cyclohexyl group, and L¹ is a group represented by formula (I1-2) or (I1-5).

COMPOUND (I) can be prepared by a known method such as mentioned in JP2010-159241A1 or JP2010-285376A1.

COMPOUND (I) wherein R³, R⁶, R⁹ and R¹² are the groups represented by the formula (II), R¹, R⁴, R⁷ and R¹⁰ are the same group, R², R⁵, R⁸ and R¹¹ are the same group, and L¹ represents —CO—O—CH₂—CO—O—, which compound is represented by formula (Ia) in the following reaction formula, can be produced by reacting the compound represented by the formula (Ia-c) with the compound represented by the formula (Ia-d) in the presence of a basic catalyst in a solvent such as anhydrous N-methyl-2-pyrrolidone;

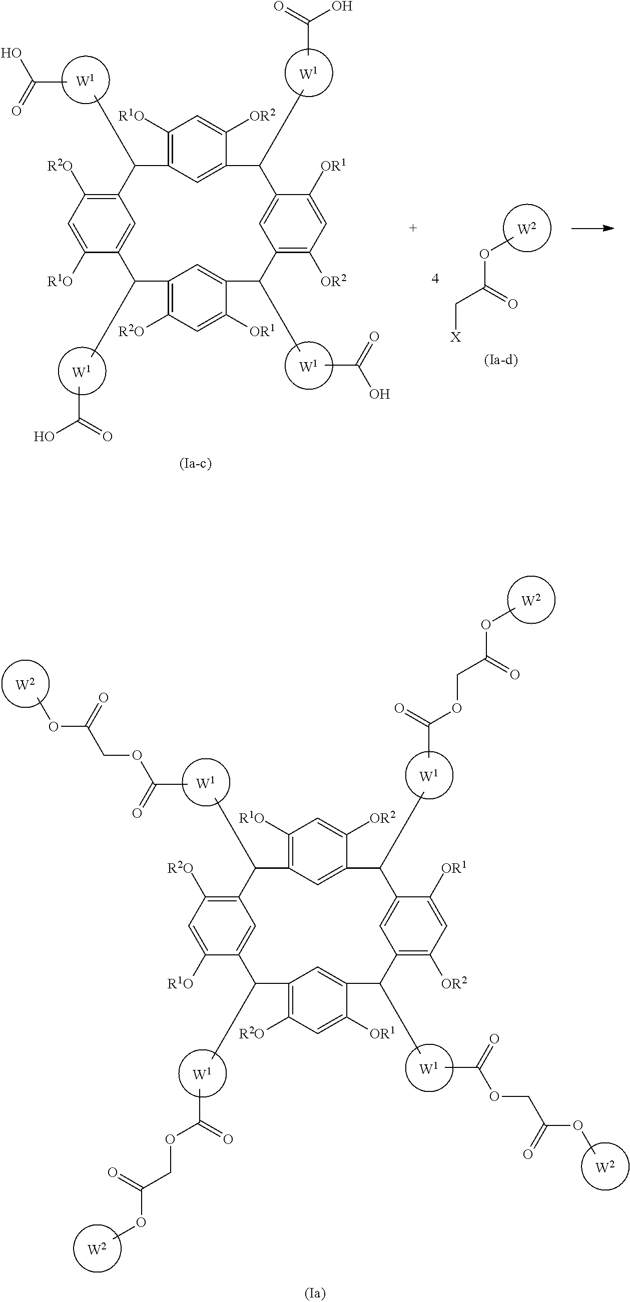

where R¹, R², the ring W¹ and the ring W² are the same as defined above.

The basic catalyst includes triethylamine, sodium hydrogen carbonate, or diazabicycloundecene.

The compound represented by the formula (Ia-d) is available on the market, which includes ethyladamantyl bromoacetate, methyladamantyl bromoacetate, ethylcyclohexyl and bromoacetate.

The compound represented by the formula (Ia-c) can be produced by reacting the compound represented by the formula (Ia-a) with the compound represented by the formula (Ia-b) in the presence of an acid catalyst in a solvent such as anhydrous dichloromethane.

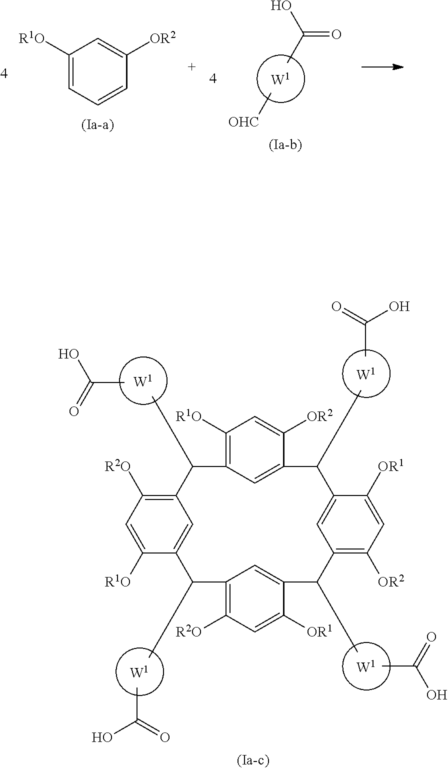

wherein R¹, R², and the ring W¹ are the same as defined above. Examples of the acid catalyst include borontrifluoride etheride.

The compound represented by the formula (Ia-a) is available on the market, which includes (C1-C20alkoxy)benzenes such as 3-methoxybenzene.

The compound represented by the formula (Ia-b) is available on the market, which includes 4-formylbenzoic acid.

The content of COMPOUND (I) in the photoresist composition of the present invention is usually 1 to 95% by weight, preferably 5 to 90% by weight, more preferably 70 to 90% by weight, of the total amount of the solid component.

If the photoresist composition is free from the resin as described later, the content of COMPOUND (I) is still more preferably 70 to 90% by weight, of the total amount of the solid component . Herein, “solid component” means components other than solvent in the photoresist composition. The content can be measured according to known analytical methods such as liquid chromatography or gas chromatography.

The photoresist composition of the present invention comprises the salt represented by the formula (B1):

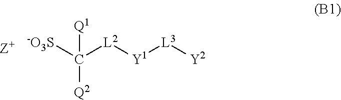

wherein Q¹ and Q² independently represent a fluorine atom or a C1-C6 perfluoroalkyl group,
L² represents a single bond or a C1-C17 divalent saturated hydrocarbon group in which a methylene group is optionally replaced by an oxygen atom, a carbonyl group, or —NR′— and in which a hydrogen atom is optionally replaced by a fluorine atom, and R′ represents a hydrogen atom or a C1-C4 alkyl group,
Y¹ represents a single bond or a C3-C18 divalent alicyclic hydrocarbon group in which a methylene group is optionally replaced by an oxygen atom, a carbonyl group, or a sulfonyl group and in which a hydrogen atom is optionally replaced by a substituent,
L³ represents a single bond or a C1-C17 divalent hydrocarbon group in which a methylene group is optionally replaced by an oxygen atom or a carbonyl group,
Y² represents a C3-C18 alicyclic hydrocarbon group in which a methylene group is optionally replaced by an oxygen atom, a sulfonyl group or a carbonyl group and in which a hydrogen atom is optionally replaced by a substituent, and
Z⁺ represents an organic cation.

The salt represented by the formula (B1) usually acts as an acid generator.

Examples of the C1-C6 perfluoroalkyl group represented by Q¹ and Q² include a trifluoromethyl group, a pentafluoroethyl group, a heptafluoropropyl group, a nonafluorobutyl group, an undecafluoropentyl group and a tridecafluorohexyl group, and a trifluoromethyl group is preferable.

Q¹ and Q² independently preferably represent a fluorine atom or a trifluoromethyl group, and Q¹ and Q² are more preferably fluorine atoms, because such photoresist composition can provide the photoresist pattern with wider forcal margin.

The divalent hydrocarbon group represented by L² and L³ may be a linear alkanediyl group, a branched alkanediyl group, divalent monocyclic or polycyclic hydrocarbon group, or a combination of these groups, examples of which include

a linear alkanediyl group such as a methylene group, an ethylene group, a propane-1,3-diyl group, a butane-1,4-diyl group, a pentane-1,5-diyl, a hexane-1,6-diyl group, a heptane-1,7-diyl grouP, an octane-1,8-diyl group, a nonane-1,9-diyl group, a decane-1,10-diyl group, an undecane-1,11-diyl group, a dodecane-1,12-diyl group, a tridecane-1,13-diyl group, a tetradecane-1,14-diyl group, a pentadecane-1,15-diyl group, a hexadecane-1,16-diyl group and a heptadecane-1,17-diyl group,

a branched chain alkanediyl group formed by replacing a hydrogen atom of the above-mentioned linear alkanediyl group by a C1-C4 alkyl group, such as a butane-1,3-diyl group, 2-methyl-propane-1,3-diyl group, 1,1-dimethylethylene group, pentane-1,4-diyl group and 2-methyl-butane-1,4-diyl group;

monocyclic saturated hydrocarbon group such as cycloalkanediyl group, e.g. a cyclobutane-1,3-diyl group, a cyclopentane-1,3-diyl group, a cyclohexane-1,4-diyl group, or a cyclooctane-1,5-diyl group; and

polycyclic saturated cyclic hydrocarbon groups such as a norbornane-1,4-diyl group, a norbornane-2,5-diyl group, an adamantane-1,5-diyl group, the adamantane-2,6-diyl group.

L² preferably represents a single bond or a C1-C17 divalent saturated hydrocarbon group in which a methylene group is optionally replaced by an oxygen atom or a carbonyl group and in which a hydrogen atom is optionally replaced by a fluorine atom.

The divalent hydrocarbon group represented by L², in which a methylene group has been replaced by an oxygen atom or a carbonyl group, includes the groups represented by formulae (b1-1), (b1-2), (b1-3), (b1-4), (b1-5) and (b1-6);

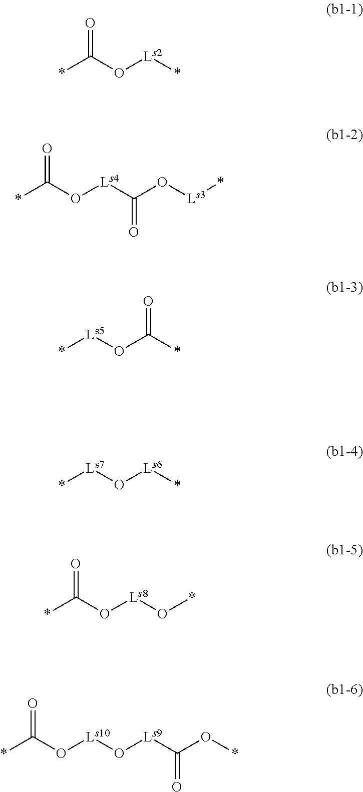

wherein L^{s2} represents a single bond or a C1-C15 hydrocarbon group, L^{s3} represents a single bond or a C1-C12 hydrocarbon group, L^{s4} represents a single bond or a C1-C13 hydrocarbon group, with proviso that total carbon number of L^{s3} and L^{s4} is 1 to 13,
L^{s5} represents a C1-C15 hydrocarbon group, L^{s6} represents a single bond or a C1-C15 hydrocarbon group, L^{s6} represents a C1-C16 hydrocarbon group, with proviso that total carbon number of L^{s6} and L^{s7} is 1 to 16,
L^{s8} represents a C1-C14 hydrocarbon group, L^{s9} represents a C1-C11 hydrocarbon group, L^{s10} represents a C1-C11 hydrocarbon group, with proviso that total carbon number of L^{s9} and L^{s10} is 1 to 12, * at the left side represents a binding position to —C(Q¹)(Q²)- and * at the right side represents a binding position to Y¹.
L^{s2}, L^{s3}, L^{s4}, L^{s5}, L^{s6}, L^{s7}, L^{s8}, L^{s9} and L^{s10} are preferably a saturated hydrocarbon group.

Examples of the groups represented by formula (b1-1) include the following ones;

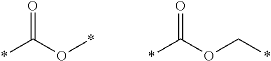 [SMILES: *OC(*)=O ; *COC(*)=O]

where * at the left side represents a binding position to —C (Q¹) (Q²)- and * at the right side represents a binding position to Y¹.

Examples of the groups represented by formula (b1-2) include the following ones;

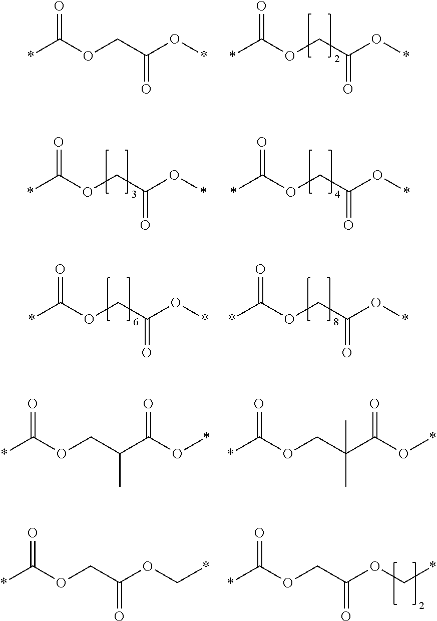

where * at the left side represents a binding position to —C (Q¹)(Q²)- and * at the right side represents a binding position to Y¹.

Examples of the groups represented by formula (b1-3) include the following ones;

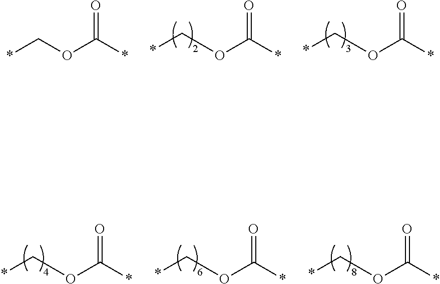

where * at the left side represents a binding position to —C (Q¹)(Q²)- and * at the right side represents a binding position to Y¹.

Examples of the groups represented by formula (b1-4) include the following ones;

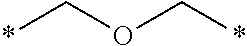 [SMILES: *COC*]

where * at the left side represents a binding position to —C(Q¹)(Q²)- and * at the right side represents a binding position to Y¹.

Examples of the groups represented by formula (b1-5) include the following ones;

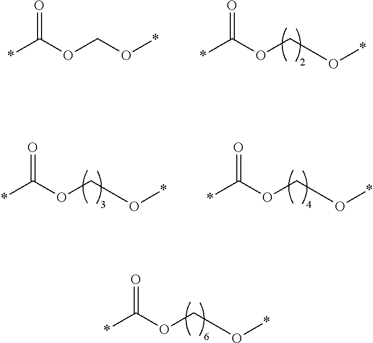

where * at the left side represents a binding position to —C (Q¹)(Q²)- and * at the right side represents a binding position to Y¹.

Examples of the groups represented by formula (b1-6) include the following ones;

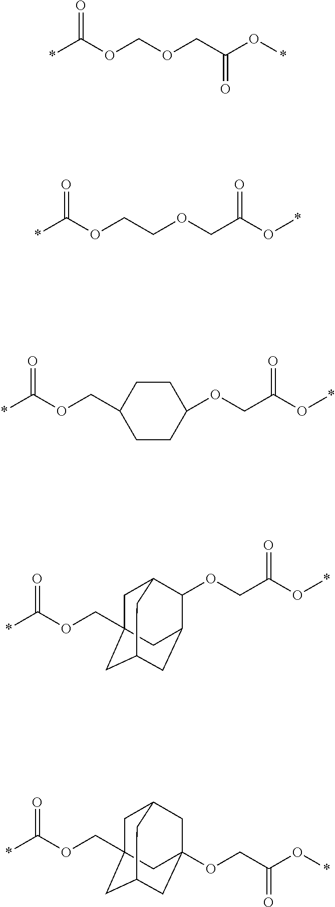 [SMILES: *OC(=O)COCOC(*)=O ; *OC(=O)COCCOC(*)=O ; *OC(=O)COC1CCC(COC(*)=O)CC1 ; *OC(=O)COC1C2CC3CC1CC(COC(*)=O)(C3)C2 ; *OC(=O)COC12CC3CC(CC(COC(*)=O)(C3)C1)C2]

where * at the left side represents a binding position to —C(Q¹)(Q²)- and * at the right side represents a binding position to Y¹.

Among them, L² represents preferably the group represented by formula (b1-1), and more preferably the group represented by formula (b1-1) in which L^{b2} is a single bond or —CH₂—.

The divalent hydrocarbon group represented by L² may be the hydrocarbon group in which a methylene group has been replaced by —NR′ where R′ represents a hydrogen atom or a C1-C4 alkyl group. R′ preferably represents a hydrogen atom.

The divalent hydrocarbon group represented by L² may be the hydrocarbon group in which a hydrogen atom has been replaced by a fluorine atom. The hydrocarbon group in which a hydrogen atom has been replaced by a fluorine atom includes the groups as follow;

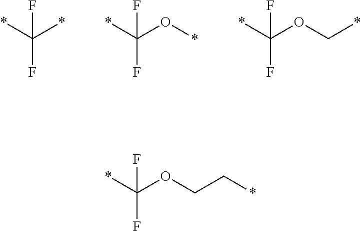 [SMILES: *C(*)(F)F ; *OC(*)(F)F ; *COC(*)(F)F ; *CCOC(*)(F)F]

where * at the left side represents a binding position to —C (Q¹)(Q²)- and * at the right side represents a binding position to Y¹.

The divalent hydrocarbon group represented by L³, in which a methylene group has been replaced by an oxygen atom or a carbonyl group, includes the groups represented by formulae (b2-1), (b2-2), (b2-3), (b2-4), (b2-5) and (b2-6);

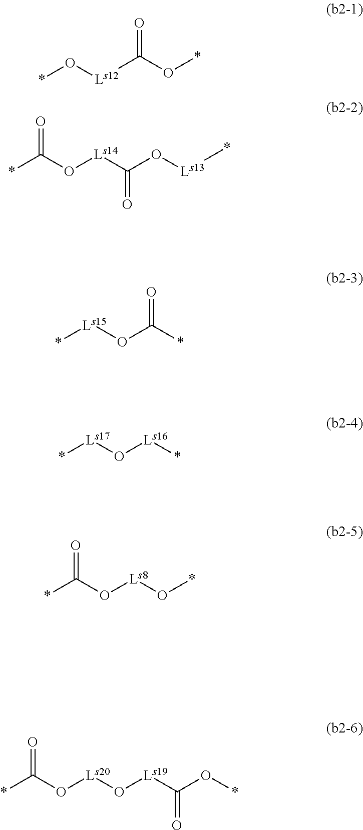

wherein L^{s12} represents a single bond or a C1-C14 hydrocarbon group, L^{s13} represents a single bond or a C1-C12 hydrocarbon group, L^{s14} represents a single bond or a C1-C13 hydrocarbon group, with proviso that total carbon number of L^{s13} and L^{s14} is 1 to 13,
L^{s15} represents a C1-C15 hydrocarbon group, L^{s16} represents a single bond or a C1-C15 hydrocarbon group, L^{s17} represents a C1-C16 hydrocarbon group, with proviso that total carbon number of L^{s16} and L^{s17} is 1 to 16,
L^{s18} represents a C1-C14 hydrocarbon group, L^{s19} represents a C1-C11 hydrocarbon group, L^{s20} represents a C1-C11 hydrocarbon group, with proviso that total carbon number of L^{s19} and L^{s20} is 1 to 12, * at the left side represents a binding position to Y¹ and * at the right side represents a binding position to Y².

L^{s12}, L^{s13}, L^{s14}, L^{s15}, L^{s16}, L^{s17}, L^{s18}, L^{s19} and L^{s20} are preferably a saturated hydrocarbon group.

Examples of the groups represented by formula (b2-1) include the following ones;

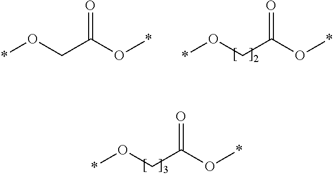

where * at the left side represents a binding position to Y¹ and * at the right side represents a binding position to Y².

Examples of the groups represented by formula (b2-2) include the following ones;

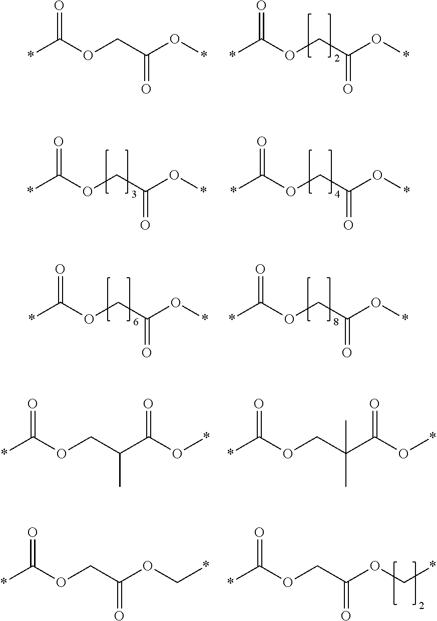

where * at the left side represents a binding position to Y¹ and * at the right side represents a binding position to Y².

Examples of the groups represented by formula (b2-3) include the following ones;

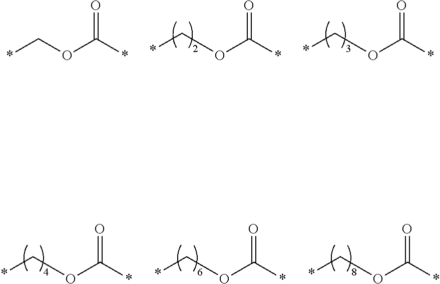

where * at the left side represents a binding position to Y¹ and * at the right side represents a binding position to Y².

Examples of the groups represented by formula (b2-4) include the following ones;

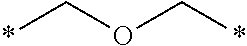 [SMILES: *COC*]

where * at the left side represents a binding position to Y¹ and * at the right side represents a binding position to Y².

Examples of the groups represented by formula (b2-5) include the following ones;

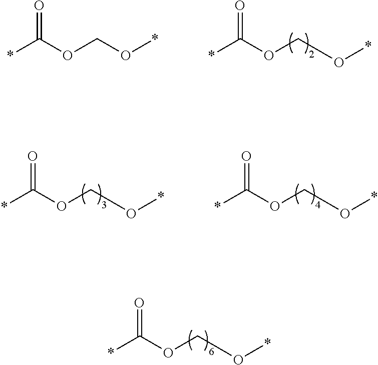

where * at the left side represents a binding position to Y¹ and * at the right side represents a binding position to Y².

Examples of the groups represented by formula (b2-6) include the following ones;

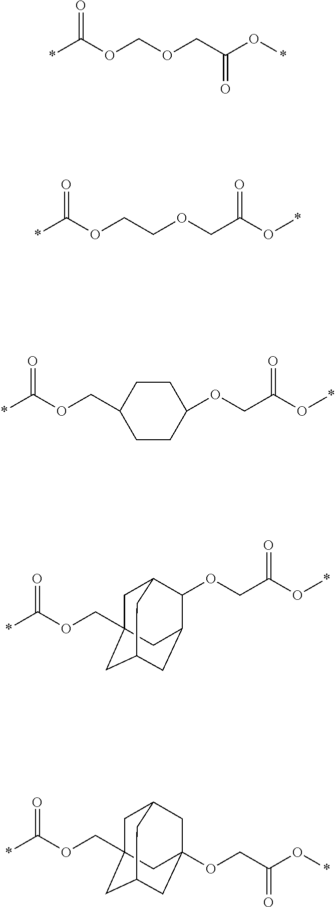 [SMILES: *OC(=O)COCOC(*)=O ; *OC(=O)COCCOC(*)=O ; *OC(=O)COC1CCC(COC(*)=O)CC1 ; *OC(=O)COC1C2CC3CC1CC(COC(*)=O)(C3)C2 ; *OC(=O)COC12CC3CC(CC(COC(*)=O)(C3)C1)C2]

where * at the left side represents a binding position to Y¹ and * at the right side represents a binding position to Y².

Among them, L³ represents preferably a single bond, or the group represented by formula (b2-1) or (b2-5).

Y¹ represents a single bond or C3-C18 divalent alicyclic hydrocarbon group.

The divalent alicyclic hydrocarbon group represented by Y¹ may be monocyclic or polycyclic.

The divalent hydrocarbon group represented by Y¹ may be the hydrocarbon group in which a methylene group has been replaced by an oxygen atom, a carbonyl group or a sulfonyl group. The divalent hydrocarbon group includes what has an alkyl group as a substituent.

The divalent hydrocarbon group represented by Y¹ includes a divalent group in which one hydrogen atom has been removed from the group represented by any one of the formulae (Y1) to (Y11).

When Y¹ represents the divalent hydrocarbon group in which a methylene group has been replaced by an oxygen atom, a carbonyl group or a sulfonyl group, the examples of Y¹ include a cyclic ether group (a group in which a methylene group of the alicyclic hydrocarbon group has been replaced by an oxygen atom), a cyclic ketone group (a group in which a methylene group of the alicyclic hydrocarbon group has been replaced by a carbonyl group), a sultone ring group (a group in which —CH₂—CH₂— of an alicyclic hydrocarbon group has been replaced by —SO₂—O—) and a lactone ring group (a group in which —CH₂—CH₂— of the alicyclic hydrocarbon group has been replaced by —CO—O—), specifically the groups in which one hydrogen atom has been removed from a group represented by any one of formulae (Y12) to (Y26).

More specific examples of Y¹ include the following groups;

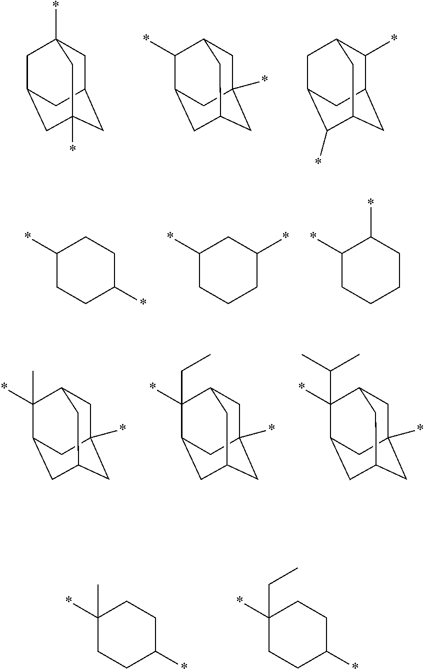

where * represents a binding position.

Y² represents a C3-C18 alicylic hydrocarbon group in which a methylene group is optionally replaced by an oxygen atom, a sulfonyl group or a carbonyl group and in which a hydrogen atom is optionally replaced by a substituent.

The alicyclic hydrocarbon group represented by Y² may be monocyclic or polycyclic group. The alicyclic hydrocarbon group represented by Y² may have an oxygen atom, a sulfonyl group or a carbonyl group by which a methylene group has been replaced. The alicyclic hydrocarbon group represented by Y² may have an alkyl group as a substituent.

When Y² represents the alicyclic hydrocarbon group in which a methylene group has been replaced by an oxygen atom, a sulfonyl group or a carbonyl group, preferably by an oxygen atom or a carbonyl group, the examples of Y² include a cyclic ether group (a group in which a methylene group of the alicyclic hydrocarbon group has been replaced by an oxygen atom), a cyclic ketone group (a group in which a methylene group of the alicyclic hydrocarbon group has been replaced by a carbonyl group), a sultone ring group (a group in which —CH₂—CH₂— of an alicyclic hydrocarbon group has been replaced by —SO₂—O—) and a lactone ring group (a group in which —CH₂—CH₂— of the alicyclic hydrocarbon group has been replaced by —CO—O—), specifically the groups represented by of formulae (Y1) to (Y26) and formulae (Y27) to (Y30) as follow;

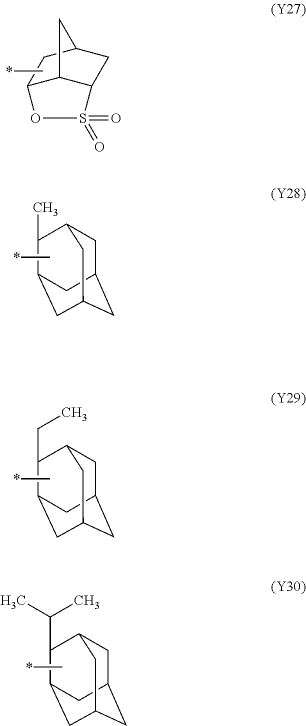

where * represents a binding position.

Among them, Y² represents preferably a group represented by any one of formulae (Y1) to (Y19) and formulae (Y27) to (Y30), more preferably a group represented by any one of formulae (Y11), (Y14), (Y15), (Y19), (Y26), (Y27), (Y28), (Y29) and (Y30), and more a group represented by any one of formulae (Y11), (Y14) and (Y28).

Examples of the substituent in the alicyclic hydrocarbon group represented by Y² include a halogen atom except a fluorine atom, a hydroxyl group, an oxo group, a glycidyloxy group, a C2-C4 acyl group, a C1-C12 alkoxy group, a C2-C7 alkoxycarbonyl group, a C7-C21 aralkyl group and —(CH₂)ⱼ₂—O—CO—R^{b1}— in which R^{b1} represents a C1-C16 aliphatic hydrocarbon group, a C3-C16 saturated cyclic hydrocarbon group or a C6-C18 aromatic hydrocarbon group and j2 represents an integer of 0 to 4. Examples of the halogen atom include a chlorine atom, a bromine atom and an iodine atom. Examples of the acyl group include an acetyl group and a propionyl group, and examples of the alkoxy group include a methoxy group, an ethoxy group, a propoxy group, an isopropoxy group and a butoxy group.

Examples of the alkoxycarbonyl group include a methoxycarbonyl group, an ethoxycarbonyl group, a propoxycarbonyl group, an isopropoxycarbonyl group and a butoxycarbonyl group.

Examples of the aralkyl group include a benzyl group, a phenethyl group, a phenylpropyl group, a trityl group, a naphthylmethyl group and a naphthylethyl group.

Examples of Y² having a substituent include the followings:

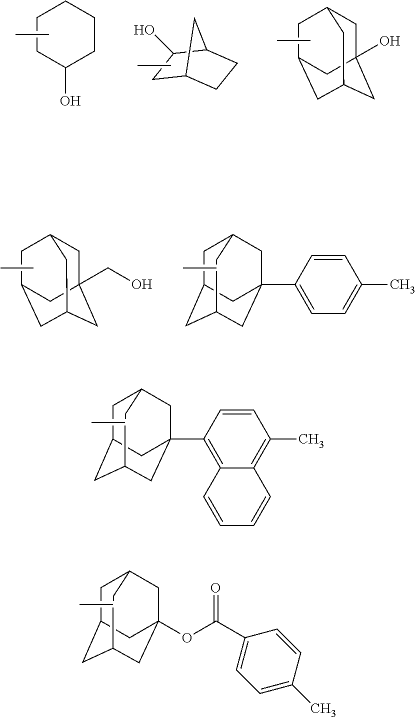

Y² is preferably an adamantyl group which can have a substituent, and is more preferably an adamantyl group, a hydroxyadamantyl group or an oxoadamantyl group.

Examples of the anions of the salt represented by the formula (B1) include the anions mentioned in JP2010-204646 and the following anions.

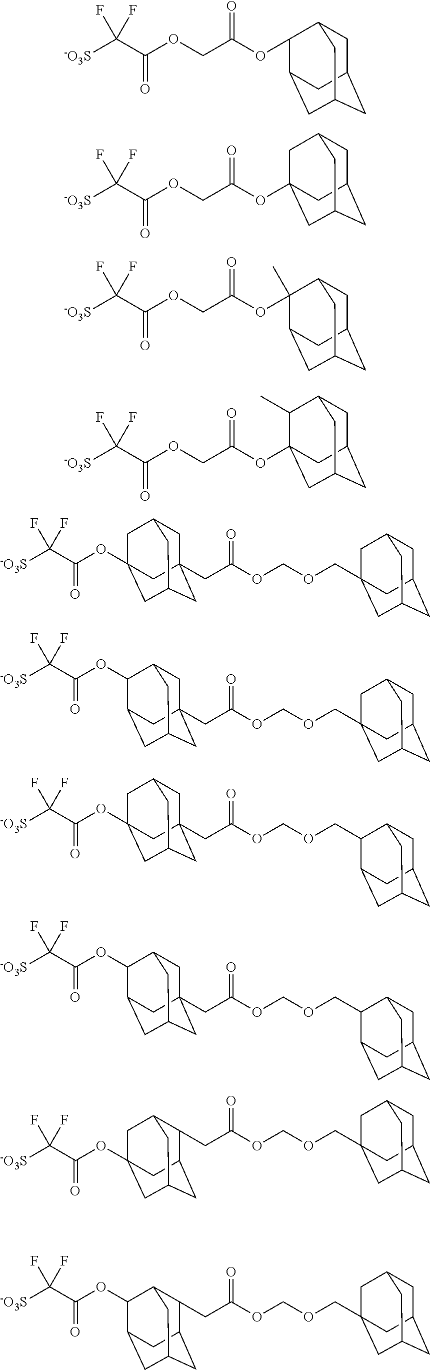

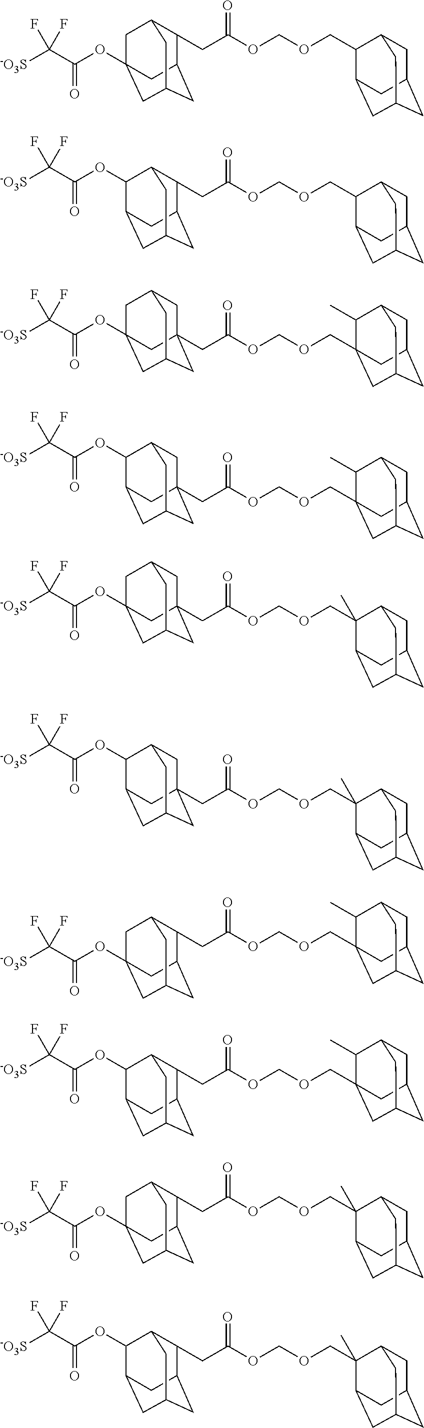

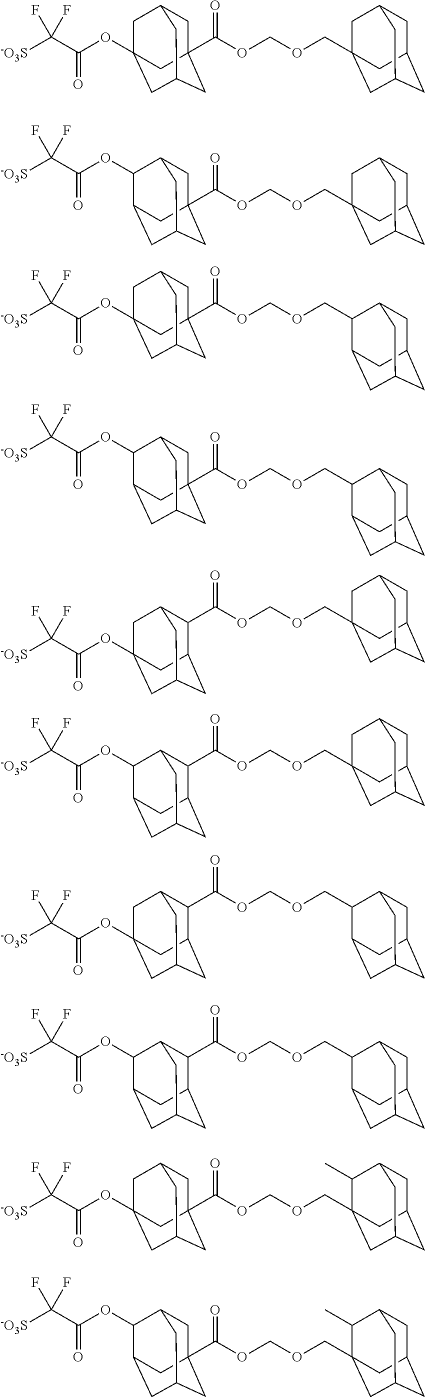

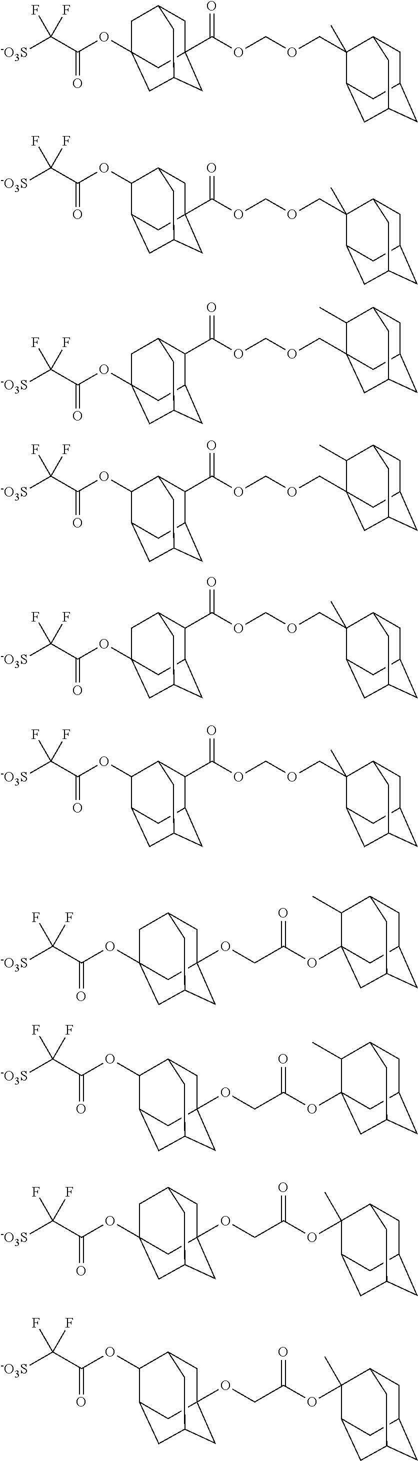

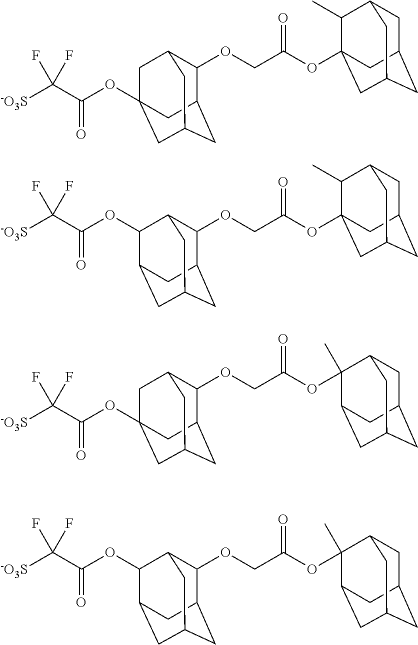

Furthermore, specific examples of anions preferably include those:

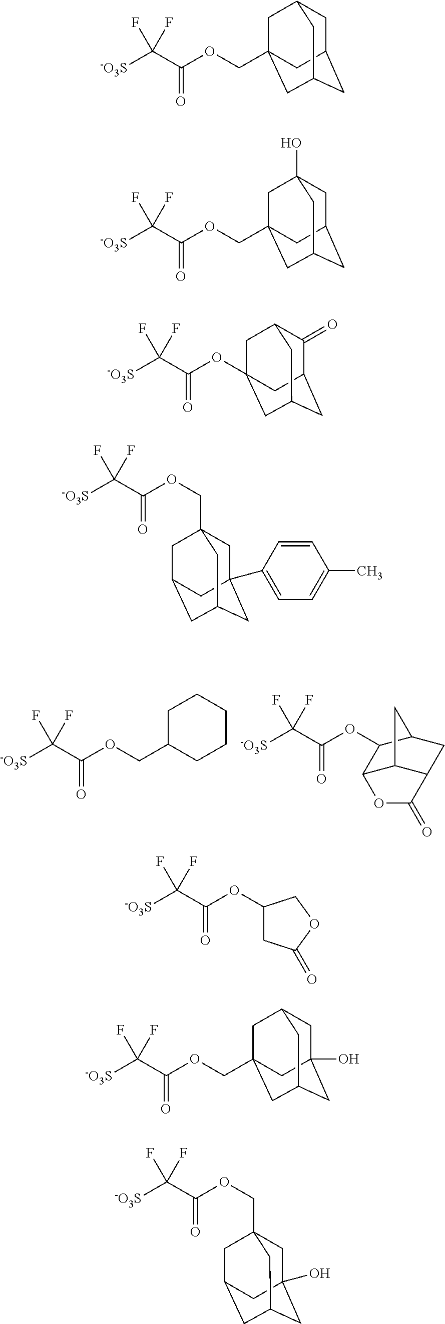

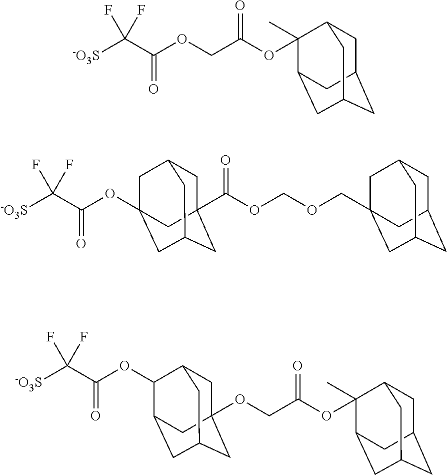

Examples of the organic cation represented by Z⁺ in the salt represented by the formula (B1) include an organic onium cation such as an organic sulfonium cation, an organic iodonium cation, an ammonium cation, a benzothiazolium cation and an organic phosphonium cation, and an organic sulfonium cation and an organic iodonium cation are preferable.

Preferable examples of the organic cation represented by Z⁺ include the cations represented by the formulae (b2-1) to (b2-4):

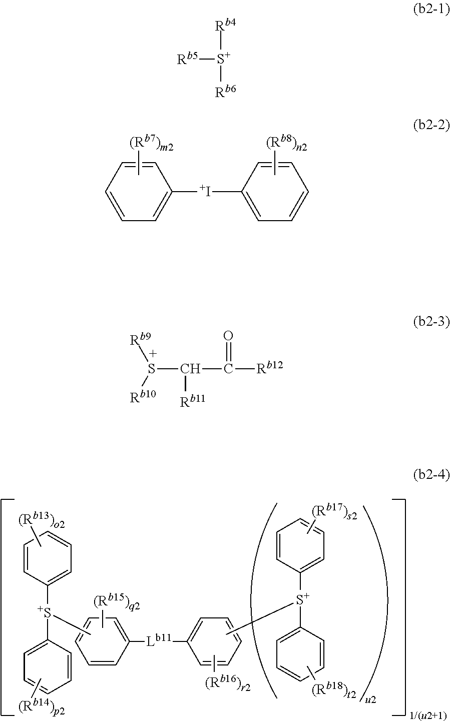

wherein R^{b4}, R^{b5} and R^{b6} independently represent a C1-C30 alkyl group in which a hydrogen atom can be replaced by a hydroxyl group or a C1-C12 alkoxy group, a C3-C18 saturated cyclic hydrocarbon group in which a hydrogen atom can be replaced by a hydroxyl group or a C1-C12 alkoxy group, or a C6-C18 aromatic hydrocarbon group in which a hydrogen atom can be replaced by a C1-C12 alkyl group or a C1-C12 alkoxy group or a C3-C36 saturated cyclic hydrocarbon group, or R^{b4} and R^{b5} are bonded to form a ring together with the adjacent S⁺,
R^{b7} and R^{b8} represent independently in each occurrence a hydrogen atom, a hydroxyl group, a C1-C12 alkyl group or a C1-C12 alkoxy group,
m2 and n2 independently represents an integer of 0 to 5,
R^{b9} and R^{b10} independently represent a C1-C12 alkyl group or a C3-C36, preferably C4-C12, saturated cyclic hydrocarbon group, or R^{b9} and R^{b10} are bonded to form a C2-C11 divalent acyclic hydrocarbon group which forms a ring together with the adjacent S⁺,
R^{b11} represents a C1-C12 alkyl group or a C3-C18, preferably C4-C12, saturated cyclic hydrocarbon group,
R^{b12} represents a C1-C12 alkyl group or a C3-C36, preferably C3-C12, saturated cyclic hydrocarbon group, or a C6-C18 aromatic hydrocarbon group which can have a substituent selected from the group consisting of a C1-C12 alkyl group, a C1-C12 alkoxy group, C3-C18 saturated cyclic hydrocarbon group and a C2-C12 alkylcarbonyloxy group
or R^{b11} and R^{b12} are bonded each other to form a 3 to 12-membered, preferably 3 to 7-membered, ring together with the adjacent —CHCO—, and a methylene group in the divalent acyclic hydrocarbon group may be replaced by a carbonyl group, an oxygen atom or a sulfur atom, and
R^{b13}, R^{b14}, R^{b15}, R^{b16}, R^{b17} and R^{b18} independently represent a hydroxyl group, a C1-C12 alkyl group or a C1-C12 alkoxy group,
L^{b11} represents an oxygen atom or a sulfur atom and
o2, p2, s2 and t2 each independently represents an integer of 0 to 5, q2 and r2 each independently represents an integer of 0 to 4, and u2 represents 0 or 1.

The alkyl group represented by R^{b9} to R^{b11} has preferably 1 to 12 carbon atoms. The saturated cyclic hydrocarbon group represented by R^{b9} to R^{b11} has preferably 3 to 36 carbon atoms and more preferably 4 to 12 carbon atoms.

Preferable examples of the alkyl group include a methyl group, an ethyl group, a propyl group, an isopropyl group, a butyl group, a sec-butyl group, a tert-butyl group, a pentyl group, a hexyl group, an octyl group and a 2-ethylhexyl group.

A C4-C12 cyclic aliphatic hydrocarbon group is preferable. Preferable examples of the cyclic aliphatic hydrocarbon group include a cyclopropyl group, a cyclobutyl group, a cyclopentyl group, a cyclohexyl group, a cycloheptyl group, a cyclodecyl group, a 2-alkyl-a-adamantyl group, a 1-(1-adamantyl)-1-alkyl group and an isobornyl group.

Preferable examples of the aromatic group include a phenyl group, a 4-methylphenyl group, a 4-ethylphenyl group, a 4-tert-butylphenyl group, a 4-cyclohexylphenyl group, a 4-methoxyphenyl group, a biphenyl group and a naphthyl group.

Examples of the alkyl group having an aromatic hydrocarbon group include a benzyl group. Examples of the alkoxy group include a methoxy group, an ethoxy group, a propoxy group, an isopropoxy group, a butoxy group, a sec-butoxy group, a tert-butoxy group, a pentyloxy group, a hexyloxy group, a heptyloxy group, an octyloxy group, a 2-ethylhexyloxy group, a nonyloxy group, a decyloxy group, an undecyloxy group and a dodecyloxy group.

Examples of the C3-C12 divalent acyclic hydrocarbon group formed by bonding R^{b9} and R^{b10} include a trimethylene group, a tetramethylene group and a pentamethylene group. Examples of the ring group formed together with the adjacent S⁺ and the divalent acyclic hydrocarbon group include a thiolan-1-ium ring (tetrahydrothiphenium ring), a thian-1-ium ring and a 1,4-oxathian-4-ium ring. AC3-C7 divalent acyclic hydrocarbon group is preferable.

Examples of the C1-C10 divalent acyclic hydrocarbon group formed by bonding R^{b11} and R^{b12} include a methylene group, an ethylene group, a trimethylene group, a tetramethylene group and a pentamethylene group and examples of the ring group include the followings.

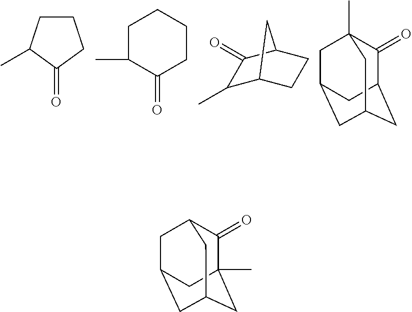

A C1-C5 divalent acyclic hydrocarbon group is preferable.

Among the above-mentioned cations, preferred is the cation represented by the formula (b2-1), and more preferred is an arylsulfonium cation such as the cation represented by the formula (b2-1-1). A triphenylsulfonium cation is especially preferable.

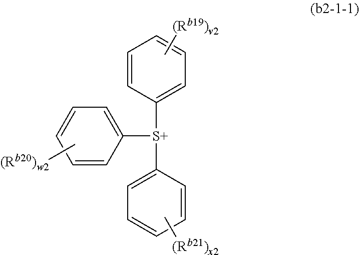

wherein R^{b19}, R^{b20} and R^{b21} are independently in each occurrence a halogen atom, a hydroxyl group, a C1-C18 alkyl group, a C3-C18 saturated cyclic hydrocarbon group or a C1-C12 alkoxy group, and v2, w2 and x2 independently each represent an integer of 0 to 5.

It is preferred that R^{b19}, R^{b20} and R^{b21} are independently in each occurrence a halogen atom, a hydroxyl group, a C1-C12 alkyl group or a C1-C12 alkoxy group and v2, w2 and x2 independently each represent an integer of 0 to 5, and it is more preferred that R^{b19}, R^{b20} and R^{b21} are independently in each occurrence a fluorine atom, a hydroxyl group, a C1-C12 alkyl group or a C1-C12 alkoxy group, and v2, w2 and x2 independently each preferably represent 0 or 1.

Specific examples of the cation represented by Z⁺ include those mentioned in JP2010-204646A1.

Examples of the salt represented by the formula (B1) include a salt wherein the anion is any one of the above-mentioned anions and the cation is any one of the above-mentioned organic cations. Preferable examples of the acid generator include a combination of any one of anions represented by the formulae (b1-1-1) to (b1-1-9) and any one of the cations represented by the formulae (b2-1-1), and a combination of any one of anions represented by the formulae (b1-1-3) to (b1-1-5) and the cation represented by the formulae (b2-3).

As the salt represented by formula (B1), the salts represented by the formulae (B1-1) to (B1-37) are preferable, and the salts represented by the formulae (B1-1), (B1-2), (B1-6), (B1-11), (B1-30), (B1-31), (B1-32), (B1-33) and (B1-35) are more preferable.

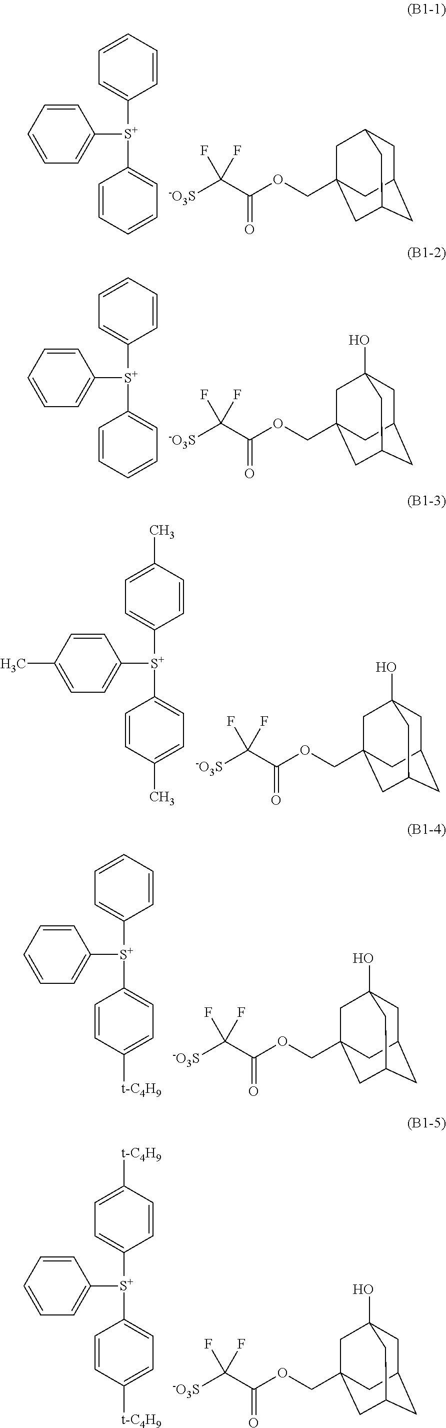

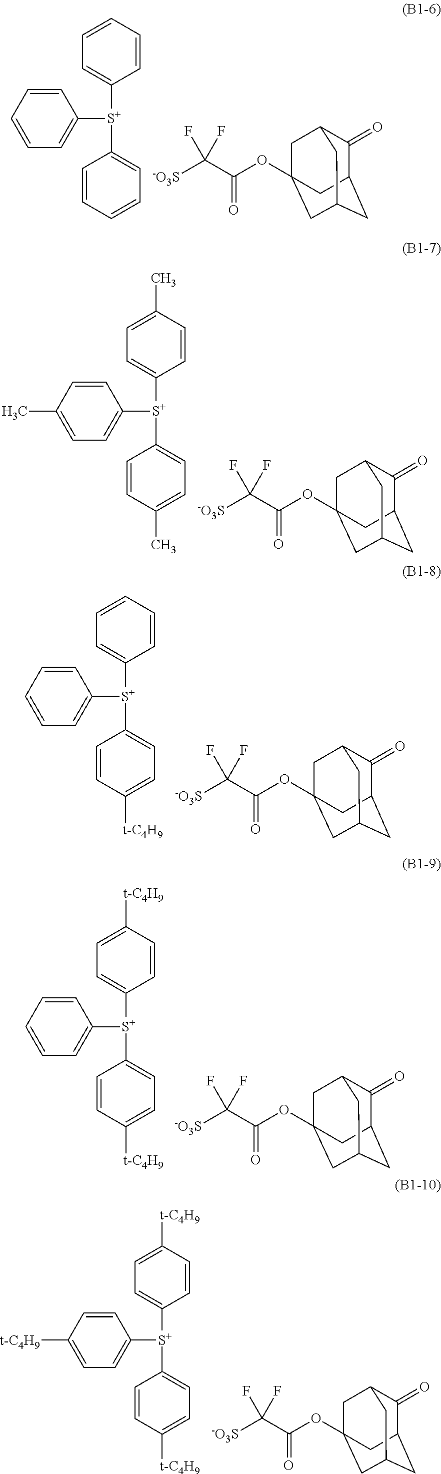

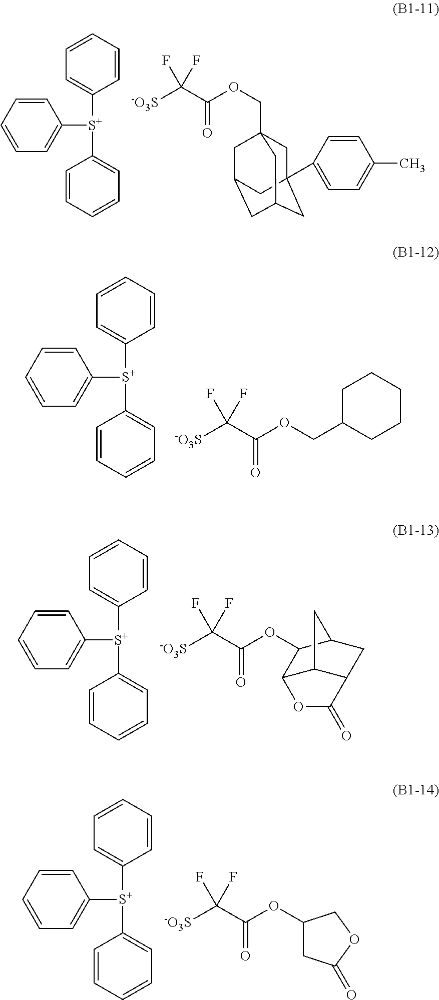

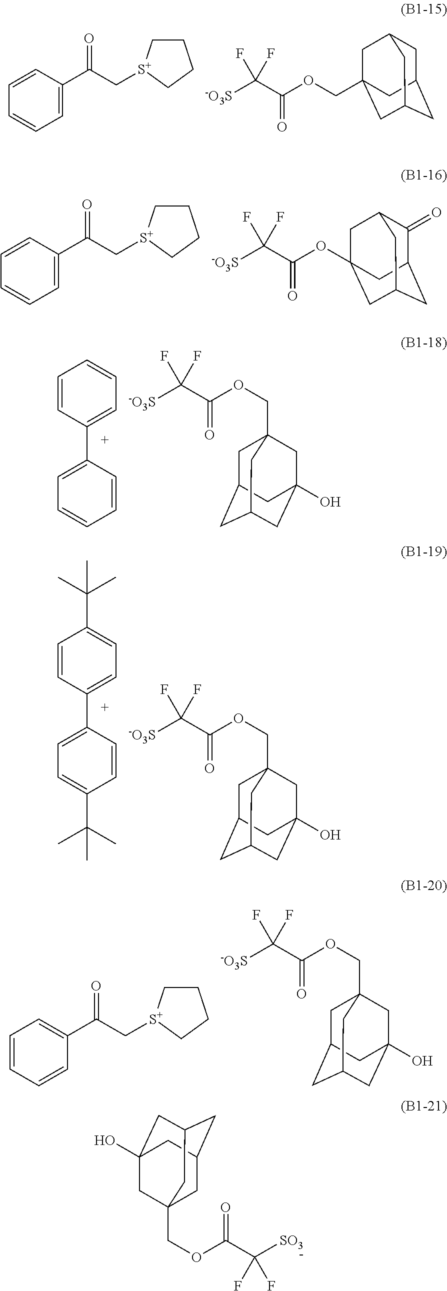

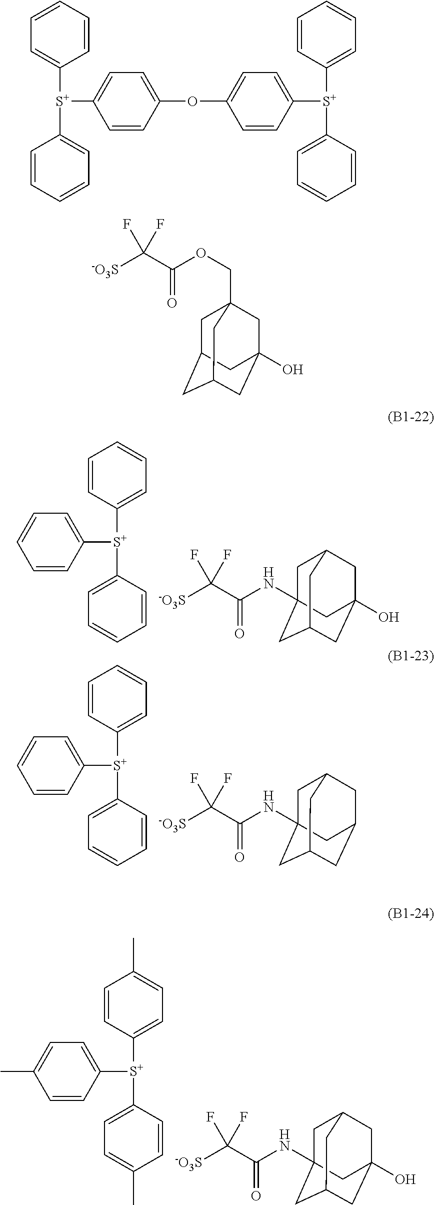

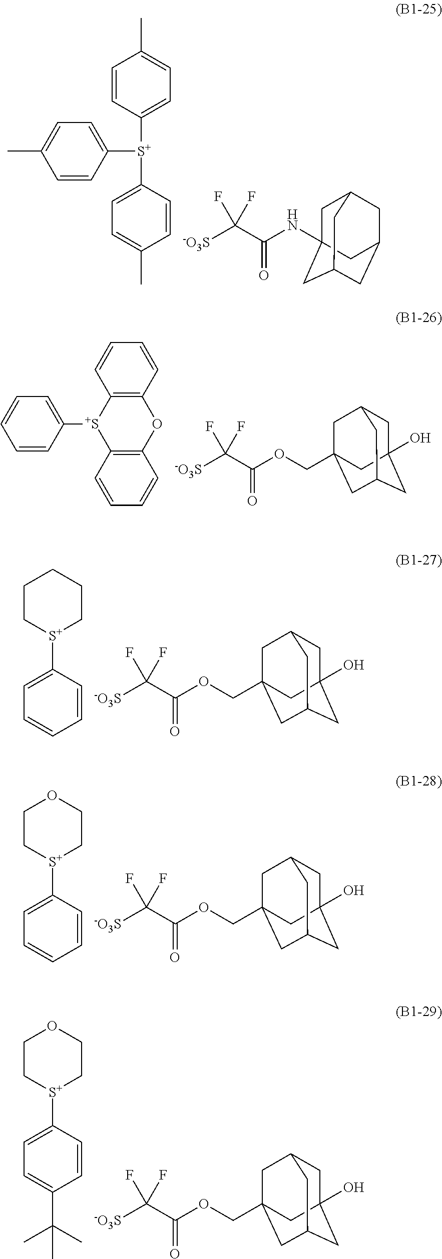

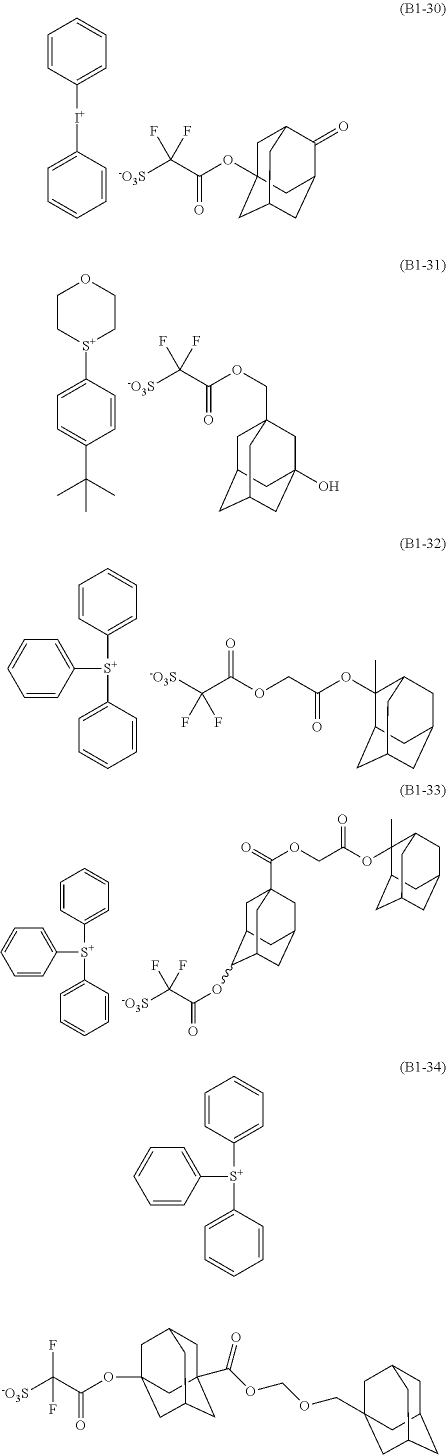

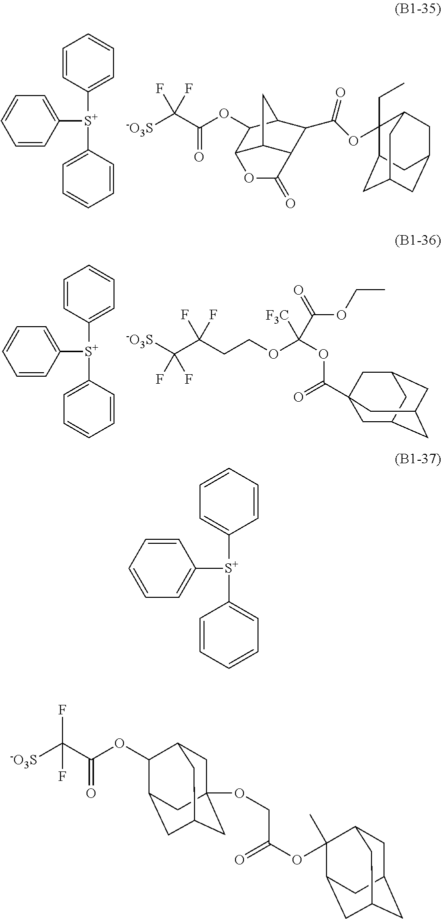

Two or more kinds of the salt represented by the formula (B1) can be used in combination.

The salt represented by the formula (B1) can be produced by a known method such as mentioned in JP2006-257078A1, JP2006-306856 A1, JP2007-224008A1, JP2008-74843A1, JP2008-69146A1, JP2011-126869 A1, JP2012-67079A1, or WO2012/056901 A1.

The content of the salt represented by the formula (B1) in the photoresist composition is usually 1 part by weight or more, preferably 5 parts by weight or more, more preferably 10 parts by weight or more, per 100 parts by weight of COMPOUND (I), and it is usually 50 parts by weight or less, preferably 40 parts by weight or less, preferably 30 parts by weight or less, per 100 parts by weight of COMPOUND (I).

The photoresist composition of the present invention may comprise a compound known as an acid generator, other than the salt represented by the formula (B1).

Such compound includes a nonionic compound, anionic compound and the combination thereof. Examples of the nonionic compound include an organo-halogen compound, a sulfonate compound such as a 2-nitrobenzylsulfonate, an aromatic sulfonate, an oxime sulfonate, an N-sulfonyloxyimide, a sulfonyloxyketone and diazonaphthoquinone 4-sulfonate, and a sulfone compound such as a disulfone, a ketosulfone and a sulfonyldiazomethane.

Examples of the ionic compound include an onium salt compound such as a diazonium salt, a phosphonium salt, a sulfonium salt and an iodonium salt. Examples of the anion of the onium salt include a sulfonic acid anion, a sulfonylimide anion and a sulfonylmethide anion.

Other examples of the compound known as an acid generator include acid generators described in JP 63-26653 A, JP 55-164824 A, JP 62-69263 A, JP 63-146038 A, JP 63-163452 A, JP 62-153853 A, JP 63-146029 A, U.S. Pat. No. 3,779,778, U.S. Pat. No. 3,849,137, DE Patent No. 3914407 and EP Patent No. 126,712.

The photoresist composition of the present invention may comprise a resin which comprises an acid-labile group and which is insoluble or poorly soluble in an aqueous alkaline solution but becomes soluble in an aqueous alkaline solution by the action of an acid (Hereinafter, such resin is referred to as RESIN (A)). RESIN (A) can be prepared by polymerizing a monomer having an acid-labile group.

Herein, the “an acid-labile group” means a group capable of being eliminated by the action of an acid. The monomer having an acid-labile group can provide a hydrophilic group such as a hydroxyl group or a carboxy group by contacting an acid.

Examples of the acid-labile group include a group represented by the formula (1):

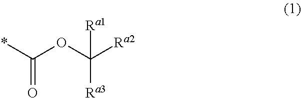

wherein R^{a1}, R^{a2} and R^{a3} independently each represent a C1-C8 alkyl group, a C3-C20 alicyclic hydrocarbon group or a combination of them, or R^{a1} and R^{a2} can be bonded each other to form a C2-C20 divalent aliphatic hydrocarbon group, and * represents a binding position.

Examples of the C1-C8 alkyl group include a methyl group, an ethyl group, a propyl group, a butyl group, a pentyl group, a hexyl group, a heptyl group, and an octyl group.

The alicyclic hydrocarbon group may be monocyclic or polycyclic, which includes a cycloalkyl group such as cyclopentyl group, cyclohexyl group, cycloheptyl group, and cyclooctyl group; polycyclic alicyclic hydrocarbon group such as decahydronaphtyl group, adamantyl group, norbornyl group and the groups represented as follow.

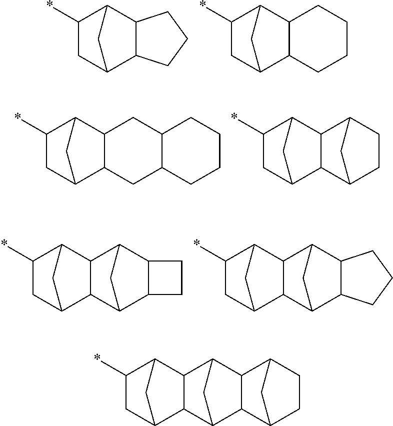

in which * represents a binding position.

The combination of alkyl group and alicyclic hydrocarbon group includes methylcyclohexyl group, dimethylcyclohexyl group, and methylnorbornyl group.

The divalent aliphatic hydrocarbon group formed by R^{a1} and R^{a2} which have bound each other has preferably C3-C12 carbon atoms.

When R^{a1} and R^{a2} are bonded each other to form a ring together with a carbon atom to which R^{al} and R^{a2} are bonded, examples of the group represented by —C(R^{a1})(R^{a2})(R^{a3}) include the following groups.

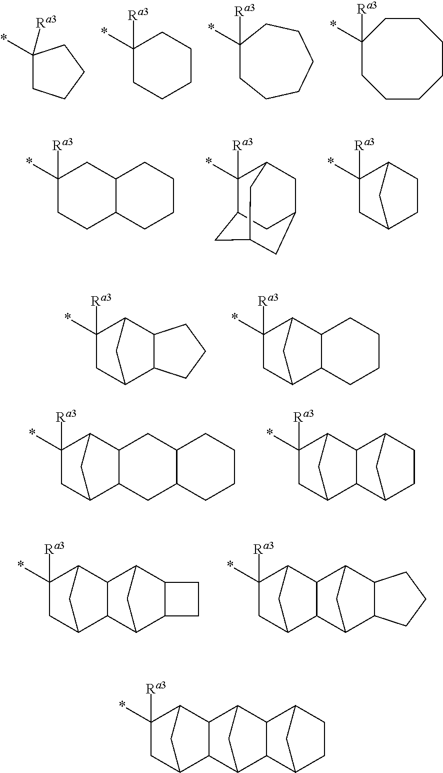

wherein R^{a3} is the same as defined above, and * represents a binding position.

The group represented by the formula (1) includes a group represented by formula (I-1), formula (I-2), formula (I-3) or formula (I-4).

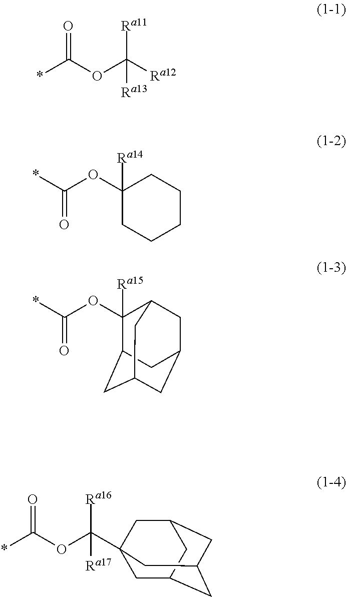

in which R^{a11}, R^{a12}, R^{a13}, R^{a14}, R^{a15}, R^{a16} and R^{a17} independently each represent a C1-C8 alkyl group.

The group represented by the formula (1) includes preferably tert-butoxycarbonyl group, 1-ethylcyclohexane-1-yloxycarbonyl group, 1-ethyladamantane-2-yloxycarbonyl group, and 2-isopropyladamantane-2-yloxycarbonyl group.

Among them, preferred are those represented by formula (1-2), formula (1-3) or formula (1-4) each of which has an alicyclic hydrocarbon group, and more preferred are those represented by formula (1-2) or formula (1-3) each of which has an alicyclic hydrocarbon group.

Examples of the acid-labile group include a group represented by the formula (2):

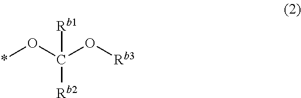

wherein R^{b1} and R^{b2} independently each represent a hydrogen atom or a C1-C12 monovalent hydrocarbon group, and R^{b3} represents a C1-C20 monovalent hydrocarbon group, and R^{b2} and R^{b3} can be bonded each other to form a C2-C20 divalent hydrocarbon group, and a methylene group in the hydrocarbon group and the ring can be replaced by —O— or —S—, and * represents a binding position.

Examples of the hydrocarbon group include an alkyl group, an alicyclic hydrocarbon group and an aromatic hydrocarbon group.

Examples of the alkyl group for formula (2) include a methyl group, an ethyl group, a propyl group, a butyl group, a pentyl group, a hexyl group, a heptyl group, an octyl group, an decyl group, and a dodecyl group.

Examples of the alicyclic hydrocarbon group for formula (2) include those as mentioned above.

Examples of the aromatic hydrocarbon group include an aryl group such as a phenyl group, a naphthyl group, an anthryl group, a biphenyl group, a phenanthryl group and a fluorenyl group, which include those having a C1-C8 alkyl group.

It is preferred that at least one of R^{b1} and R^{b2} is a hydrogen atom.

Examples of the group represented by the formula (2) include the following;

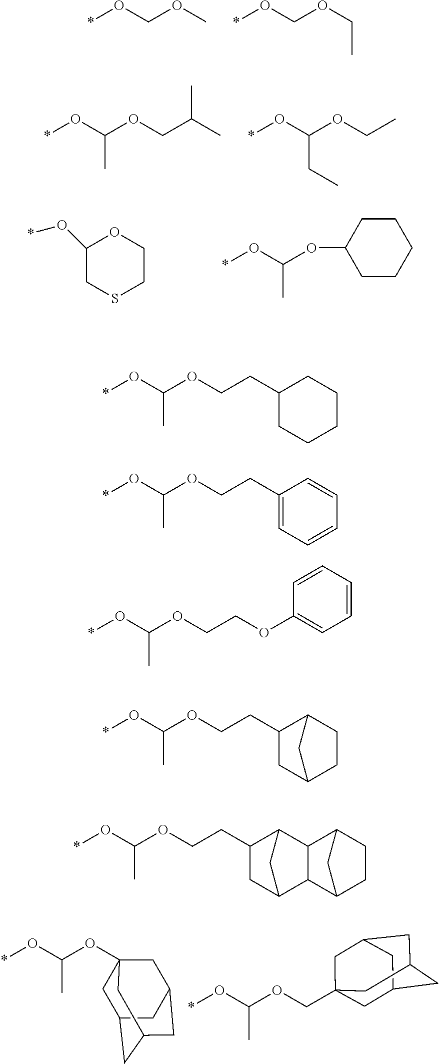

where * represents a binding position.

The monomer having an acid-labile group is preferably a monomer having an acid-labile group in its side chain and a carbon-carbon double bond, and is more preferably an acrylate monomer having an acid-labile group in its side chain or a methacryalte monomer having an acid-labile group in its side chain.

An acrylate monomer having the group represented by the formula (1) or (2) in its side chain or a methacryalte monomer having the group represented by the formula (1) or (2) in its side chain is especially preferable.

An acrylate monomer having the group represented by the formula (1) in its side chain or a methacryalte monomer having the group represented by the formula (1) in its side chain is preferable, and an acrylate monomer having the group represented by the formula (1) in which R^{a1} and R^{a2} are bonded each other to form a C5-C20 saturated alicycle together with the carbon atom to which they are bonded in its side chain or a methacryalte monomer having the group represented by the formula (1) in which R^{a1} and R^{a2} are bonded each other to form a C5-C20 saturated alicyclic hyrdocarbon together with the carbon atom to which they are bonded in its side chain is more preferable. When the photoresist composition comprises a resin derived from a monomer having a bulky structure such as a saturated alicyclic hydrocarbon group, the photoresist composition having excellent resolution tends to be obtained.

Preferable examples of the monomer having an acid-labile group include the monomers represented by the formulae (a1-1) and (a1-2):

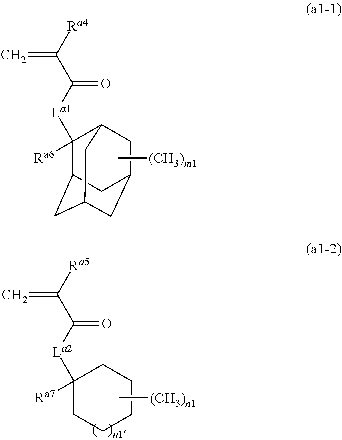

wherein L^{a1} and L^{a2} each independently represents *—O— or *—O—(CH₂)ₖ₁—CO—O— in which * represents a binding position to a carbonyl group,
R^{a4} and R^{a5} each independently represents a hydrogen atom or a methyl group, and k1 represents an integer of 1 to 7,
R^{a6} and R^{a7} each independently represents a C1-C8 alkyl group, a C3-C10 alicyclic hydrocarbon group or combination of them, and
m1 represents an integer of 0 to 14,
n1 represents an integer of 0 to 10
and n1′ represents an integer of 0 to 3.

Each of L^{a1} and L^{a2} is preferably *—O— or *—O—(CH₂)_{f1}—CO—O— in which * represents a binding position to —CO—, and f1 represents an integer of 1 to 4, and is more preferably *—O— or *—O—CH₂—CO—O—, and is especially preferably *—O—.

Each of R^{a4} and R^{a5} is a preferably methyl group. Examples of the alkyl group represented by R^{a6} and R^{a7} include a methyl group, an ethyl group, a propyl group, a butyl group, a pentyl group, a hexyl group, a heptyl group, and an octyl group.

The alkyl group represented by R^{a6} and R^{a7} has preferably 1 to 6 carbon atoms.

The alicyclic hydrocarbon group represented by R^{a6} and R^{a7} may be monocyclic or polycyclic. Examples of the monocyclic alicyclic hydrocarbon group include cyclopentyl group, cyclohexyl group, cycloheptyl group and cyclooctyl group. Examples of the polycyclic alicyclic hydrocarbon group include decahydronaphtyl group, adamantyl group or norbornyl group, and the following groups.

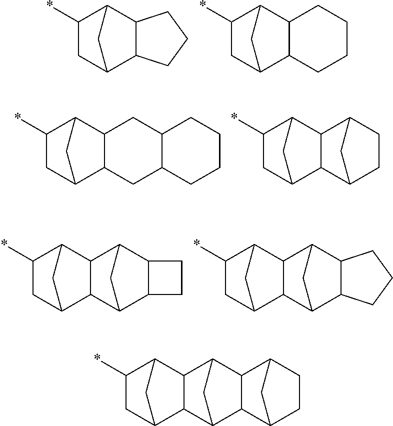

where * represents a binding position.

The alicyclic hydrocarbon group represented by R^{a6} and R^{a7} has preferably 8 or less, more preferably 6 or less carbon groups.

The combination of alkyl group and alicyclic hydrocarbon group includes cyclohexyl groups substituted with an alkyl group, such as methylcyclohexyl group, or dimethylcyclohexyl group, or norbornyl groups substituted with an alkyl group such as methylnorbornyl group.

In the formula (a1-1), m1 is preferably an integer of 0 to 3, and is more preferably 0 or 1.

In the formula (a1-2), n1 is preferably an integer of 0 to 3, and is more preferably 0 or 1, and n1′ is preferably 0 or 1, and more preferably 1.

It is preferred that k1 is an integer of 1 to 4, and it is more preferred that k1 is 1.

Examples of the monomer represented by the formula (a1-1) include those described in JP2010-204646A1, preferably the monomers represented by the formulae (a1-1-1), (a1-1-2), (a1-1-3), (a1-1-4), (a1-1-5), (a1-1-6), (a1-1-7) and (a1-1-8), and more preferably monomers represented by the formulae (a1-1-1), (a1-1-2), (a1-1-3) and (a1-1-4).

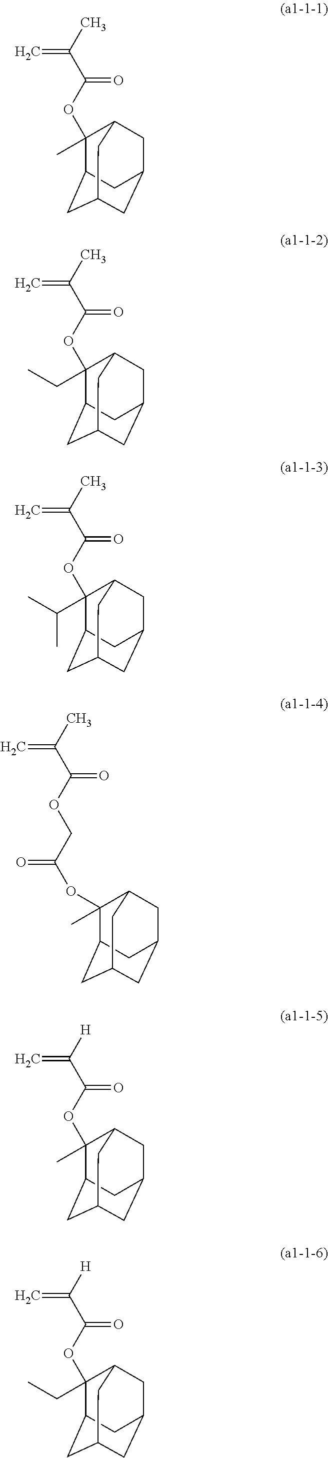

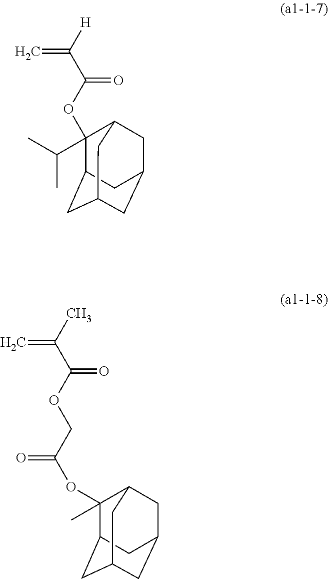 [SMILES: C=CC(=O)OC1(C(C)C)C2CC3CC(C2)CC1C3 ; C=C(C)C(=O)OCC(=O)OC1(C)C2CC3CC(C2)CC1C3]

Examples of the monomers represented by the formula (a1-2) include 1-ethylcyclopentane-1-yl(meth)acrylate, 1-ethylcyclohexane-1-yl(meth)acrylate, 1-ethylcycloheptane-1-yl(meth)acrylate, 1-methylcyclopentane-1-yl(meth)acrylate, 1-methylcyclohexane-1-yl(meth)acrylate, and 1-isopropylcyclohexane-1-yl(meth)acrylate. Preferred are the monomers represented by formulae (a1-2-1) to (a1-2-6), more preferred are the monomers represented by formulae (a1-2-3) and (a1-2-4).

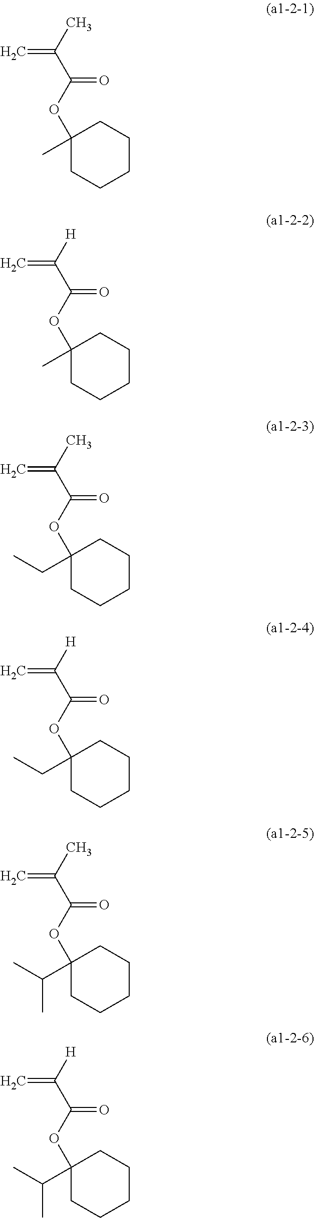

The total content of the structural units derived from the monomers represented by formula (a1-1) or (a1-2) is usually 10 to 95% by mole, preferably 15 to 90% by mole and more preferably 20 to 85% by mole based on the total mole number of all the structural units of RESIN (A).

The total content of the structural units having an acid-labile group is usually 10 to 80% by mole, preferably 20 to 60% by mole based on the total mole number of all the structural units of RESIN (A).

The total content of the structural units having an adamantyl group, preferably the structural units derived from the monomer represented by formula (a1-1), is preferably 15 or more moles per 100 moles of all the structural units of RESIN (A).

RESIN (A) preferably further comprises a structural unit derived from a monomer having no acid-labile group. RESIN (A) can have two or more kinds of structural units derived from the monomers having no acid-labile group.

The monomer having no acid-labile group preferably has a hydroxyl groups or a lactone ring. When the resin comprises a structural unit derived from the monomer having no acid-labile group and having a hydroxyl groups or a lactone ring, a photoresist composition having good resolution and adhesiveness of photoresist to a substrate tends to be obtained.

When KrF excimer laser (wavelength: 248 nm) lithography system, or a high energy laser such as electron beam and extreme ultraviolet is employed as an exposure system, RESIN (A) preferably comprises a structural unit derived from a monomer having a phenolic-hydroxy group as the monomer having no acid-labile group. When ArF excimer laser (wavelength: 193 nm) is employed as an exposure system, RESIN (A) preferably comprises a structural unit derived from a monomer having an alcoholic-hydroxy group as the monomer having no acid-labile group.

Examples of the monomer having no acid-labile group and having a phenolic-hydroxyl group include those represented by the formula (a2-0):

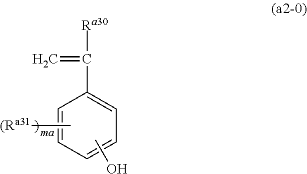

wherein R^{a30} represents a hydrogen atom, a halogen atom, a C1-C6 alkyl group optionally having a halogen atom,
R^{a31} is independently in each occurrence a halogen atom, a hydroxyl group, a C1-C6 alkyl group, a C1-C6 alkoxy group, a C2-C4 acyl group, a C2-C4 acyloxy group, an acryloyl group or a methacryloyl group, ma represents an integer of 0 to 4.

In the formula (a2-0), examples of the halogen atom include a fluorine atom, examples of the C1-C6 alkyl group include a methyl group, an ethyl group, a propyl group, an isopropyl group, a butyl group, an isobutyl group, a sec-butyl group, a tert-butyl group, a pentyl group and a hexyl group, and a C1-C4 alkyl group is preferable and a C1-C2 alkyl group is more preferable and a methyl group is especially preferable. Examples of the C1-C6 halogenated alkyl group include a trifluoromethyl group, a pentafluoroethyl group, a heptafluoropropyl group, a heptafluoroisopropyl group, a nonafluorobutyl group, a nonafluoro-sec-butyl group, a nonafluoro-tert-butyl group, a perfluoropentyl group and a perfluorohexyl group. Examples of the C1-C6 alkoxy group include a methoxy group, an ethoxy group, a propoxy group, an isopropoxy group, a butoxy group, an isobutoxy group, a sec-butoxy group, a tert-butoxy group, a pentyloxy group and a hexyloxy group, and a C1-C4 alkoxy group is preferable and a C1-C2 alkoxy group is more preferable and a methoxy group is especially preferable. Examples of the C2-C4 acyl group include an acetyl group, a propionyl group and a butyryl group, and examples of the C2-C4 acyloxy group include an acetyloxy group, a propionyloxy group and a butyryloxy group. In the formula (a2-0), ma is preferably 0, 1 or 2, and is more preferably 0 or 1, and especially preferably 0.

RESIN (A) which comprises the structural unit derived from the monomer having no acid-labile group and having a phenolic-hydroxyl group can be produced, for example, by polymerizing a monomer in which a phenolic-hydroxy group has been protected with a protecting group such as an acetyl group, for example in a manner of radical polymerization, followed by conducting deprotection of the obtained polymer with an acid or a base. Considering that RESIN (A) generally comprises a structural unit derived from a monomer having an acid-labile group, the deprotection of protected phenolic-hydroxy groups is preferably carried out by contacting the group with a base such as 4-dimethylaminopyridine or triethylamine so that the deprotection does not significantly detract the acid-labile group.

The monomers having no acid-labile group and having a phenolic-hydroxyl group include those described in JP2010-204634A1, which are preferably those represented by formula (a2-0-1) or formula (a2-0-2).

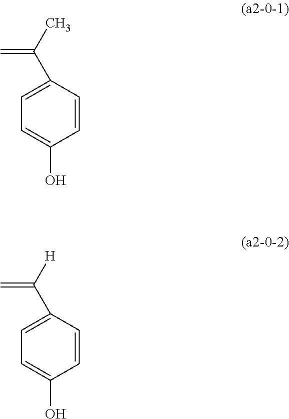

When RESIN (A) comprises a structural unit derived from the monomer of formula (a2-0), the content of the structural unit is usually to 90% by moles, preferably 10 to 85% by moles, and more preferably 15 to 80% by moles, based on total mole number of all the structural units of RESIN (A).

The monomers having no acid-labile group and having an alcoholic-hydroxyl group include those represented by formula (a2-1);

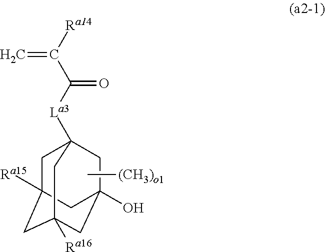

wherein L^{a3} represents —O— or —O— (CH₂)ₖ₂—CO—O—, where k2 represents an integer of 1 to 7 and * is a binding position to —CO—,
R^{a14} represents a hydrogen atom or a methyl group,
R^{a15} and R^{a16} each independently represent a hydrogen atom, a methyl group, or a hydroxy group, and
O1 represents an integer of 0 to 10.

In formula (a2-1), L^{a3} is preferably —O— or —O— (CH₂)_{f1}—CO—O—, where f1 represents an integer of 1 to 4 and * is a binding position to —CO—, and more preferably —O—.

R^{a14} is preferably a methyl group.
R^{a15} is preferably a hydrogen atom.
R^{a16} is preferably a hydrogen atom or a hydroxy group.
O1 is preferably an integer of 0 to 3, and more preferably 0 or 1.

The monomers having no acid-labile group and having a alcoholic-hydroxyl group include those described in JP2010-204646A1, which are preferably those represented by formulae (a2-1-1), (a2-1-2), (a2-1-3), (a2-1-4), (a2-1-5) and (a2-1-6), more preferably those represented by any one of formulae (a2-1-1), (a2-1-2), (a2-1-3) and (a2-1-4), and still more preferably those represented by any formulae (a2-1-1) and (a2-1-3).

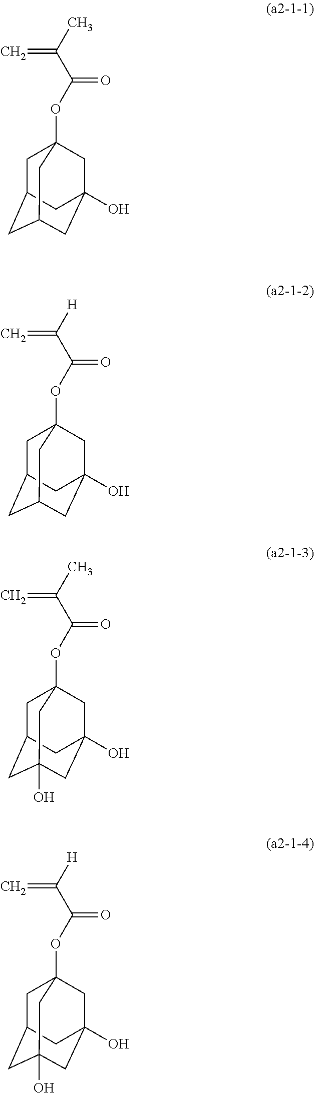 [SMILES: C=C(C)C(=O)OC12CC3CC(CC(O)(C3)C1)C2 ; C=CC(=O)OC12CC3CC(CC(O)(C3)C1)C2 ; C=C(C)C(=O)OC12CC3CC(O)(CC(O)(C3)C1)C2 ; C=CC(=O)OC12CC3CC(O)(CC(O)(C3)C1)C2]

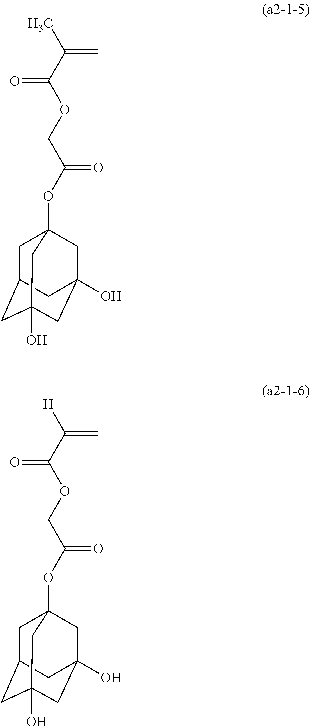 [SMILES: C=C(C)C(=O)OCC(=O)OC12CC3CC(O)(CC(O)(C3)C1)C2 ; C=CC(=O)OCC(=O)OC12CC3CC(O)(CC(O)(C3)C1)C2]

When RESIN (A) comprises a structural unit derived from the monomer of formula (a2-1), the content of the structural unit is usually 3 to 45% by moles, preferably 5 to 40% by moles, more preferably 5 to 35% by moles, based on total mole number of all the structural units of RESIN (A).

Examples of the lactone ring of the monomer having no acid-labile group and a lactone ring include a monocyclic lactone ring such as β-propiolactone ring, γ-butyrolactone ring and δ-valerolactone ring, and a condensed ring formed from a monocyclic lactone ring and the other ring. Among them, preferred are γ-butyrolactone ring and a condensed lactone ring formed from γ-butyrolactone ring and the other ring.

Preferable examples of the monomer having no acid-labile group and a lactone ring include the monomers represented by the formulae (a3-1), (a3-2) and (a3-3):

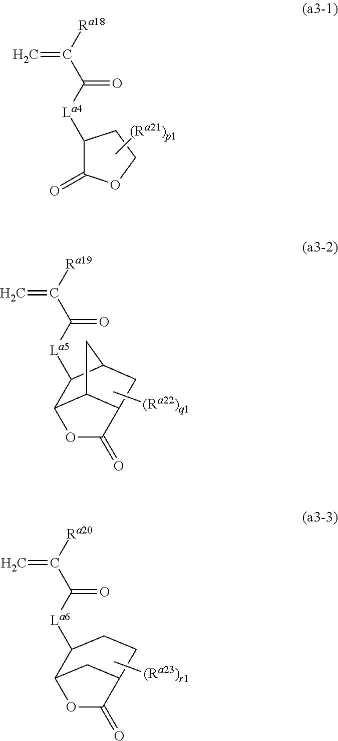

wherein L^{a4}, L^{a5} and L^{a6} each independently represent *—O— or *—O— (CH₂)ₖ₃—CO—O— in which * represents a binding position to —CO— and k3 represents an integer of 1 to 7,
R^{a18}, R^{a19} and R^{a20} each independenyly represent a hydrogen atom or a methyl group,
R^{a22} represents a C1-C4 alkyl group,
R^{a22} and R^{a23} are independently in each occurrence a carboxyl group, a cyano group or a C1-C4 alkyl group, and
p1 represents an integer of 0 to 5, q1 and r1 independently each represent an integer of 0 to 3.

It is preferred that L^{a4}, L^{a5} and L^{a6} each independently represent *—O— or *—O—(CH₂)_{d1}—CO—O— in which * represents a binding position to —CO— and d1 represents an integer of 1 to 4, and it is more preferred that L^{a4}, L^{a5} and L^{a6} are*—O— or *—O—CH₂—CO—O—. R^{a18}, R^{al9} and R^{a20} are preferably methyl groups. R^{a21} is preferably a methyl group. It is preferred that R^{a22} and R^{a23} are independently in each occurrence a carboxyl group, a cyano group or a methyl group. It is preferred that p1 is an integer of 0 to 2, and it is more preferred that p1 is 0 or 1. It is preferred that q1 and r1 independently each represent an integer of 0 to 2, and it is more preferred that q1 and r1 independently each represent 0 or 1.

Examples of the monomer having no acid-labile group and a lactone ring include those described in JP2010-204646. Preferred are the monomers represented by the formulae (a3-1-1), (a3-1-2), (a3-1-3), (a3-1-4), (a3-2-1), (a3-2-2), (a3-2-3), (a3-2-4), (a3-3-1), (a3-3-2), (a3-3-3) and (a3-3-4), more preferred are the monomers represented by the formulae (a3-1-1), (a3-1-2), (a3-2-3), and (a3-2-4), and still more preferred are the monomers represented by the formulae (a3-1-1) and (a3-2-3).

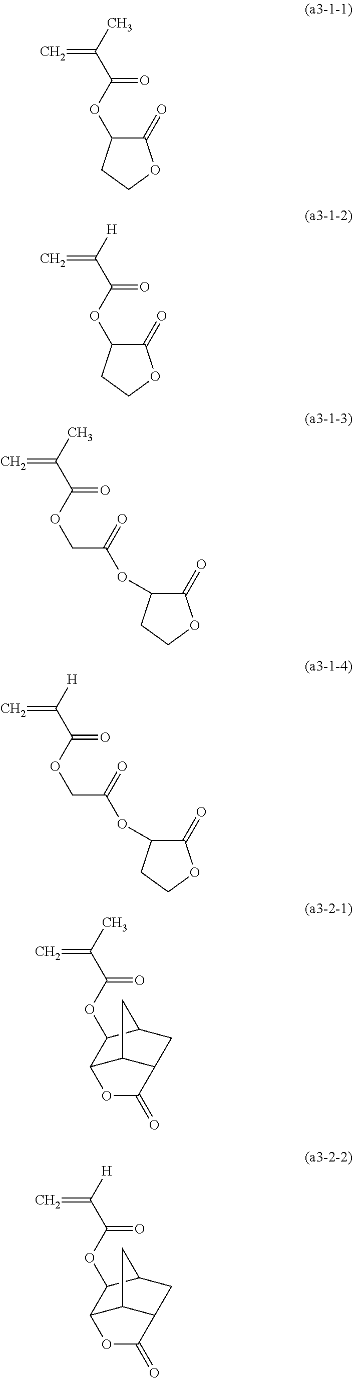

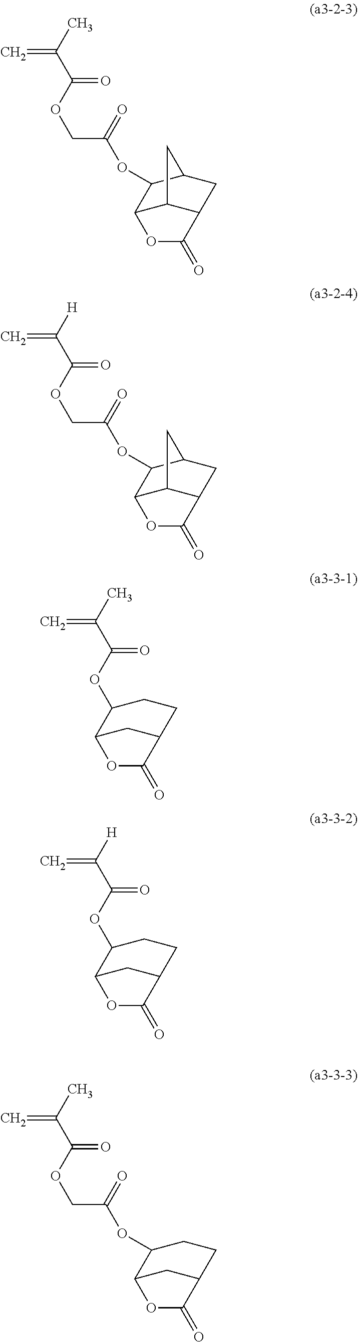 [SMILES: C=C(C)C(=O)OCC(=O)OC1C2CC3C(=O)OC1C3C2 ; C=CC(=O)OCC(=O)OC1C2CC3C(=O)OC1C3C2 ; C=C(C)C(=O)OC1CCC2CC1OC2=O ; C=CC(=O)OC1CCC2CC1OC2=O ; C=C(C)C(=O)OCC(=O)OC1CCC2CC1OC2=O]

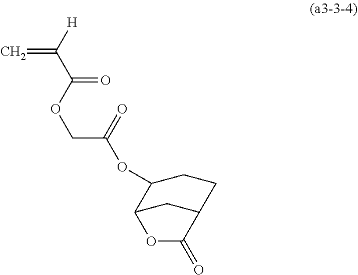 [SMILES: C=CC(=O)OCC(=O)OC1CCC2CC1OC2=O]

When RESIN (A) comprises a structural unit derived from the monomer having no acid-labile group but a lactone ring, the content of the structural unit is usually 5 to 70% by moles, preferably 10 to 65% by moles, more preferably 10 to 60% by moles, based on total mole number of all the structural units of RESIN (A).

RESIN (A) may comprise any other structural units than one derived from the monomers as mentioned above.

RESIN (A) is generally a copolymer which comprises the structural unit derived from the monomer having an acid labile group, and the structural unit derived from the monomer having no acid labile group,

preferably a copolymer which comprises the structural unit derived from the monomer having an acid labile group, and the structural unit derived from the monomer having no acid labile group but a phenolic-hydroxyl group and/or the structural unit derived from the monomer having no acid labile group but a lactone ring.

In the copolymer, the monomer having an acid labile group is preferably a monomer represented by any one of formulae (a1-1) and (a1-2), more preferably a monomer represented by formula (a1-1). In the copolymer, the monomer having no acid labile group but a phenolic-hydroxyl group is preferably the monomer represented by formula (a2-1).

In the copolymer, the monomer having no acid labile group but a lactone ring is preferably the monomer represented by formulae (a3-1) and (a3-2).

RESIN (A) can be produced according to known polymerization methods such as radical polymerization.

RESIN (A) usually has 2,500 or more of the weight-average molecular weight, preferably 3,000 or more of the weight-average molecular weight. The resin usually has 50,000 or less of the weight-average molecular weight, preferably has 30,000 or less of the weight-average molecular weight.

The weight-average molecular weight can be measured with gel permeation chromatography (standard: polystyrene).

The photoresist composition of the present invention comprises RESIN (A) in amount of preferably 10% to 95% by mass, more preferably 20% to 85% by mass of the total amount of solid components.

The photoresist composition of the present invention may comprise a quencher, a compound which traps an acid generated from an acid generator. The quencher for the photoresist composition includes the basic compound and the compound represented by formula (D) as described later.

The basic compound is preferably a basic nitrogen-containing organic compound, and examples thereof include an amine compound such as an aliphatic amine and an aromatic amine and an ammonium salt. Examples of the aliphatic amine include a primary amine, a secondary amine and a tertiary amine. Examples of the aromatic amine include an aromatic amine in which aromatic ring has one or more amino groups such as aniline and a heteroaromatic amine such as pyridine.

The basic compounds include preferably a compound represented by the formulae (C1), (C2), (C3), (C4), (C5), (C6), (C7) and (C8), more preferably a compound represented by the formulae (C1), still more preferably a compound represented by the formulae (C1-1).

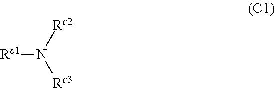

wherein R^{c1}, R^{c2} and R^{c3} independently represent a hydrogen atom, a C1-C6 alkyl group, a C5-C10 alicyclic hydrocarbon group or a C6-C10 aromatic hydrocarbon group, and the alkyl group and the alicyclic hydrocarbon group can have a substituent selected from the group consisting of a hydroxy group, an amino group and a C1-C6 alkoxy group, and the aromatic hydrocarbon group can have a substituent selected from the group consisting of C1-C6 alkyl groups, a C5-C10 alicyclic hydrocarbon group, a hydroxy group, an amino group, and a C1-C6 alkoxy group,

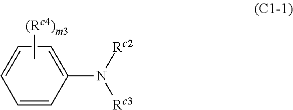

wherein R^{c2} and R^{c3} are defined as above, each of R^{c4} independently represents a C1-C6 alkyl group, a C1-C6 alkoxy group, a C5-C10 alicyclic hydrocarbon group or a C6-C10 aromatic hydrocarbon group, and m3 represents an integer of 0 to 3,

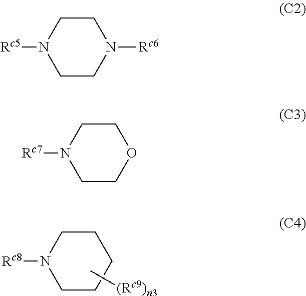

wherein R^{c5}, R^{c6}, R^{c7} and R^{c8} are defined same as R^{c1}, each of R^{c9} independently represents a C1-C6 alkyl group, a C3-C6 alicyclic hydrocarbon group, or a C2-C6 alkanoyl group, and n3 represents an integer of 0 to 8,

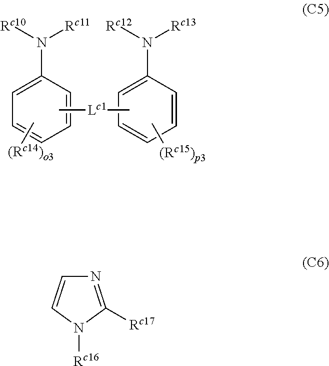

wherein each of R^{c10}, R^{c11}, R^{c12}, R^{c13} and R^{c16} is defined same as R^{c1}, each of R^{c14}, R^{c15} and R^{c17} is defined same as R^{c4},
L^{c1} represents a C1-C6 alkanediyl group, a carbonyl group, —C(═NH)—, a sulfur atom or a combination thereof, and o3 and p3 respectively represent an integer of 0 to 3,

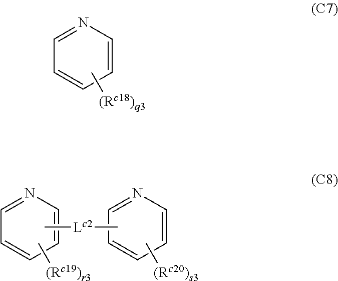

wherein each of R^{c18}, R^{c19} and R^{c20} is defined same as R^{c4}, L^{c2} represents a single bond, a C1-C6 alkanediyl group, a carbonyl group, —C(═NH)—, a sulfur atom or a combination thereof, and q3, r3 and p3 respectively represent an integer of 0 to 3.

Examples of the compound represented by the formula (C1) include 1-naphthylamine, 2-naphthylamine, aniline, diisopropylaniline, 2-methylaniline, 3-methylaniline, 4-methylaniline, 4-nitroaniline, N-methylaniline, N,N-dimethylaniline, diphenylamine, hexylamine, heptylamine, octylamine, nonylamine, decylamine, dibutylamine, dipentylamine, dihexylamine, diheptylamine, dioctylamine, dinonylamine, didecylamine, triethylamine, trimethylamine, tripropylamine, tributylamine, tripentylamine, trihexylamine, triheptylamine, trioctylamine, trinonylamine, tridecylamine, methyldibutylamine, methyldipentylamine, methyldihexylamine, methyldicyclohexylamine, methyldiheptylamine, methyldioctylamine, methyldinonylamine, methyldidecylamine, ethyldibutylamine, ethydipentylamine, ethyldihexylamine, ethydiheptylamine, ethyldioctylamine, ethyldinonylamine, ethyldidecylamine, dicyclohexylmethylamine, tris[2-(2-methoxyethoxy)ethyl]amine, triisopropanolamine, ethylenediamine, tetramethylenediamine, hexamethylenediamine, 4,4′-diamino-1,2-diphenylethane, 4,4′-diamino-3,3′-dimethyldiphenylmethane and 4,4′-diamino-3,3′-diethyldiphenylmethane. Among them, preferred is diisopropylaniline and more preferred is 2,6-diisopropylaniline

Examples of the compound represented by the formula (C2) include piperazine.

Examples of the compound represented by the formula (C3) include morpholine.

Examples of the compound represented by the formula (C4) include piperidine and hindered amine compounds having a piperidine skeleton as disclosed in JP 11-52575 A1.

Examples of the compound represented by the formula (C5) include 2,2′-methylenebisaniline.

Examples of the compound represented by the formula (C6) include imidazole and 4-methylimidazole.

Examples of the compound represented by the formula (C7) include pyridine and 4-methylpyridine.

Examples of the compound represented by the formula (C8) include di-2-pyridylketone, 1,2-di(2-pyridyl)ethane, 1,2-di(4-pyridyl)ethane, 1,3-di(4-pyridyl)propane, 1,2-bis(2-pyridyl)ethene, 1,2-bis(4-pyridyl)ethene, 1,2-di(4-pyridyloxy)ethane, 4,4′-dipyridyl sulfide, 4,4′-dipyridyl disulfide, 2,2′-dipyridylamine, 2,2′-dipicolylamine and bipyridine.

Examples of the ammonium salt include tetramethylammonium hydroxide, tetrabutylammonium hydroxide, tetrahexylammonium hydroxide, tetraoctylammonium hydroxide, phenyltrimethylammonium hydroxide, (3-trifluoromethylphenyl)trimethylammonium hydroxide and (2-hydroxyethyl)trimethylammonium hydroxide (so-called “choline”).

Another Example of the quencher includes a nitrogen-containing compound as mentioned in US2011/0201823A1.

When the photoresist composition contains the basic compound, the content thereof is preferably 0.01 to 5% by weight, more preferably 0.01 to 3% by weight, still more preferably 0.01 to 1% by weight of the total amount of solid component.

The compound represented by formula (D) can be used as a quencher for the photoresist composition of the present invention.

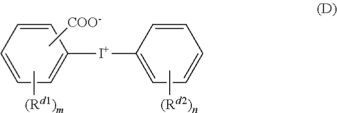

wherein R^{d1} and R^{d2} independently in each occurrence represent a C1-C12 hydrocarbon group, a C1-C6 alkoxy group, a C2-C7 acyl group, a C2-C7 acyloxy group, a C2-C7 alkoxycarbonyl group, a nitro group or halogen atom, and m and n independently represent an integer of 0 to 4.

The hydrocarbon groups represented by R^{d1} and R^{d2} include an aliphatic hydrocarbon group, an alicyclic hydrocarbon group, an aromatic hydrocarbon group and these combinations.

The aliphatic hydrocarbon group includes a C1-C12 alkyl groups such as methyl radical, an ethyl group, a propyl group, isopropyl radical, butyl, isobutyl, t-butyl, a pentyl group, a hexyl group, a nonyl group.

The alicyclic hydrocarbon group includes monocyclic and polycyclic ones. Examples of which include a C3-C12 cycloalkyl group such as a cyclopropyl group, cyclobutyl, a cyclopentyl group, a cyclohexyl group, a cyclononyl group or cyclo-dodecyl, and a norbornyl group and an adamantyl group.

The aromatic hydrocarbon groups include C6-C12 aryl groups such as a phenyl group, 1-naphthyl group, 2-naphthyl group, 2-methylphenyl group, 3-methylphenyl group, 4-methylphenyl group, 4-ethylphenyl group, 4-propylphenyl group, 4-isopropylphenyl group, 4-butylphenyl group, 4-t-butylphenyl group, 4-hexylphenyl group, 4-cyclohexylphenyl group, antolyl group, p-adamantylphenyl group, a tolyl group, a xylyl group, a cumenyl group, a mesityl group, a biphenyl group, a phenanthryl group, a 2,6-diethylphenyl group, 2-methyl-6-ethylphenyl group.

These combinations include an alkylcycloalkyl groups, a cycloalkylalkyl group, aralkyl groups (e.g., phenylmethyl group, 1-phenylethyl group, 2-phenylethyl group, 1-phenyl-1-propyl group, 1-phenyl-2-propyl group, 2-phenyl-2-propyl group, 3-phenyl-1-propyl group, 4-phenyl-1-butyl, a 5-phenyl-1-pentyl group, and a 6-phenyl-1-hexyl group).

The alkoxy groups include a methoxy group, and an ethoxy group.

The acyl groups include an acetyl group, a propanoyl group, a benzoyl group, and a cyclohexanecarbonyl group.

The acyloxy group includes those in which an oxygen atom (—O—) is attached to a carbon atom constituting a carbonyl group of the acyl group mentioned above.

The alkoxycarbonyl group includes those in which a carbonyl group (—CO—) is attached to an oxygen atom constituting the alkoxy group mentioned above.

The halogen atoms include a fluorine atom, a chlorine atom, or a bromine atom.

In formula (D), each of R^{d1} and R^{d2} preferably represents a C1-C8 alkyl group, a C3-C10 cycloalkyl groups, a C1-C6 alkoxy group, a C2-C4 acyl group, a C2-C4 acyloxy group, a C2-C4 alkoxycarbonyl group, a nitro group or a halogen atom.

The m and n each represents an integer of preferably 0-2, more preferably 0.

The compound represented by formula (D) includes the following ones.

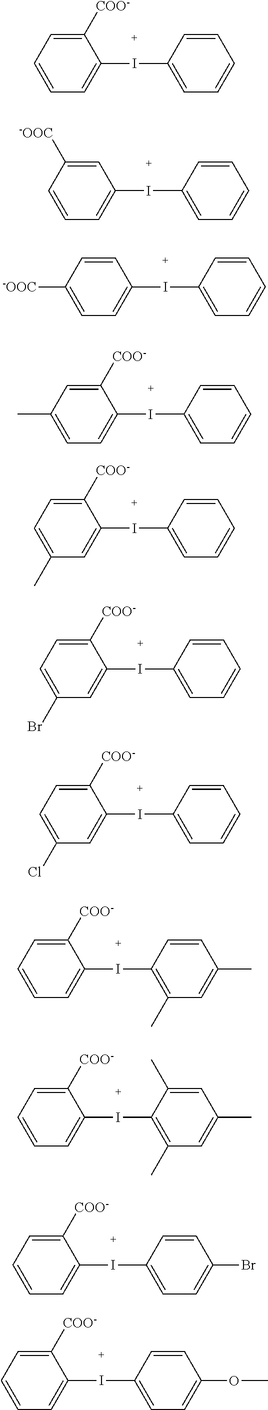

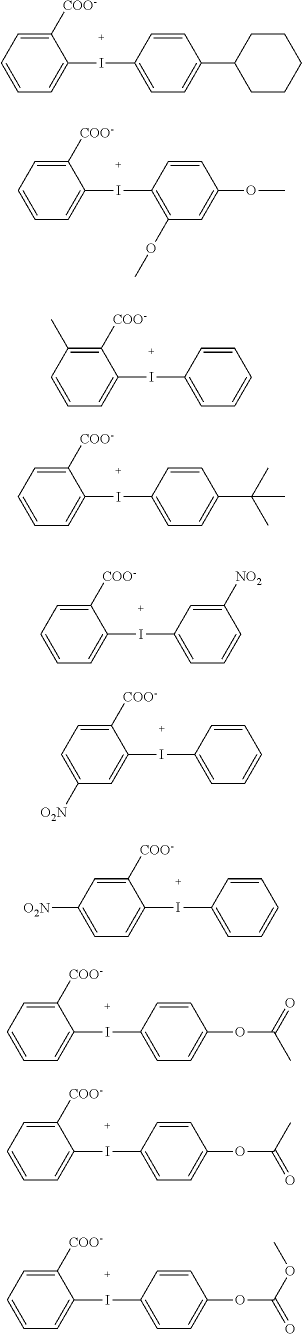

The compound represented by formula (D) can be prepared by the method of mention in “Tetrahedron Vol. 45, No. 19, p6281-6296”, which is commercially available.

The content of the compound represented by formula (D) is preferably 0.01 to 5% by weight, and more preferably 0.01 to 3% by weight of the total amount of the solid components in the photoresist composition of the present invention.

The photoresist composition of the present invention usually contains one or more solvents. Examples of the solvent include a glycolether ester such as ethylcellosolve acetate, methylcellosolve acetate and propyleneglycolmonomethylether acetate; a glycol ether such as propylene glycol monomethylether; an acyclic ester such as ethyl lactate, butyl acetate, amyl acetate and ethyl pyruvate; a ketone such as acetone, methyl isobutyl ketone, 2-heptanone and cyclohexanone; and a cyclic ester such as γ-butyrolactone.

The amount of the solvent is usually 90% by weight or more, preferably 92% by weight or more, preferably 94% by weight or more based on total amount of the photoresist composition of the present invention. The amount of the solvent is usually 99.9% by weight or less and preferably 99% by weight or less, based on total amount of the photoresist composition of the present invention.

The photoresist composition of the present invention may comprise, if necessary, a small amount of various additives such as a sensitizer, a dissolution inhibitor, other polymers, a surfactant, a stabilizer and a dye as long as the effect of the present invention is not prevented.

The photoresist compositions of the present invention can usually be prepared by mixing, in a solvent, COMPOUND (I) and the salt represented by formula (B1), and if necessary RESIN (A), a basic compound, the compound represented by formula (D) and/or additives at a suitable ratio for the composition, optionally followed by filtrating the mixture with a filter having from 0.003 to 0.2 μm of a pore size.

The order of mixing these components is not limited to any specific order. The temperature at mixing the components is usually 10 to 40° C., which can be selected in view of the resin or the like.

The mixing time is usually 0.5 to 24 hours, which can be selected in view of the temperature. The means for mixing the components is not limited to specific one. The components can be mixed by being stirred.

The photoresist composition of the present invention is useful for a chemically amplified photoresist composition.

A photoresist pattern can be produced by the following steps (1) to (5):

(1) a step of applying the photoresist composition of the present invention on a substrate,

(2) a step of forming a photoresist film by conducting drying,

(3) a step of exposing the photoresist film to radiation,

(4) a step of baking the exposed photoresist film, and

(5) a step of developing the baked photoresist film thereby forming a photoresist pattern.

The applying of the photoresist composition on a substrate is usually conducted using a conventional apparatus such as spin coater. Examples of the substrate include a silicon wafer or a quartz wafer on which a sensor, a circuit, a transistor or the like has been formed.

The substrate may be washed, or coated with a reflect-preventing layer such as one containing hexamethyldisilazane. For forming the reflect-preventing layer, such composition for organic reflect-preventing layer as available on the market can be used.

The formation of the photoresist film is usually conducted using a heating apparatus such as hot plate or a decompressor, and the heating temperature is usually 50 to 200° C., and the operation pressure is usually 1 to 1.0*10⁵ Pa.

The photoresist film obtained is exposed to radiation using an exposure system. The exposure is usually conducted through a mask having a pattern corresponding to the desired photoresist pattern. Examples of the exposure source include a light source radiating laser light in a UV-region such as a KrF excimer laser (wavelength: 248 nm), an ArF excimer laser (wavelength: 193 nm) and a F₂ laser (wavelength: 157 nm), and a light source radiating harmonic laser light in a far UV region or a vacuum UV region by wavelength conversion of laser light from a solid laser light source (such as YAG or semiconductor laser). The exposure may be conducted without using a mask, for example in case of using electron beam as exposure source.

The temperature of baking of the exposed photoresist film is usually 50 to 200° C., and preferably 70 to 150° C.

The development of the baked photoresist film is usually carried out with a developer using a development apparatus.

The development can be carried out in manner of known methods such as dipping, paddle, spray, or dynamic dispense method. The temperature of development is preferably 5 to 60° C. The time for development is usually 5 to 300 seconds.

The photoresist composition can provide positive or negative photoresist pattern. Each type of the pattern can be selectively made by development with a developer capable of providing desired pattern.

When a positive photoresist pattern is made from the photoresist composition of the present invention, an alkaline developer may be employed as a developer. The alkaline developer to be used may be any one of various alkaline aqueous solution used in the art. Generally, an aqueous solution of tetramethylammonium hydroxide or (2-hydroxyethyl)trimethylammonium hydroxide (commonly known as “choline”) is often used. The alkaline developer may contain a surfactant.

After development, the formed photoresist pattern is preferably washed with ultrapure water, and the remained water on the photoresist pattern and the substrate is preferably removed.

When a negative photoresist pattern is made from the photoresist composition of the present invention, organic solvent-containing developers may be employed as a developer.

The organic solvent for the developers includes ketone solvents such as 2-hexanone or 2-heptanone; glycoletherester solvents such as propyleneglycolmonomethylether acetate; ester solvents such as butyl acetate; glycolether solvents such as propyleneglycolmonomethylether; amide solvents such as N,N-dimethylacetoamide; and aromatic hydrocarbon solvents such as anisole.

The organic solvent-containing developer preferably comprises butyl acetate, 2-heptanone, or both of them.

When the organic solvent-containing developer comprises butyl acetate and 2-heptanone, the total content of them is preferably 50 to 100% by mole, more preferably 90 to 100% by mole, and the developer still more preferably consists substantially of butyl acetate and 2-heptanone.

The organic solvent-containing developer may comprise surfactants or water.

The content of the organic solvent in the organic solvent-containing developer is preferably 90 to 100% by mole, more preferably 95 to 100% by mole. The organic solvent-containing developer still more preferably consists of organic solvents.

Development can be stopped by replacing the organic solvent-containing developer by another solvent.

The negative-type photoresist pattern after development is preferably washed with solvents in which the pattern is not dissolved.

The solvents for this washing include alcohol solvents or ester solvents. It is preferred that the solvents on the substrate or the pattern are removed therefrom after washing them.

The photoresist composition of the present invention provides a photoresist pattern with high resolution, which is suitable for KrF excimer laser lithography, ArF excimer laser lithography, EUV (extreme ultraviolet) lithography, and EB (electron beam) lithography. Further, the photoresist composition of the present invention can especially be used for EUV lithography and EB lithography, which is available to fine processing for semiconductors.

### EXAMPLES

The present invention will be described more specifically by Examples, which are not construed to limit the scope of the present invention. The “%” and “part(s)” used to represent the content of any component and the amount of any material to be used in the following Examples are on a weight basis unless otherwise specifically noted.

The structure of the compounds were determined by spectrometry with Agilent type 1100 [Agilent Technologies; equipped with LC part and LC/MCD part].

### Synthetic Example 1

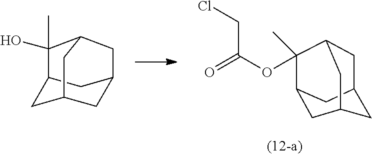 [SMILES: CC1(O)C2CC3CC(C2)CC1C3 ; CC1(OC(=O)CCl)C2CC3CC(C2)CC1C3]

Fed were 25 parts of 2-methyl-2-adamantanol and 200 parts of tetrahydrofuran in a reactor, followed by stirring them at room temperature. After confirming that 2-methyl-2-adamantanol had been dissolved, 14.27 parts of pyridine was fed thereinto and then the temperature of the mixture was raised to 40° C.

Furthermore, the mixture of 25.47 parts of chloroacetyl chloride and 50 parts of tetrahydrofuran was dropped thereto over 1 hour, followed by stirring it 40° C. for 8 hours. After stirring it, the temperature of the reaction mixture was cooled to 5° C. and then 100 parts of ion exchanged water which had been cooled to 5° C. was added thereto and stirred, followed by separating an aqueous layer therefrom.

To the aqueous layer 65 parts of ethyl acetate was added, followed by separating into an organic layer therefrom. To the organic layer, 65 parts of 10% aqueous potassium carbonate at 5° C. was added and washed with it, followed by separating into an organic layer therefrom.

To the washed organic layer, 65 parts of ion exchanged water was added and washed with it, followed by separating into an organic layer therefrom, which operations were conducted three times. The organic layer after washing with water was concentrated, and then 40 parts of n-heptane was added to the obtained concentrates and stirred, followed by filtrating it. The filtrates were dried to obtain 17.62 parts of compounds represented by formula (I2-a).

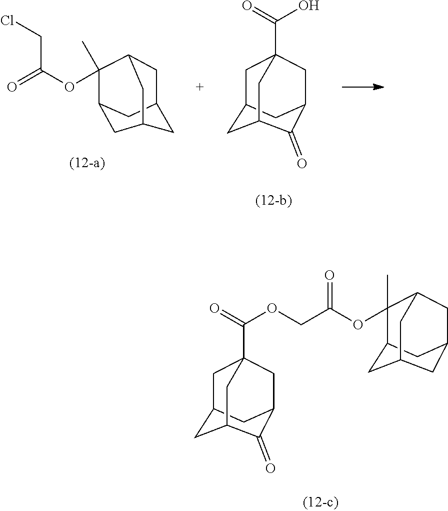 [SMILES: CC1(OC(=O)CCl)C2CC3CC(C2)CC1C3 ; O=C1C2CC3CC1CC(C(=O)O)(C3)C2 ; CC1(OC(=O)COC(=O)C23CC4CC(C2)C(=O)C(C4)C3)C2CC3CC(C2)CC1C3]

Fed were 15 parts of compounds represented by formula (I2-b) and 75 parts of N,N′-dimethylformamide into a reactor and then the mixture was stirred at 23° C. for 30 minutes. After stirring it, 6.4 parts of potassium carbonate and 1.92 parts of potassium iodides were fed thereinto and then stirred at 50° C. for one hour. Dissolving 16.87 parts of the compound represented by formula (I2-a) in 33.74 parts of N,N′-dimethylformamide, the obtained solution was dropped to the obtained mixture over 1 hour, and then stirred at 50° C. for 5 hours. The reaction mixture was cooled to 23° C., and then 300 parts of ethyl acetate and 150 parts of ion exchanged water was added and stirred to separate into an organic layer therefrom.

The organic layer was repeatedly washed with 150 parts of ion exchanged water until the separated aqueous layer becomes neutral.

The organic layer after washing with water was concentrated, and then 150 parts of n-heptane was added to the obtained concentrates and stirred, followed by filtrating it. The filtrates were dried to obtain 22.67 parts of compounds represented by formula (I2-c).

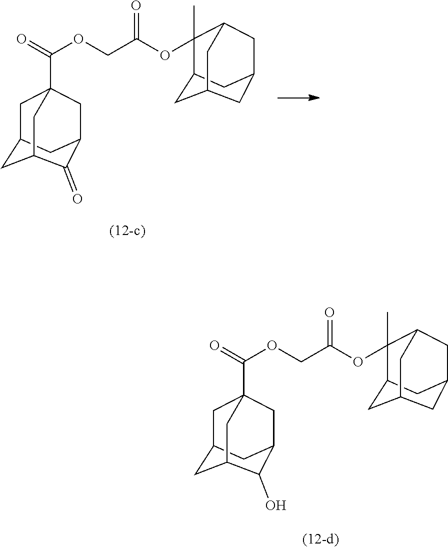 [SMILES: CC1(OC(=O)COC(=O)C23CC4CC(C2)C(=O)C(C4)C3)C2CC3CC(C2)CC1C3 ; CC1(OC(=O)COC(=O)C23CC4CC(C2)C(O)C(C4)C3)C2CC3CC(C2)CC1C3]

Fed were 15 parts of compounds represented by formula (I2-c) and 75 parts of acetonitrile into a reactor, and the mixture was stirred at 23° C. for 30 minutes, followed by cooling it to 5° C. Thereinto 0.71 parts of sodium borohydride and 10.63 parts of ion exchanged water were fed and then stirred at 5° C. for 3 hours. Furthermore, 50 parts of ion exchanged water and 100 parts of ethyl acetate were fed to the reaction mixture, followed by separating into an organic layer therefrom.

The organic layer was repeatedly washed with 50 parts of ion exchanged water until the separated aqueous layer became neutral.

The organic layer after washing with water was concentrated, and then 12.43 parts of compounds represented by formula (I2-d) was separated therefrom by Silica gel column chromatography under the following condition; Column (60-200 mesh, Merck & Co.; Solvent: ethyl acetate).

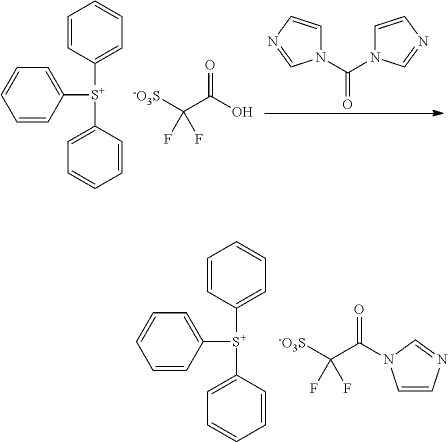

Triphenylsulfonium difluorocarboxylmethanesulfonate was obtained by a method mentioned in JP2008-127367A1.

Fed were 10 parts of triphenylsulfonium difluorocarboxylmethanesulfonate and 60 parts of acetonitrile thereinto, followed by stirring the mixture at 40° C. for 30 minutes.

Then 4.44 parts of 1,1′-carbonyldiimidazole was added thereto and stirred at 50° C. for 1 hour to obtain triphenylsulfonium 1-imidazolylcarbonyldifluoromethanesulfonate.

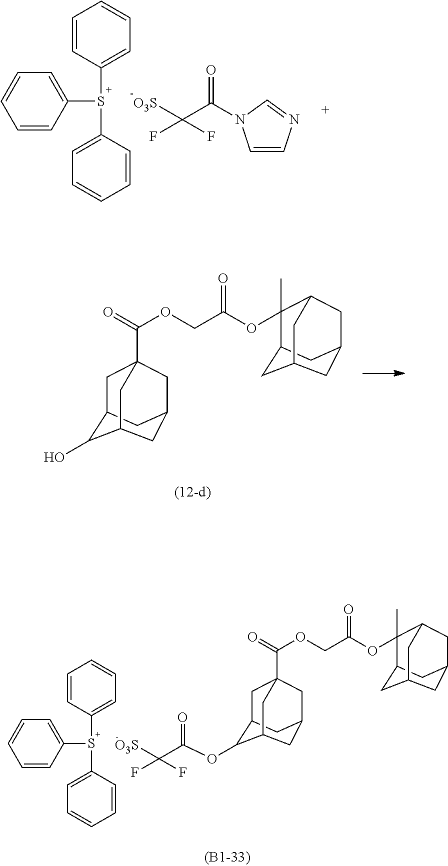

To the solution containing triphenylsulfonium 1-imidazolylcarbonyldifluoromethanesulfonate, 9.19 parts of the compound represented by formula (I2-d) and stirred at 23° C. for 1 hour. To the obtained reaction mixture, 100 parts of chloroform and 50 parts of ion exchanged water were fed and stirred to separate an organic layer therefrom. The organic layer was washed with water 5 times. To the washed organic layer 1 part of active carbon was added and stirred at 23° C. for 30 minutes, followed by filtrating it. The filtrates were concentrated and 50 parts of acetonitrile was added to the obtained concentrate to solve it, and then the mixture was concentrated and 50 parts of ethyl acetate was added thereto, followed by stirring it. Then a supernatant was removed therefrom. To the obtained residue, 50 parts of tert-butylmethylether was added and stirred, followed by removing its supernatant therefrom. To the obtained residue, chloroform was added and the obtained mixture was concentrated, followed by separating 16.84 parts of salt represented by formula (B1-33) with the Silica gel column (60-200 mesh, Merck; development solvents: chloroform/methanol=5/1)

### MS (ESI(+) Spectrum):M⁺ 263.1

### MS (ESI(−) Spectrum):M⁻ 559.2

### Synthetic Example 2

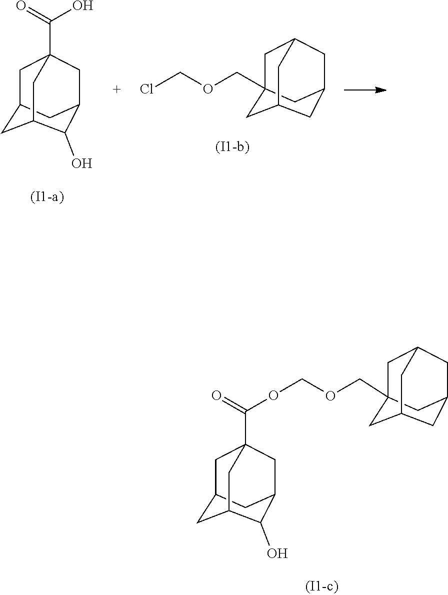 [SMILES: O=C(O)C12CC3CC(C1)C(O)C(C3)C2 ; ClCOCC12CC3CC(CC(C3)C1)C2 ; O=C(OCOCC12CC3CC(CC(C3)C1)C2)C12CC3CC(C1)C(O)C(C3)C2]

Fed were 5 parts of compounds represented by formula (I1-a) and 25 parts of dimethylformamide into a reactor, and the mixture was stirred at 23° C. for 30 minutes. After stirring, 3.87 parts of triethylamine was dropped thereto and then stirred at 23° C. for 30 minutes. To the obtained mixture, a solution where 6.57 parts of the compound represented by formula (I1-b) has been dissolved in 6.57 parts of dimethylformamide was dropped thereto over 30 minutes and then stirred at 23° C. for 2 hours.

Furthermore, 23.5 parts of ion exchanged water and 140.99 parts of ethyl acetate were fed to the reaction mixture and then stirred at 23° C. for 30 minutes, followed by separating into an organic layer therefrom.

To collected organic layer, 70.5 parts of ion exchanged water was added and then stirred at 23° C. for 30 minutes, followed by separating into an organic layer therefrom. Such washing with water was conducted 6 times. The organic layer after washing with water was concentrated, and then 92.2 parts of n-heptane was added thereto and stirred, followed by filtrating it to obtain 2.85 parts of the compound represented by formula (I1-c).

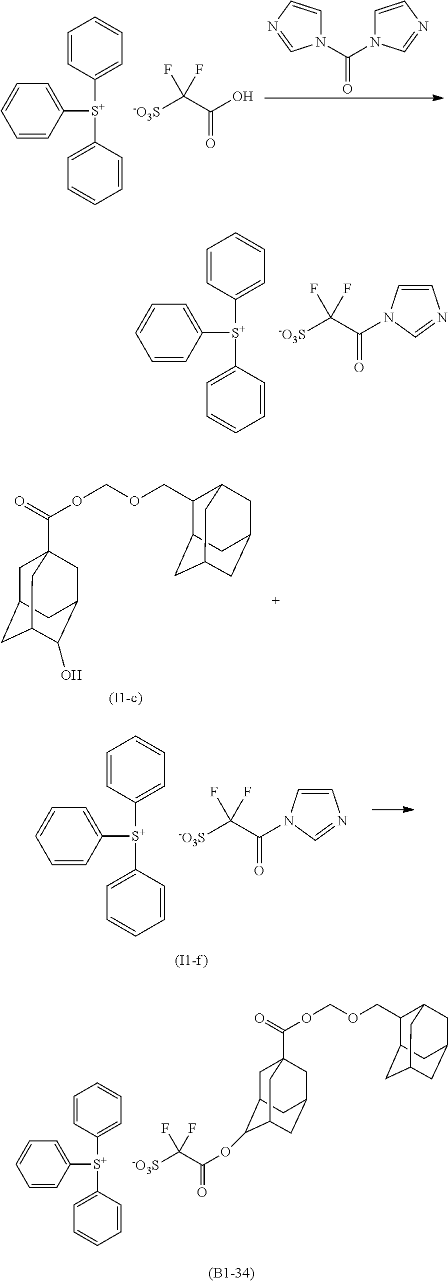

Triphenylsulfonium difluorocarboxylmethanesulfonate was obtained by a method mentioned in JP2008-127367A1. Fed were 2.99 parts of triphenylsulfonium difluorocarboxylmethanesulfonate and 15 parts of acetonitrile thereinto, followed by stirring the mixture at 23° C. for 30 minutes. Then 1.3 parts of 1,1′-carbonyldiimidazole was added thereto and stirred at 70° C. for 2 hours. Then the obtained reaction mixture was cooled to 23° C. and filtrated to obtain a solution containing triphenylsulfonium 1-imidazolylcarbonyldifluoromethanesulfonate.

Dissolving 2.3 parts of compounds represented by formula (I1-c) in 6.89 parts of chloroform, the obtained solution was fed into the solution containing triphenylsulfonium 1-imidazolylcarbonyldifluoromethanesulfonate, followed by stirring the mixture at 23° C. for 23 hours. The obtained reaction mixture was concentrated, and then 58.47 parts of chloroform and 29.24 parts of 2% aqueous oxalic acid solution were added to the obtained concentrates and stirred, followed by separating into an organic layer. Such washing with aqueous oxalic acid solution was conducted twice. To the obtained organic layer, 29.24 parts of ion exchanged water was added and stirred, followed by separating into an organic layer. Such washing with water was conducted 4 times. The washed organic layer was concentrated and then the obtained concentrates were dissolved in 27.27 parts of acetonitrile, followed by concentrating it. To the obtained concentrates, 70 parts of tert-butylmethylether was added and then stirred, followed by removing its supernatant therefrom. The obtained residue was dissolved in acetonitrile, followed by concentrating the solution to 3.58 parts of salt represented by formula (B1-34).

### MASS(ESI(+) Spectrum):M⁺ 263.1

### MASS(ESI(−) Spectrum):M⁻ 531.2

### Synthetic Example 3

The salt represented by the following formula was obtained by the method mentioned in JP2008-69146A1.

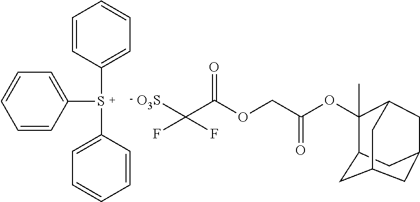

### Synthetic Example 4

The compounds represented by formulae A1, A2, A3 and A4 were obtained by the method mentioned in JP2010-159241A1 and JP2010-235376A1.

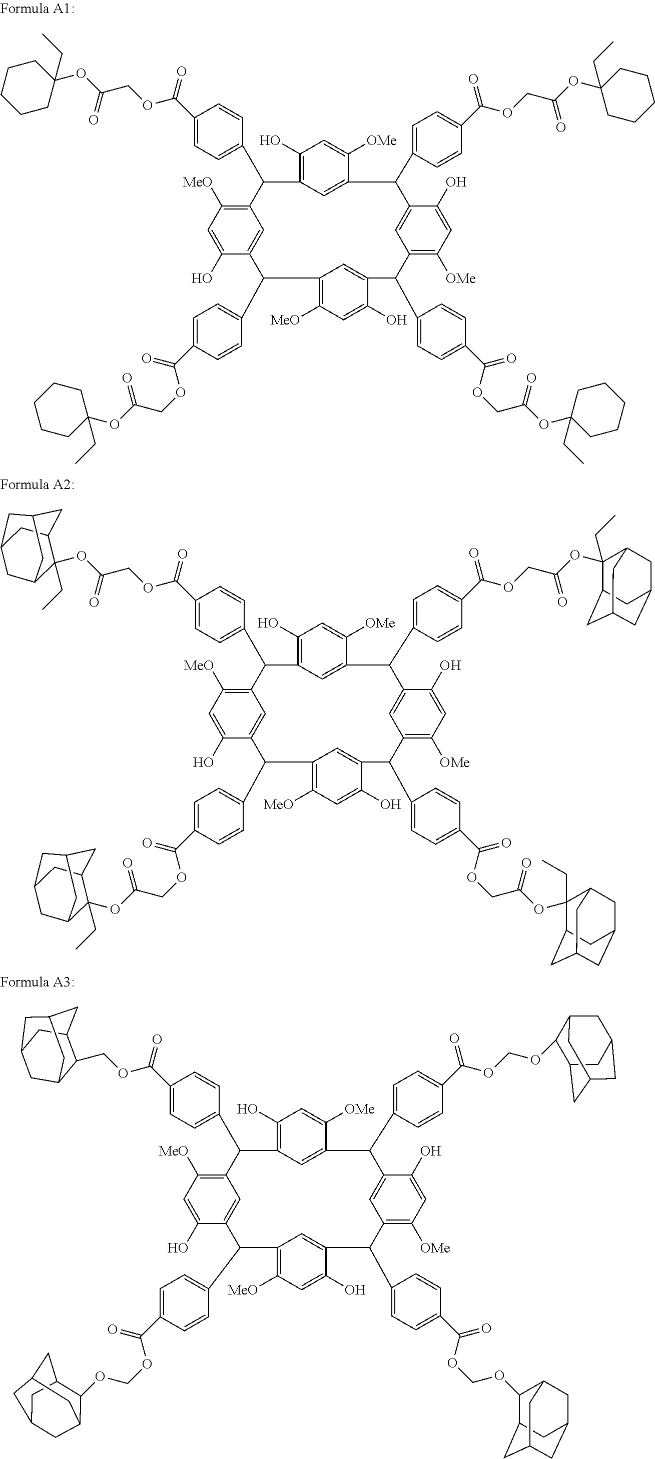

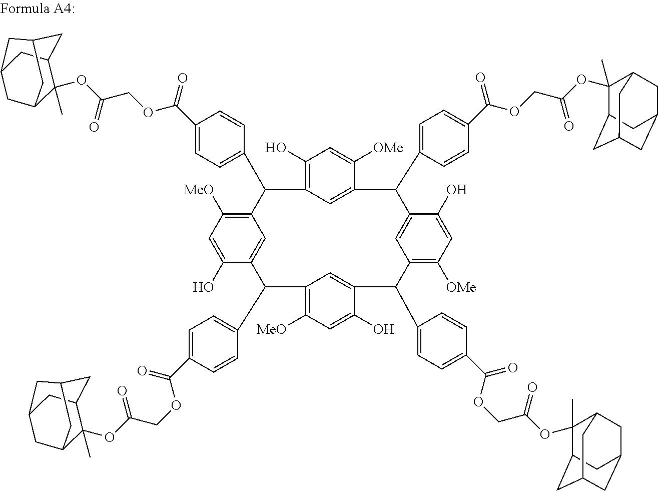 [SMILES: COc1cc(O)c2cc1C(c1ccc(C(=O)OCC(=O)OC3(C)C4CC5CC(C4)CC3C5)cc1)c1cc(c(OC)cc1O)C(c1ccc(C(=O)OCC(=O)OC3(C)C4CC5CC(C4)CC3C5)cc1)c1cc(c(OC)cc1O)C(c1ccc(C(=O)OCC(=O)OC3(C)C4CC5CC(C4)CC3C5)cc1)c1cc(c(OC)cc1O)C2c1ccc(C(=O)OCC(=O)OC2(C)C3CC4CC(C3)CC2C4)cc1]

### Examples 1 to 24 and Comparative Example 1

The components used for the examples and the comparative examples are followings.

### <Compound I>

A1: The compound represented by formula A1
A2: The compound represented by formula A2
A3: The compound represented by formula A3
A4: The compound represented by formula A4

### <Acid Generator>

Z1: Triphenylsulfonium=nonafluorobutanesulfonate
B1-1: The compound represented by the following formula, prepared by such a method as mentioned in JP2008-74843A1

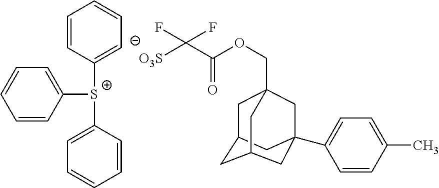

B1-2: The compound represented by the following formula

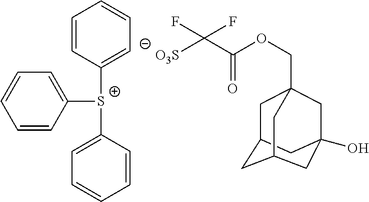

B1-3: The compound represented by the following formula

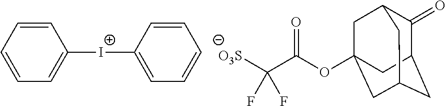

B1-4: The compound represented by the following formula

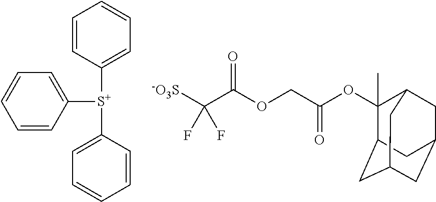

B1-5: The compound represented by the following formula

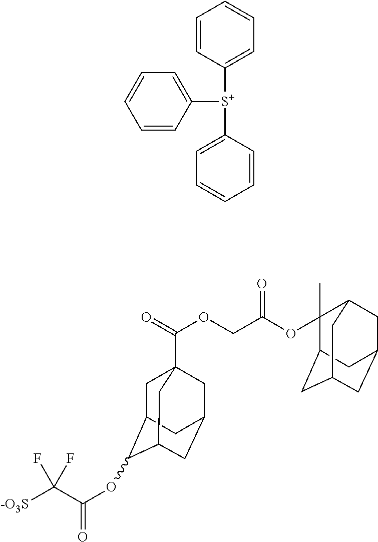

B1-6: The compound represented by the following formula

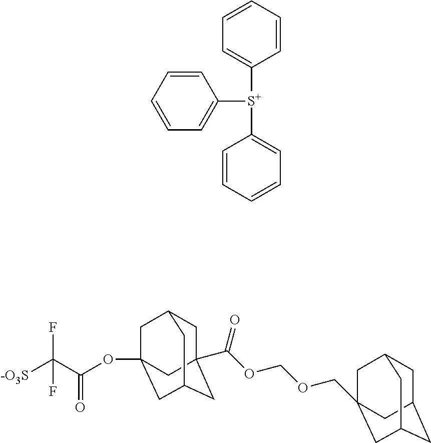

B1-7: The compound represented by the following formula, prepared by such a method as mentioned in JP2008-126869A1

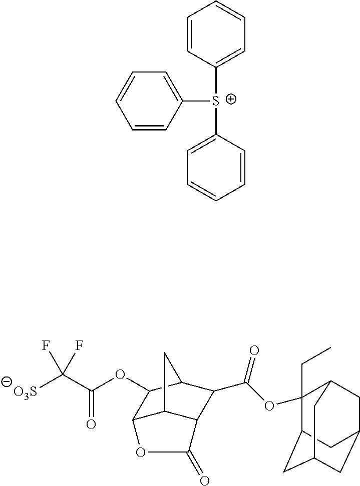

B1-8: The compound represented by the following formula, manufactured by Central Grass Corp., Ltd.

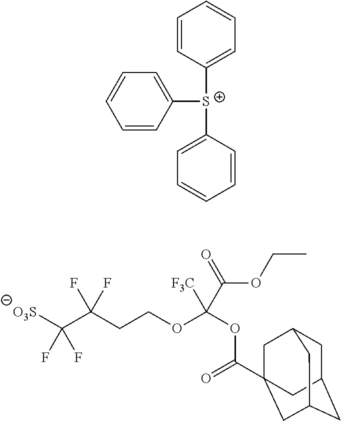

### <Quencher>

C1: The compound represented by the following formula, manufactured by Tokyo Chemical Industries, Co., Ltd.

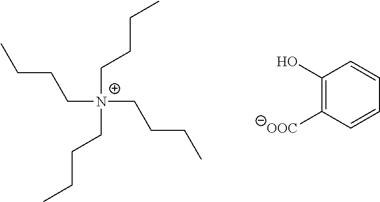

C2: The compound represented by the following formula

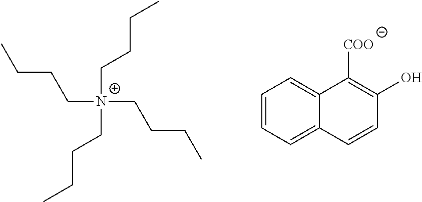

C3: tri(n-octyl)aniline
C4: 2,6-diisopropylaniline, manufactured by Tokyo Chemical Industries, Co., Ltd.
D1: The compound represented by the following formula, manufactured by Tokyo Chemical Industries, Co., Ltd.

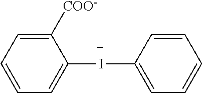

F1: The compound represented by the following formula

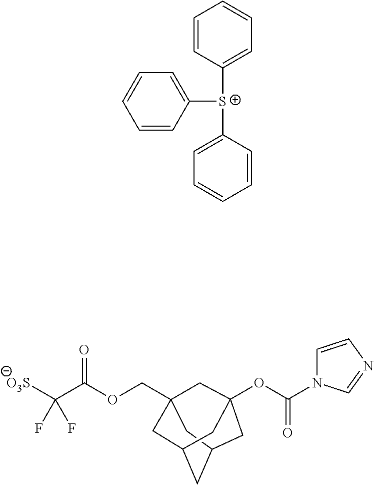

### <Solvent>

| | |
|---|---|
| propylene glycol monomethyl ether acetate | 400 parts |
| propylene glycol monomethyl ether | 150 parts |
| γ-butyrolactone | 5 parts |

The following components as shown in Table 1 and the solvents mentioned above were mixed to give a solution, and the solution was further filtrated through a fluorine resin filter having a pore diameter of 0.2 μm, to prepare photoresist compositions.

TABLE 1

| | COM- | | | | |
|---|---|---|---|---|---|
| | POUND (I) | Acid generator | Quencher | | |
| | (kind/amount | (kind/amount | (kind/amount | PB | PEB |
| Ex. No. | (part)) | (part)) | (part)) | (° C.) | (° C.) |
| Ex. 1 | A1/10 parts | B1-1/2 parts | C1/0.15 parts | 110 | 100 |
| Ex. 2 | A2/10 parts | B1-1/2 parts | C1/0.15 parts | 110 | 110 |
| Ex. 3 | A3/10 parts | B1-1/2 parts | C1/0.15 parts | 110 | 110 |
| Ex. 4 | A4/10 parts | B1-1/2 parts | C1/0.15 parts | 110 | 110 |
| Ex. 5 | A4/10 parts | B1-2/2.5 parts | C1/0.2 parts | 110 | 110 |
| Ex. 6 | A4/10 parts | B1-3/2.5 parts | C1/0.2 parts | 110 | 110 |
| Ex. 7 | A1/10 parts | B1-4/2 parts | C1/0.15 parts | 110 | 110 |
| Ex. 8 | A2/10 parts | B1-4/2 parts | C1/0.15 parts | 110 | 110 |
| Ex. 9 | A3/10 parts | B1-4/2 parts | C1/0.15 parts | 110 | 110 |
| Ex. 10 | A4/10 parts | B1-4/2 parts | C1/0.15 parts | 110 | 110 |
| Ex. 11 | A4/10 parts | B1-5/3 parts | C3/0.02 parts | 110 | 110 |
| | | | F1/0.5 parts | | |
| Ex. 12 | A4/10 parts | B1-5/2.5 parts | C2/0.36 parts | 110 | 110 |
| Ex. 13 | A4/10 parts | B1-5/1.7 parts | C2/0.23 parts | 110 | 110 |
| | | B1-2/0.6 parts | | | |
| Ex. 14 | A1/10 parts | B1-6/2.5 parts | C1/0.2 parts | 110 | 110 |
| Ex. 15 | A2/10 parts | B1-6/2.5 parts | C1/0.2 parts | 110 | 110 |
| Ex. 16 | A3/10 parts | B1-6/2.5 parts | C1/0.2 parts | 110 | 110 |
| Ex. 17 | A4/10 parts | B1-6/2.5 parts | C1/0.2 parts | 110 | 110 |
| Ex. 18 | A4/10 parts | B1-6/2.5 parts | C2/0.28 parts | 110 | 110 |
| Ex. 19 | A4/10 parts | B1-6/1.7 parts | C2/0.28 parts | 110 | 110 |
| | | B1-2/0.6 parts | | | |
| Ex. 20 | A4/10 parts | B1-6/2.5 parts | C3/0.02 parts | 110 | 110 |
| | | | F1/0.3 parts | | |
| Ex. 21 | A2/10 parts | B1-7/2.5 parts | D1/0.24 parts | 110 | 110 |
| Ex. 22 | A2/10 parts | B1-8/2.5 parts | D1/0.3 parts | 110 | 110 |
| Ex. 23 | A2/10 parts | B1-2/2 parts | D1/0.22 parts | 110 | 110 |
| Ex. 24 | A2/10 parts | B1-7/2.5 parts | F1/0.3 parts | 110 | 110 |
| Compar. | A4/10 parts | Z1/1.5 parts | C4/0.07 parts | 100 | 100 |
| Ex. 1 | | | | | |

Silicon wafers were each contacted with hexamethyldisilazane at 90° C. for 60 seconds and each of the photoresist compositions prepared as above was spin-coated over the silicon wafer to give a film thickness after drying of 0.06 μm. After application of each of the photoresist compositions, the silicon wafers thus coated with the respective photoresist compositions were each baked on a direct hotplate at a temperature shown in the column of “PB” in Table 1 for 60 seconds. Using a writing electron beam lithography system (“HL-800D” manufactured by Hitachi, Ltd., accelerating voltage: 50 KeV), each wafer on which the respective photoresist film had been thus formed was exposed to a line and space pattern, while changing stepwise the exposure quantity.

After the exposure, each wafer was subjected to post-exposure baking on a hotplate at a temperature shown in the column of “PEB” in Table 1 for 60 seconds and then to paddle development with an aqueous solution of 2.38% by weight tetramethylammonium hydroxide for 60 seconds.

### Resolution:

The exposure quantity at which the line width and the space width of pattern became 1:1 is referred to as “effective sensitivity”. The line and space pattern as obtained by the exposure at the exposure quantity equivalent to the effective sensitivity was observed with a scanning electron microscope. When the line width of the pattern was 50 nm or less, its evaluation is marked by “◯”. When the line width of the pattern was over 50 nm but not over 55 nm, its evaluation is marked by “Δ”. When the line width of the pattern was over 55 nm, its evaluation is marked by “X”. The smaller the line width is, the better the pattern is.

TABLE 2

| Ex. No. | Resolution |
|---|---|
| Ex. 1 | ◯ |
| Ex. 2 | ◯ |
| Ex. 3 | ◯ |
| Ex. 4 | ◯ |
| Ex. 5 | ◯ |
| Ex. 6 | ◯ |
| Ex. 7 | ◯ |
| Ex. 8 | ◯ |
| Ex. 9 | ◯ |
| Ex. 10 | ◯ |
| Ex. 11 | ◯ |
| Ex. 12 | ◯ |
| Ex. 13 | ◯ |
| Ex. 14 | ◯ |
| Ex. 15 | ◯ |
| Ex. 16 | ◯ |
| Ex. 17 | ◯ |
| Ex. 18 | ◯ |
| Ex. 19 | ◯ |
| Ex. 20 | ◯ |
| Ex. 21 | ◯ |
| Ex. 22 | ◯ |
| Ex. 23 | ◯ |
| Ex. 24 | ◯ |
| Compar. Ex. 1 | X |

Apparent from the results shown in Table 2, the photoresist compositions obtained by Examples corresponding to the present invention show good resolution and good line edge roughness.

### Examples 25 to 31

The components as shown in Table 3 and the solvents mentioned above were mixed to give a solution, and the solution was further filtrated through a fluorine resin filter having a pore diameter of 0.2 μm, to prepare photoresist composition.

TABLE 3

| | COMPOUND | | | | |
|---|---|---|---|---|---|
| | (I) | Acid generator | Quencher | | |
| | (kind/amount | (kind/amount | (kind/amount | PB | PEB |
| Ex. No. | (part)) | (part)) | (part)) | (° C.) | (° C.) |
| Ex. 25 | A4/10 parts | B1-1/2.5 parts | C1/0.15 parts | 110 | 110 |
| Ex. 26 | A4/10 parts | B1-5/2.5 parts | C2/0.36 parts | 110 | 110 |
| Ex. 27 | A4/10 parts | B1-5/1.7 parts | C2/0.23 parts | 110 | 110 |
| | | B1-2/0.6 parts | | | |
| Ex. 28 | A4/10 parts | B1-6/1.7 parts | C2/0.28 parts | 110 | 110 |
| | | B1-2/0.6 parts | | | |
| Ex. 29 | A4/10 parts | B1-5/2.5 parts | C3/0.02 parts | 110 | 110 |
| | | | F1/0.3 parts | | |
| Ex. 30 | A2/10 parts | B1-7/2.5 parts | D1/0.3 parts | 110 | 100 |
| Ex. 31 | A2/10 parts | B1-7/2.5 parts | F1/0.3 parts | 110 | 100 |

Silicon wafers were each contacted with hexamethyldisilazane at 90° C. for 60 seconds and each of the photoresist compositions prepared as above was spin-coated over the silicon wafer to give a film thickness after drying of 0.04 μm. After application of each of the photoresist compositions, the silicon wafers thus coated with the respective photoresist compositions were each baked on a direct hotplate at a temperature shown in the column of “PB” of Table 3 for 60 seconds. Using an EUV (extreme ultraviolet) exposure system (NA=0.30, quadrapole illumination), each wafer on which the respective photoresist film had been thus formed was exposed through a mask of 1:1 line and space pattern (line width: 30 nm to 20 nm) to make a line and space pattern, while changing stepwise the exposure quantity.

After the exposure, each wafer was subjected to post-exposure baking on a hotplate at shown in the column of “PEB” of Table 3 for 60 seconds and then to paddle development with an aqueous solution of 2.38% by weight tetramethylammonium hydroxide for 60 seconds.

### Resolution:

The line and space pattern as obtained by the exposure at exposure quantity equivalent to the effective sensitivity was observed with a scanning electron microscope. The smaller the line width is, the better the pattern is. When the line width of the pattern was 24 nm or less, its evaluation is marked by “◯”. When the line width of the pattern was over 24 nm but not over 28 nm, its evaluation is marked by “Δ”. When the line width of the pattern was over 28 nm, its evaluation is marked by “X”.

TABLE 4

| Ex. No. | Resolution |
|---|---|
| Ex. 25 | ◯ |
| Ex. 26 | ◯ |
| Ex. 27 | ◯ |
| Ex. 28 | ◯ |
| Ex. 29 | ◯ |
| Ex. 30 | ◯ |
| Ex. 31 | ◯ |

Apparent from the results shown in Examples, the photoresist compositions of to the present invention can provide a photoresist pattern with good resolution.

What is claimed is:

1. A photoresist composition comprising
a compound represented by formula (I): 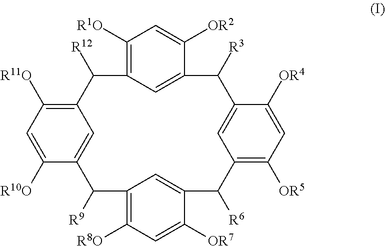
wherein R¹, R², R⁴, R⁵, R⁷, R⁸, R¹⁰ and R¹¹ independently represent a hydrogen atom, a C1-C20 aliphatic hydrocarbon group, a C6-C10 aromatic hydrocarbon group, or a C2-C10 alkoxyalkyl group,
R³, R⁶, R⁹ and R¹² independently represent a group of formula (II): 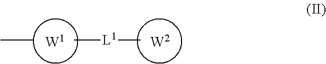
where the ring W¹ represents a C3-C36 aliphatic hydrocarbon ring, or a C6-C36 aromatic hydrocarbon ring,
the ring W² represents a C3-C36 aliphatic hydrocarbon ring which optionally has a subsituent and in which a methylene group is optionally replaced by an oxygen atom, a sulfonyl group or a carbonyl group, or a C6-C36 aromatic hydrocarbon ring which optionally has a subsituent, and
L¹ represents a single bond or a C1-C10 divalent aliphatic hydrocarbon group in which a methylene group is optionally replaced by an oxygen atom or a carbonyl group, and
a salt represented by the formula (B1): 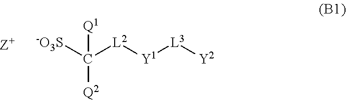
wherein Q¹ and Q² independently represent a fluorine atom or a C1-C6 perfluoroalkyl group,
L² represents a single bond or a C1-C17 divalent saturated hydrocarbon group in which a methylene group is optionally replaced by an oxygen atom, a carbonyl group, or —NR′— and in which a hydrogen atom is optionally replaced by a fluorine atom, and R′ represents a hydrogen atom or a C1-C4 alkyl group,
Y¹ represents a single bond or a C3-C18 divalent alicyclic hydrocarbon group in which a methylene group is optionally replaced by an oxygen atom, a carbonyl group or a sulfonyl group and in which a hydrogen atom is optionally replaced by a substituent,
L³ represents a single bond or a C1-C17 divalent hydrocarbon group in which a methylene group is optionally replaced by an oxygen atom or a carbonyl group,
Y² represents a C3-C18 alicyclic hydrocarbon group in which a methylene group is optionally replaced by an oxygen atom, a sulfonyl group or a carbonyl group and in which a hydrogen atom is optionally replaced by a substituent, and
Z⁺ represents an organic cation.

2. The photoresist composition according to claim 1, wherein Q¹ and Q² represent a fluorine atom.

3. The photoresist composition according to claim 1, wherein Y¹ represents a single bond or a C3-C18 divalent alicyclic hydrocarbon group.

4. The photoresist composition according to claim 1, wherein L² represents a single bond or a C1-C17 divalent saturated hydrocarbon group in which a methylene group is optionally replaced by an oxygen atom or a carbonyl group and in which a hydrogen atom is optionally replaced by a fluorine atom.

5. The photoresist composition according to claim 1, wherein L² represents *—CO—O-L^{s2}- where L^{s2} represents a single bond or a C1-C15 divalent hydrocarbon group and * represents a binding position to —C(Q¹)(Q²)-.

6. The photoresist composition according to claim 1, wherein Z⁺ represents an arylsulfonium cation.

7. The photoresist composition according to claim 1, wherein the ring W¹ represents a benzene ring.

8. The photoresist composition according to claim 1, wherein the ring W² represents a group of formula (I-a); 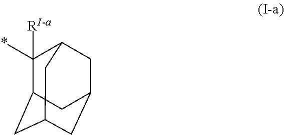
in which R^{I-a} represents a hydrogen atom or a C1-C6 alkyl group, and * represents a binding position to L¹, or
a group of formula (I-d); 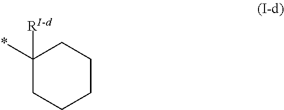
in which R^{I-d} represents a hydrogen atom or a C1-C6 alkyl group, and * represents a binding position to L¹.

9. The photoresist composition according to claim 1, wherein L¹ represents *—CO—O—CH₂—O— or *—CO—O—CH₂—CO—O— where * represents a binding position to W¹.

10. The photoresist composition according to claim 1, which further comprises a quencher.

11. A process for producing a photoresist pattern comprising the following steps (1) to (5):
(1) a step of applying the photoresist composition according to claim 1 onto a substrate,
(2) a step of forming a photoresist film by conducting drying,
(3) a step of exposing the photoresist film to radiation,
(4) a step of baking the exposed photoresist film, and
(5) a step of developing the baked photoresist film thereby forming a photoresist pattern.
